(19) United States
(12) Patent Application Publication
(10) Pub. No.: US 2025/0072206 A1
(43) Pub. Date: Feb. 27, 2025

(54) LIGHT EMITTING ELEMENT, AND DISPLAY DEVICE INCLUDING THE SAME

(71) Applicant: Samsung Display Co., Ltd., Yongin-si (KR)

(72) Inventors: Kwang Hun PARK, Yongin-si (KR); SEULONG KIM, Yongin-si (KR); YUNJAE KIM, Yongin-si (KR); JINYEONG KIM, Yongin-si (KR); HYUNGU KIM, Yongin-si (KR); BOHUN PARK, Yongin-si (KR); Heeju AN, Yongin-si (KR); SUNG-JIN LEE, Yongin-si (KR)

(73) Assignee: Samsung Display Co., Ltd., Yongin-si (KR)

(21) Appl. No.: 18/756,003

(22) Filed: Jun. 27, 2024

(30) Foreign Application Priority Data
Aug. 22, 2023 (KR) 10-2023-0110164

(51) Int. Cl. H10K 50/19; H10K 50/13; H10K 50/858; H10K 59/122; H10K 85/30; H10K 85/60; H10K 102/00

(52) U.S. Cl. CPC H10K 50/19; H10K 50/13; H10K 50/858; H10K 59/122; H10K 85/342; H10K 85/623; H10K 85/633; H10K 85/636; H10K 85/654; H10K 85/6572; H10K 85/6574; H10K 85/6576; H10K 85/658; H10K 2102/351

(57) ABSTRACT

Embodiments provide a light emitting element and a display device including the light emitting element. The light emitting element includes a first electrode, a first light emitting unit disposed on the first electrode and including a first emission layer, a charge generation unit disposed on the first light emitting unit, a second light emitting unit disposed on the charge generation unit and including a second emission layer, a second electrode disposed on the second light emitting unit, a first capping layer disposed on the second electrode, and a second capping layer disposed on the first capping layer. The first capping layer includes a first compound represented by Formula 1, and the second capping layer includes a second compound represented by Formula 2-1 or Formula 2-2. Formulas 1, 2-1, and 2-2 are explained in the specification:

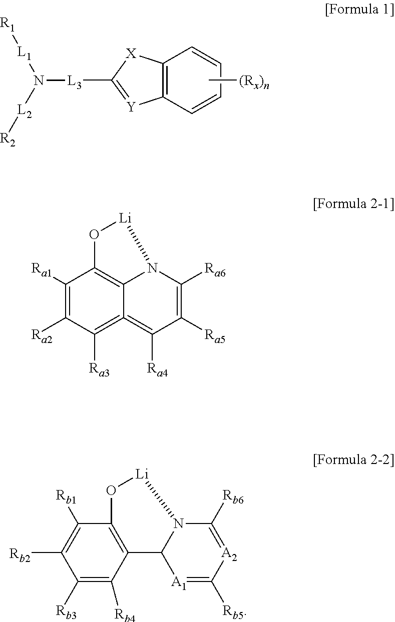

### CROSS-REFERENCE TO RELATED APPLICATION(S)

This application claims priority to and benefits of Korean Patent Application No. 10-2023-0110164 under 35 U.S.C. § 119, filed on Aug. 22, 2023, in the Korean Intellectual Property Office, the entire contents of which are incorporated herein by reference.

### BACKGROUND

### 1. Technical Field

The disclosure relates to a light emitting element, and a display device including the same.

### 2. Description of the Related Art

Organic light emitting elements are self-emitting elements having fast response times and low driving voltages. Accordingly, organic light emitting display devices including organic light emitting elements may not include a separate light source, and thus may be thin and lightweight. Organic light emitting display devices have numerous advantages, such as excellent brightness and viewing angle independence.

An organic light emitting element is a display element that includes an emission layer made of organic materials between an anode electrode and a cathode electrode. After a hole provided from the anode electrode and an electron provided from the cathode electrode combine in the emission layer to form an exciton, light corresponding to the energy between the hole and the electron is generated from the exciton.

A tandem organic light emitting element may have a structure that includes two or more stacks of a hole injection layer/emission layer/electron transport layer between the anode electrode and the cathode electrode. A charge generation layer that assists in the generation and transport of charges may be present between each of the stacks.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element in which luminescence characteristics and an element service life are improved.

The disclosure also provides a display device including the light emitting element in which the luminous efficiency and service life are improved, thereby having excellent display quality.

According to an embodiment, a light emitting element may include a first electrode, a first light emitting unit disposed on the first electrode and including a first emission layer, a charge generation unit disposed on the first light emitting unit, a second light emitting unit disposed on the charge generation unit and including a second emission layer, a second electrode disposed on the second light emitting unit, a first capping layer disposed on the second electrode, and a second capping layer disposed on the first capping layer, wherein
the first capping layer may include a first compound represented by Formula 1, and the second capping layer may include a second compound represented by Formula 2-1 or Formula 2-2:

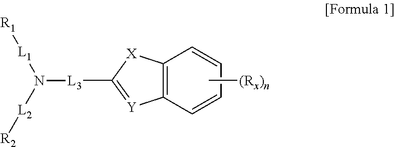

In Formula 1, L₁ to L₃ may each independently be a direct linkage, a substituted or unsubstituted arylene group having 6 to 12 ring-forming carbon atoms, or a substituted or unsubstituted heteroarylene group having 5 to 11 ring-forming carbon atoms,
X may be O or S,
Y may be N or C(R_{y}), and
R₁, R₂, Rₓ, and R_{y} may each independently be a hydrogen atom, a deuterium atom, a halogen atom, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; and n may be an integer from 0 to 4;

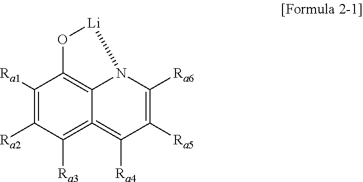

In Formula 2-1, Rₐ₁ to Rₐ₆ may each independently be a hydrogen atom, a deuterium atom, a halogen atom, a cyano group, a substituted or unsubstituted amine group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring;

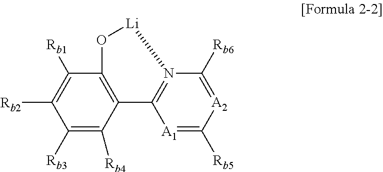

In Formula 2-2, A₁ and A₂ may each independently be N or C(R_{z}), and
R_{z} and R_{b1} to R_{b6} may each independently be a hydrogen atom, a deuterium atom, a halogen atom, a cyano group, a substituted or unsubstituted amine group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In an embodiment, the first capping layer may have a refractive index in a range of about 2.2 to about 6.0, with respect to visible light having a wavelength of about 450 nm; and the second capping layer may have a refractive index in a range of about 1.0 to about 2.0, with respect to visible light having a wavelength of about 450 nm.

In an embodiment, in Formula 1, R₁ and R₂ may each independently be a substituted or unsubstituted amine group, a substituted or unsubstituted phenyl group, a substituted or unsubstituted naphthyl group, a substituted or unsubstituted benzoxazole group, a substituted or unsubstituted benzothiazole group, a substituted or unsubstituted benzofuran group, or a substituted or unsubstituted benzothiophene group.

In an embodiment, in Formula 2-1 and Formula 2-2, Rₐ₁ to Rₐ₆ and R_{b1} to R_{b6} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted phenyl group, or bonded to an adjacent group to form a ring.

In an embodiment, the first compound may be represented by any one of Formula 1-1 to Formula 1-3:

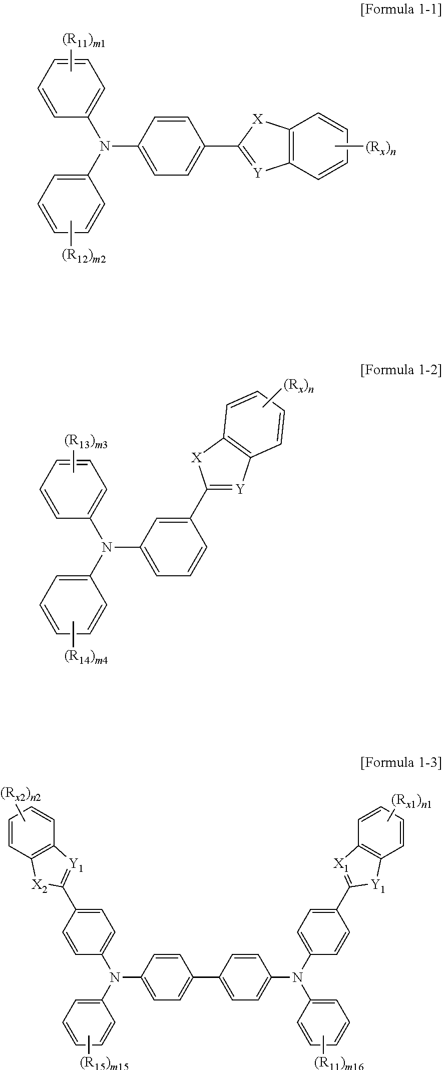

In Formula 1-1 to Formula 1-3, R₁₁ to R₁₆ may each independently be a hydrogen atom, a deuterium atom, a halogen atom, a cyano group, a substituted or unsubstituted amine group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring; Rₓ₁ and Rₓ₂ may each independently be a hydrogen atom, a deuterium atom, a halogen atom, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; X₁ and X₂ may each independently be O or S; Y₁ and Y₂ may each independently be N or C(R_{y}); n1 and n2 may each independently be an integer from 0 to 4; m1 to m6 may each independently be an integer from 0 to 5; and X, Y, Rₓ, R_{y}, and n are the same as defined in Formula 1.

In an embodiment, the first compound may include at least one compound selected from Compound Group 1, which is explained below.

In an embodiment, the second compound may include at least one compound selected from Compound Group 2, which is explained below.

In an embodiment, a refractive index of the first capping layer with respect to visible light may be higher than a refractive index of the second capping layer with respect to visible light.

In an embodiment, a thickness of the first capping layer may be greater than a thickness of the second capping layer.

In an embodiment, a sum of a thickness of the first capping layer and a thickness of the second capping layer may be in a range of about 100 nm to about 300 nm.

In an embodiment, the first capping layer may have a thickness in a range of about 50 nm to about 80 nm; and the second capping layer may have a thickness in a range of about 30 nm to 60 nm.

In an embodiment, the first emission layer may include a first red emission layer that emits red light, a first green emission layer that emits green light, and a first blue emission layer that emits blue light; and the first red emission layer, the first green emission layer, and the first blue emission layer may be spaced apart from each other in a plan view.

In an embodiment, the second emission layer may include a second red emission layer that corresponds to the first red emission layer and emits red light, a second green emission layer that corresponds to the first green emission layer and emits green light, and a second blue emission layer that corresponds to the first blue emission layer and emits blue light.

In an embodiment, the first light emitting unit may further include a first hole transport region disposed on a lower portion of the first emission layer, and a first electron transport region disposed on an upper portion of the first emission layer; and the second light emitting unit may further include a second electron transport region disposed on an upper portion of the second emission layer.

According to an embodiment, a display device may include a base layer, a circuit layer disposed on the base layer, and a display element layer disposed on the circuit layer and including a light emitting element, wherein
the light emitting element may include a first electrode, a first light emitting unit disposed on the first electrode and including a first emission layer, a charge generation unit disposed on the first light emitting unit, a second light emitting unit disposed on the charge generation unit and including a second emission layer, a second electrode disposed on the second light emitting unit, a first capping layer disposed on the second electrode, and a second capping layer disposed on the first capping layer; the first capping layer may include a first compound represented by Formula 1; and the second capping layer may include a second compound represented by Formula 2-1 or Formula 2-2.

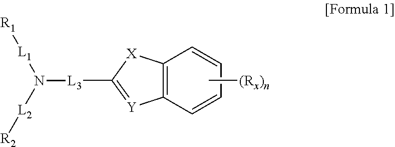

In Formula 1, L₁ to L₃ may each independently be a direct linkage, a substituted or unsubstituted arylene group having 6 to 12 ring-forming carbon atoms, or a substituted or unsubstituted heteroarylene group having 5 to 11 ring-forming carbon atoms; X may be O or S; Y may be N or C(R_{y}); R₁, R₂, Rₓ, and R_{y} may each independently be a hydrogen atom, a deuterium atom, a halogen atom, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; and n may be an integer from 0 to 4.

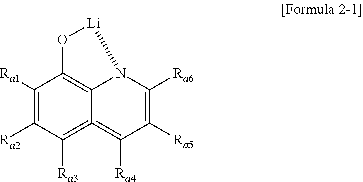

In Formula 2-1, Rₐ₁ to Rₐ₆ may each independently be a hydrogen atom, a deuterium atom, a halogen atom, a cyano group, a substituted or unsubstituted amine group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

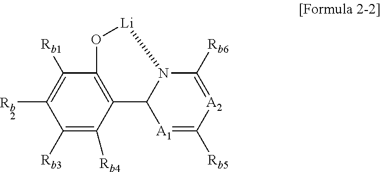

In Formula 2-2, A₁ and A₂ may each independently be N or C(R_{z}); and R_{z} and R_{b1} to R_{b6} may each independently be a hydrogen atom, a deuterium atom, a halogen atom, a cyano group, a substituted or unsubstituted amine group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In an embodiment, the base layer may include a first light emitting region, a second light emitting region, and a third light emitting region, which are spaced apart from each other in a plan view, and a non-light emitting region defined between the first light emitting region, the second light emitting region, and the third light emitting region; the display element layer may include a pixel defining film that overlaps the non-light emitting region, and openings that overlap each of the first light emitting region, the second light emitting region, and the third light emitting region; and the first emission layer may be disposed in each of the openings.

In an embodiment, the first emission layer may include a first red emission layer that corresponds to the first light emitting region, a first green emission layer that corresponds to the second light emitting region, and a first blue emission layer that corresponds to the third light emitting region; and the second emission layer may include a second red emission layer that corresponds to the first light emitting region, a second green emission layer that corresponds to the second light emitting region, and a second blue emission layer that corresponds to the third light emitting region.

In an embodiment, the first light emitting unit may further include a first hole transport region disposed on a lower portion of the first emission layer, and a first electron transport region disposed on an upper portion of the first emission layer; and the first hole transport region and the first electron transport region may each be provided as a common layer with respect to the first light emitting region, the second light emitting region, and the third light emitting region.

In an embodiment, the second light emitting unit may further include a second electron transport region disposed on an upper portion of the second emission layer; and the second electron transport region may be provided as a common layer with respect to the first light emitting region, the second light emitting region, and the third light emitting region.

In an embodiment, the first electrode, the charge generation unit, the second electrode, the first capping layer, and the second capping layer may each be provided as a common layer with respect to the first light emitting region, the second light emitting region, and the third light emitting region.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIGS. 3A to 3D are each a schematic cross-sectional view of a light emitting element according to an embodiment;

FIG. 4 is a schematic cross-sectional view of a light emitting element according to an embodiment; and

FIG. 5 is a schematic perspective view of a vehicle in which display devices are disposed according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, a heterocyclic group, an aryl group, and a heteroaryl group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be aliphatic or aromatic. The heterocycle may be aliphatic or aromatic. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted at an atom which is directly linked to an atom substituted with a corresponding substituent, as another substituent that is substituted at an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However embodiments are not limited thereto.

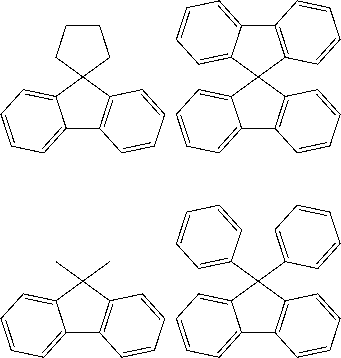

In the specification, a heterocyclic group may be any functional group or substituent derived from a ring that includes at least one of B, O, N, P, Si, S, and Se as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group contains two or more heteroatoms, the two or more heteroatoms may be the same as or different from each other. The number of ring-forming carbon atoms in a heterocyclic group may be 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, a xanthene group, an indolocarbazole group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, and may be 1 to 40, 1 to 30, or 1 to 20. For example, a carbonyl group may have one of the following structures, but embodiments are not limited thereto.

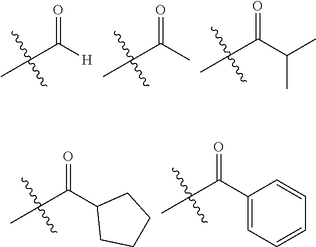

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkyl sulfoxy group, an alkyl aryl group, an alkyl boron group, an alkyl silyl group, or an alkyl amine group may be the same as an example of an alkyl group as described above.

In the specification, an aryl group within an aryloxy group, an arylthio group, an aryl sulfoxy group, an aryl boron group, an aryl silyl group, or an aryl amine group may be the same as an example of an aryl group as described above.

In the specification, a direct linkage may be a single bond.

In the specification, the symbols

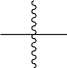

and —* each represent a bond to a neighboring atom in a corresponding formula or moiety.

Hereinafter, embodiments will be described with reference to the accompanying drawings.

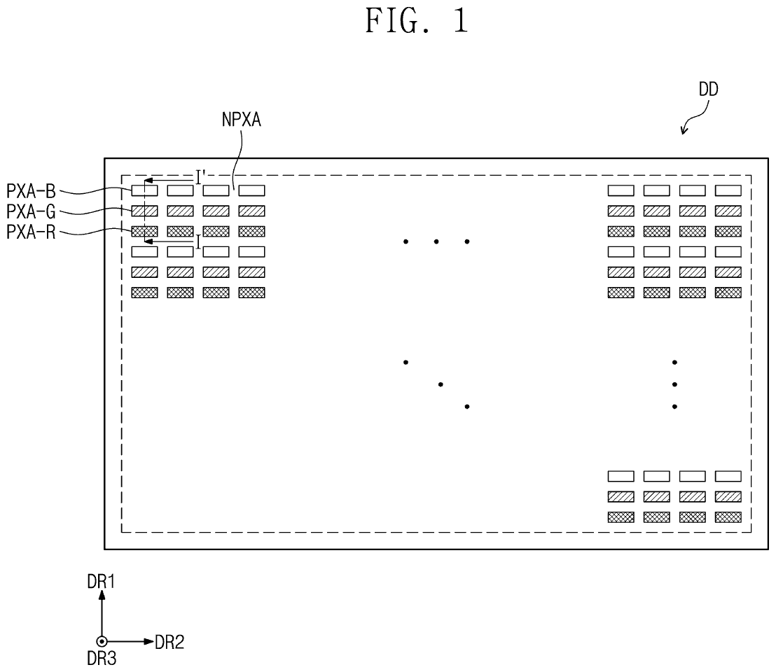

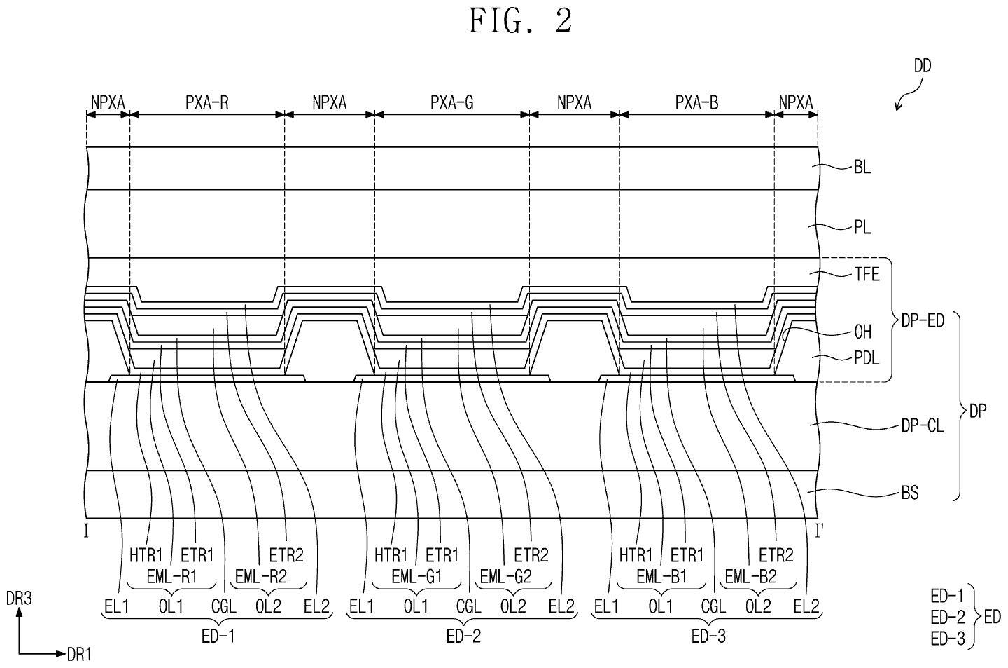

FIG. 1 is a schematic plan view of a display device DD according to an embodiment. FIG. 2 is a schematic cross-sectional view of a display device DD according to the embodiment. FIG. 2 is a schematic cross-sectional view illustrating a part taken along virtual line I-I′ in FIG. 1.

The display device DD may include a display panel DP and an optical layer PL disposed on the display panel DP. The display panel DP includes light emitting elements ED-1, ED-2, and ED-3. The display device DD may include multiples of each of the light emitting elements ED-1, ED-2, and ED-3. The optical layer PL may be disposed on the display panel DP to control light that is reflected at the display panel DP from an external light. The optical layer PL may include, for example, a polarization layer or a color filter layer. Although not shown in the drawings, in an embodiment, the optical layer PL may be omitted from the display device DD.

A base substrate BL may be disposed on the optical layer PL. The base substrate BL may provide a base surface on which the optical layer PL is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display element layer DP-ED. The display element layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

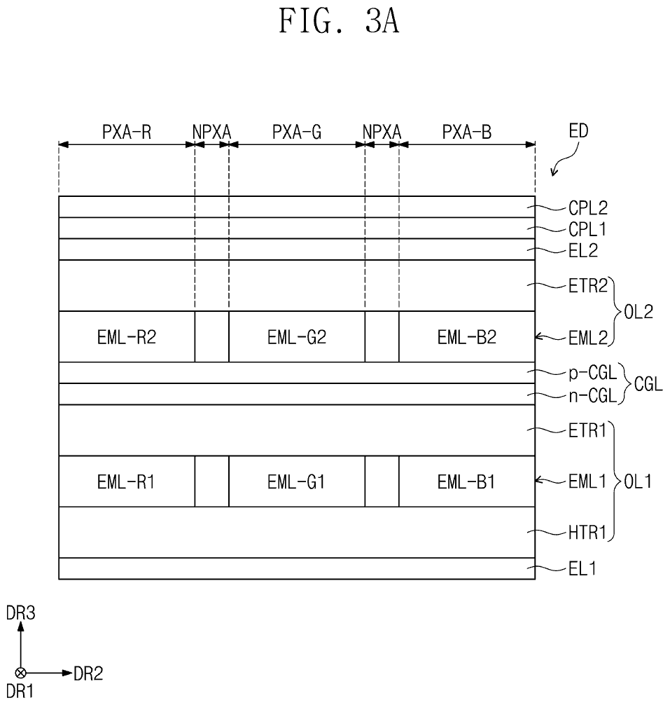

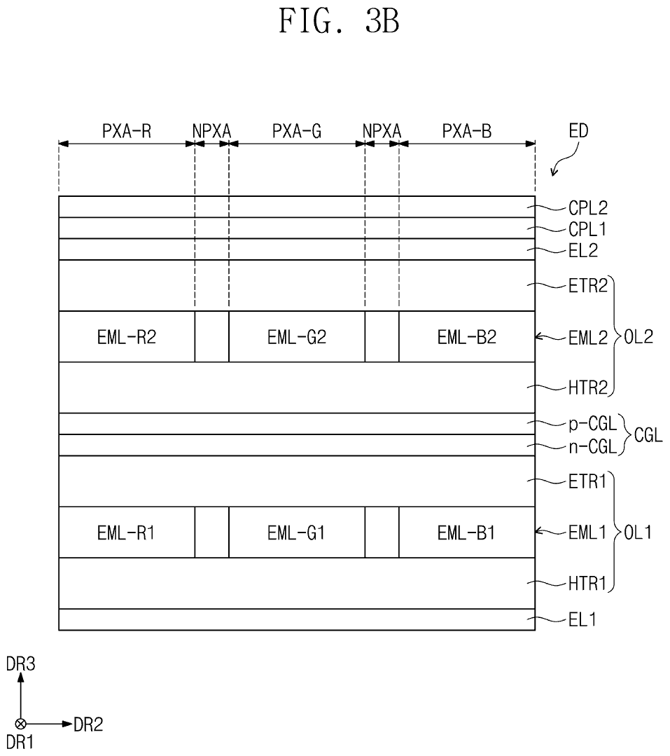

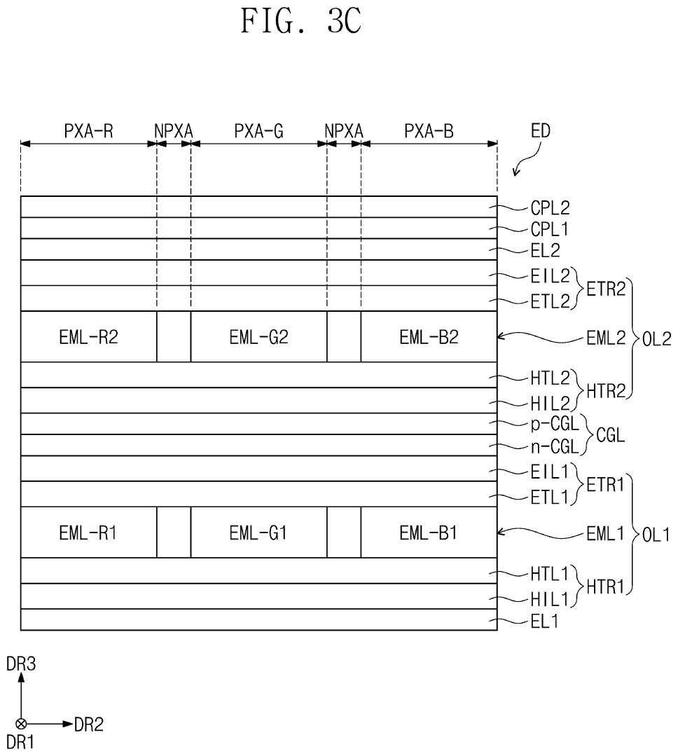

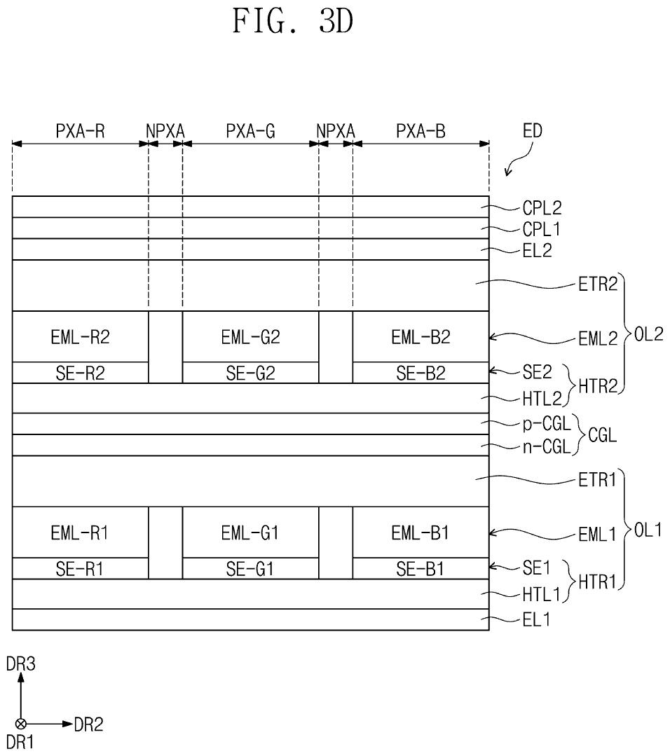

The light emitting elements ED-1, ED-2, and ED-3 may include a first light emitting element ED-1, a second light emitting element ED-2, and a third light emitting element ED-3. The light emitting elements ED-1, ED-2, and ED-3 may each have a structure of a light emitting element ED of an embodiment according to any of FIGS. 3A to 3D, which will be described later. The light emitting elements ED-1, ED-2, and ED-3 may each include a first light emitting unit OL1, a charge generation unit CGL, a second light emitting unit OL2, and a second electrode EL2. The light emitting elements ED-1, ED-2, and ED-3 may each be a light emitting element having a tandem structure. In the light emitting elements ED-1, ED-2, and ED-3, the two light emitting units may each emit light in a same wavelength region.

The first light emitting unit OL1 may include a first hole transport region HTR1, first emission layers EML-R1, EML-G1, and EML-B1, and a first electron transport region ETR1. The second light emitting unit OL2 may include second emission layers EML-R2, EML-G2, and EML-B2, and a second electron transport region ETR2. FIG. 2 illustrates an embodiment in which the first and second emission layers EML-R1, EML-G1, EML-B1, EML-R2, EML-G2, and EML-B2 of the light emitting elements ED-1, ED-2, and ED-3 are disposed in openings OH defined in the pixel defining film PDL, and the first hole transport region HTR1, the first and second electron transport regions ETR1 and ETR2, the charge generation unit CGL, and the second electrode EL2 are each provided as a common layer for the light emitting elements ED-1, ED-2, and ED-3. However, embodiments are not limited thereto. Although not illustrated in FIG. 2, in an embodiment, at least one of the first hole transport region HTR1, the first and second electron transport regions ETR1 and ETR2, and the charge generation unit CGL may each be provided as a pattern layer by being patterned in the openings OH defined in the pixel defining film PDL. In the specification, the term “common layer” may be interpreted such that the component may be provided in common to the all of light emitting elements ED-1, ED-2, and ED-3 to form a substantial single configuration, and the term “pattern layer” may be interpreted such that the components may be provided by being patterned inside the openings OH defined in the pixel defining film PDL and spaced apart from each other. For example, in an embodiment, the first hole transport region HTR1, the first and second emission layers EML-R1, EML-G1, EML-B1, EML-R2, EML-G2, and EML-B2, the charge generation unit CGL, the first and second electron transport regions ETR1 and ETR2, and the like of the light emitting elements ED-1, ED-2, and ED-3 may be provided by an inkjet printing method as needed.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display element layer DP-ED from moisture and/or oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be regions between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The first emission layers EML-R1, EML-G1, and EML-B1 and the second emission layers EML-R2, EML-G2, and EML-B2 of the light emitting elements ED-1, ED-2, and ED-3 may be disposed in the openings OH defined in the pixel defining film PDL and separated from each other.

The light emitting regions PXA-R, PXA-G, and PXA-B may be arranged into groups according to the colors of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a first light emitting region PXA-R in a red light emitting region, a second light emitting region PXA-G in a green light emitting region, and a third light emitting region PXA-B in a blue light emitting region.

In the display device DD according to an embodiment, the light emitting elements ED-1, ED-2 and ED-3 may emit light having wavelength regions that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength region, or at least one light emitting element may emit light in a wavelength region that is different from the remainder.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations, according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of the green light emitting region PXA-G may be smaller than an area of the blue light emitting region PXA-B, but embodiments are not limited thereto.

FIGS. 3A to 3D are each a schematic cross-sectional view of a light emitting element according to an embodiment.

Referring to FIG. 3A, the light emitting element ED according to an embodiment may include a first electrode EL1, a first light emitting unit OL1, a charge generation unit CGL, a second light emitting unit OL2, a second electrode EL2, a first capping layer CPL1, and a second capping layer CPL2. In the light emitting element ED, the first light emitting unit OL1 may include a first hole transport region HTR1, a first emission layer EML1, and a first electron transport region ETR1, which are sequentially stacked, and the second light emitting unit OL2 may include a second emission layer EML2 and a second electron transport region ETR2, which are sequentially stacked.

In comparison to FIG. 3A, FIG. 3B illustrates a schematic cross-sectional view of a light emitting element ED in which the second light emitting unit OL2 further includes a second hole transport region HTR2 disposed on a lower portion of the second emission layer EML2. In comparison to FIG. 3B, FIG. 3C illustrates a schematic cross-sectional view of a light emitting element ED in which the first and second hole transport regions HTR1 and HTR2 respectively include first and second hole injection layers HIL1 and HIL2, and first and second hole transport layers HTL1 and HTL2, and the first and second electron transport regions ETR1 and ETR2 respectively include first and second electron injection layers EIL1 and EIL2 and first and second electron transport layers ETL1 and ETL2. In comparison to FIG. 3B, FIG. 3D illustrates a schematic cross-sectional view of a light emitting element ED in which the first and second hole transport regions HTR1 and HTR2 respectively include first and second emission-auxiliary layers SE-1 (SE-R1, SE-G1, and SE-B1) and SE-2 (SE-R2, SE-G2, and SE-B2), and first and second hole transport layers HTL1 and HTL2.

Hereinafter, each of components included in the light emitting element ED will be described with reference to FIGS. 3A to 3D.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The first light emitting unit OL1 is provided on the first electrode EL1. The charge generation unit CGL is provided on the first light emitting unit OL1. For example, the charge generation unit CGL may be provided on the first electron transport region ETR1 of the first light emitting unit OL1. The second light emitting unit OL2 is provided on the charge generation unit CGL.

The first light emitting unit OL1 may include the first hole transport region HTR1, the first emission layer EML1, and the first electron transport region ETR1, which are sequentially stacked. The second light emitting unit OL2 may include the second emission layer EML2, and the second electron transport region ETR2. In an embodiment, the second light emitting unit OL2 may include the second hole transport region HT2, the second emission layer EML2, and the second electron transport region ETR2, which are sequentially stacked.

The hole transport regions HTR1 and HTR2 may each independently include at least one of the hole injection layers HIL1 and HIL2, the hole transport layers HTL1 and HTL2, the emission-auxiliary layers SE1 and SE2, and electron blocking layers (not shown). A thickness of the hole transport regions HTR1 and HTR2 may each independently be, for example, in a range of about 50 Å to about 15,000 Å.

The hole transport regions HTR1 and HTR2 may each independently be a layer consisting of a single material, a layer including different materials, or a structure including multiple layers including different materials.

In embodiments, the hole transport regions HTR1 and HTR2 may each independently have a single layer structure of the hole injection layers HIL1 and HIL2 or the hole transport layers HTL1 and HTL2, or may each independently have a single layer structure formed of a hole injection material and a hole transport material. In embodiments, the hole transport regions HTR1 and HTR2 may each independently have a single-layered structure formed of different materials, or may each independently have a structure in which hole injection layers HIL1 and HIL2/hole transport layers HTL1 and HTL2, hole injection layers HIL1 and HIL2/hole transport layers HTL1 and HTL2/emission-auxiliary layers SE1 and SE2, or hole injection layers HIL1 and HIL2/hole transport layers HTL1 and HTL2/emission-auxiliary layers SE1 and SE2/electron blocking layers (not shown) are stacked in their respective stated order from the first electrode EL1, but embodiments are not limited thereto.

When the hole transport regions HTR1 and HTR2 includes the emission-auxiliary layers SE1 and SE2, respectively, the emission-auxiliary layers SE1 and SE2 may be pattern layers that are patterned and provided in the openings OH (see FIG. 2). For example, the emission-auxiliary layers SE1 and SE2 may respectively include red emission-auxiliary layers SE-R1 and SE-R2 overlapping the first light emitting region PXA-R, green emission-auxiliary layers SE-G1 and SE-G2 overlapping the second light emitting region PXA-G, and blue emission-auxiliary layers SE-B1 and SE-B2 overlapping the third light emitting region PXA-B. The emission-auxiliary layers SE1 and SE2 may each compensate for a resonance distance according to a wavelength of light emitted from the emission layers EML1 and EML2, and may each increase light emission efficiency by adjusting a hole charge balance. The emission-auxiliary layers SE1 and SE2 may also prevent electron injection into the hole transport regions HTR1 and HTR2, respectively.

Each of the hole transport regions HTR1 and HTR2 may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport regions HTR1 and HTR2 may each independently include a compound represented by Formula H-1:

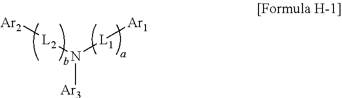

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In still another embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and a compound represented by Formula H-1 is not limited to Compound Group H:

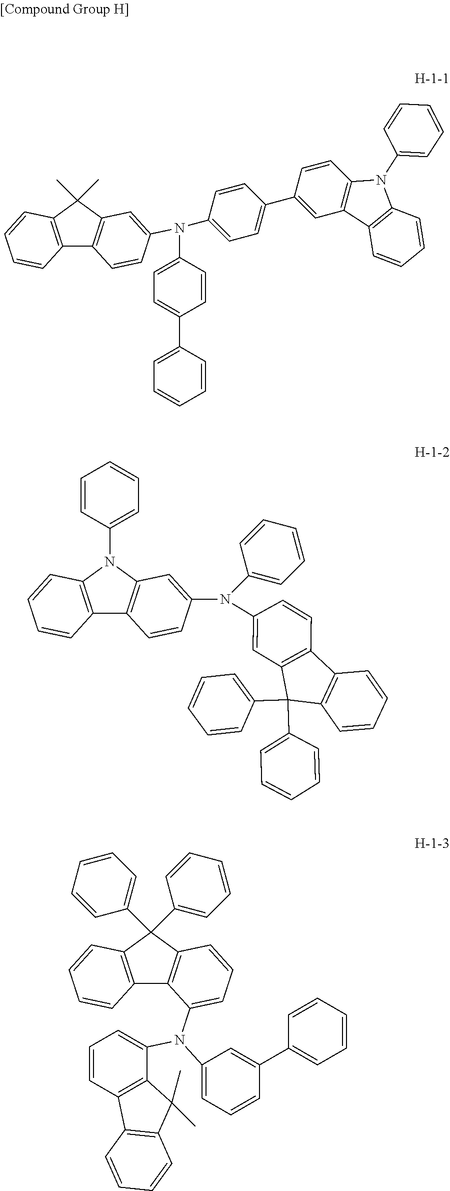 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

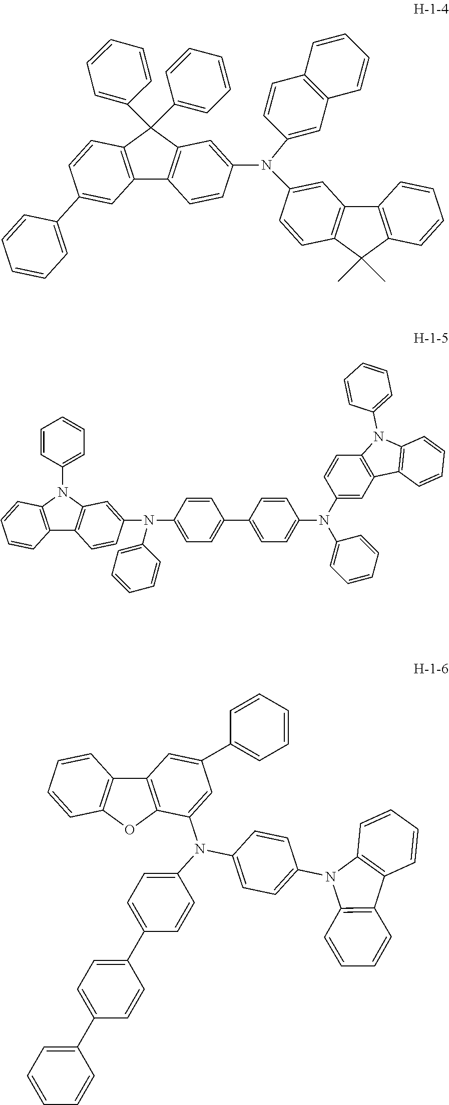 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

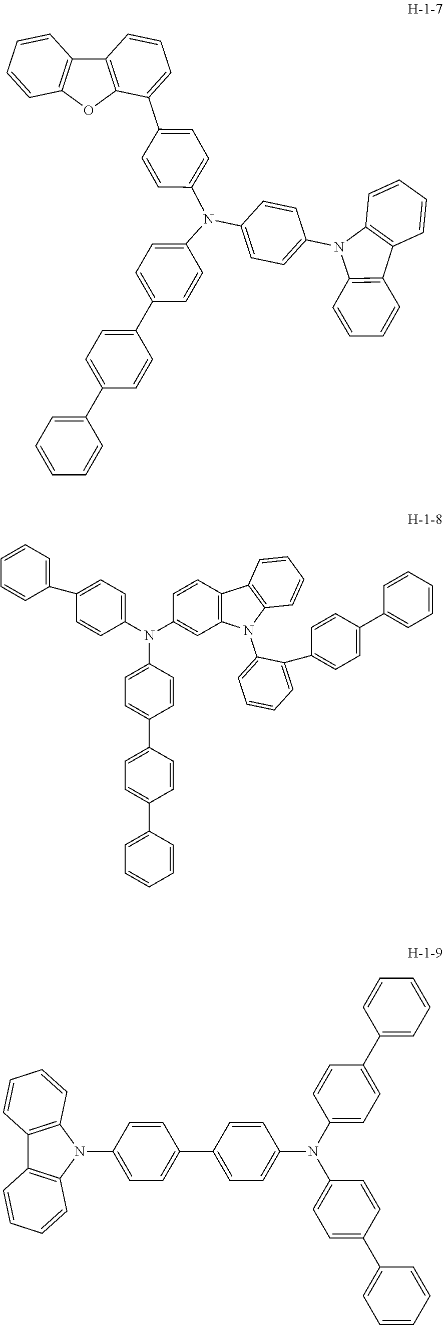 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

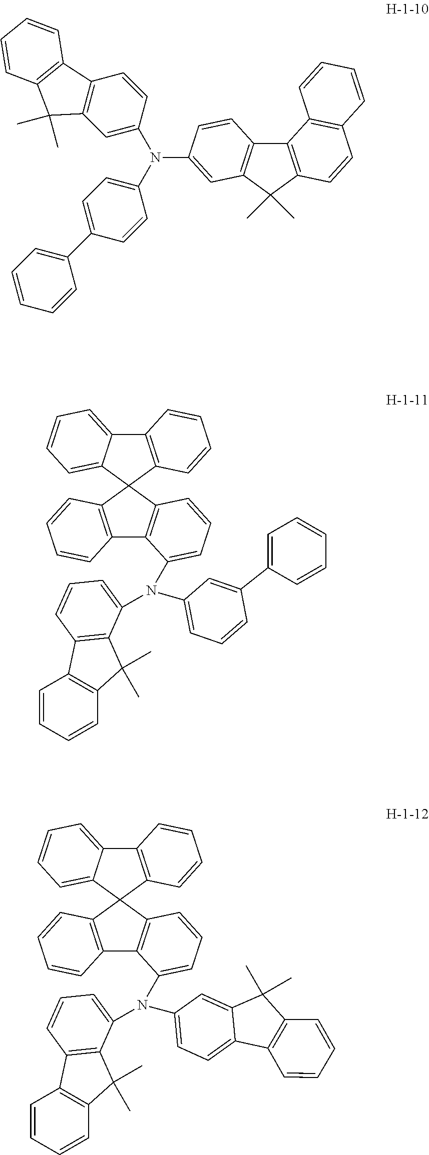 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

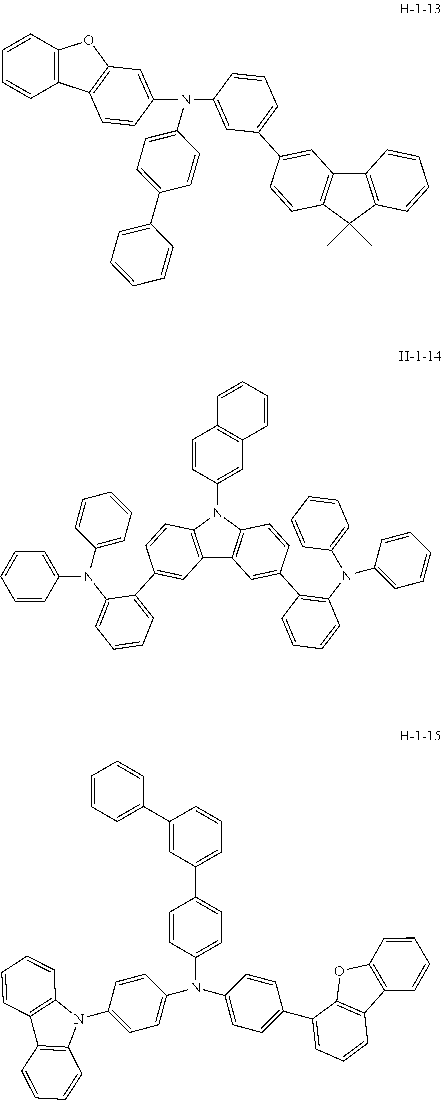 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

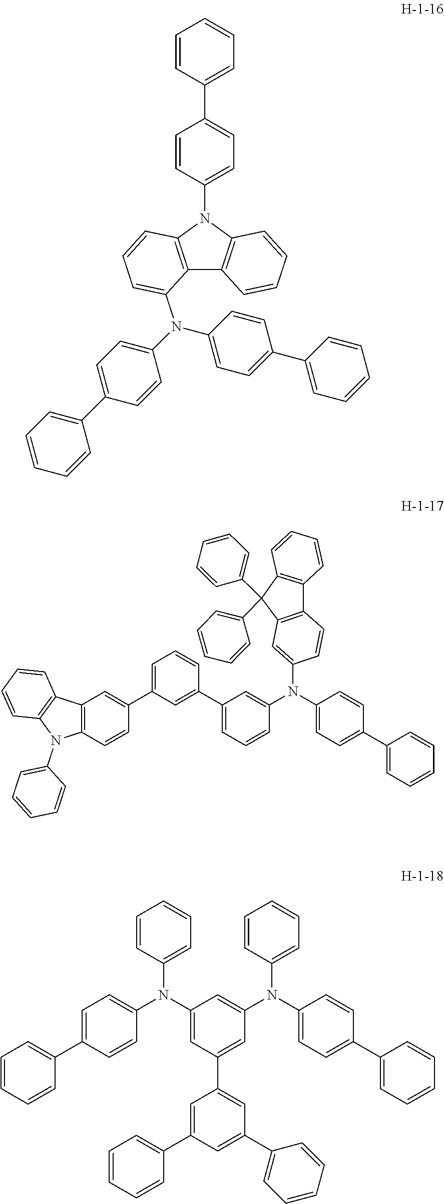 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

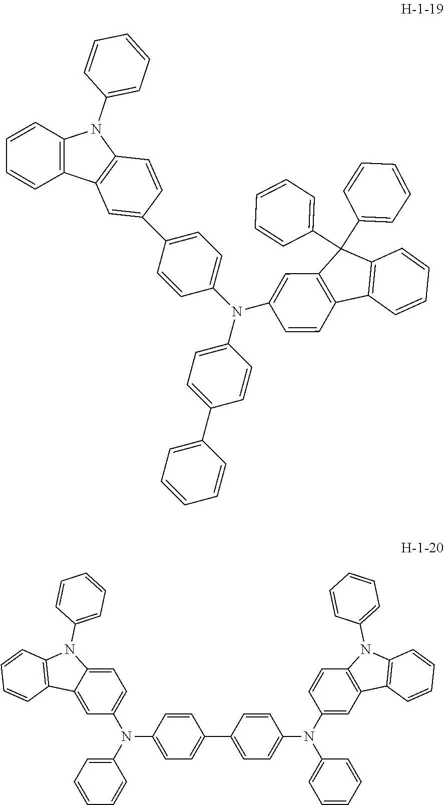 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

The hole transport regions HTR1 and HTR2 may each independently further include, for example, a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine](m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N-di(naphthalene-1-yl)-N,N-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f:2′,3′-h]quinoxaline-2,3,6,7,10,11-hexacarbonitrile (HATCN), etc.

The hole transport regions HTR1 and HTR2 may each independently further include a carbazole-based derivative such as N-phenyl carbazole or polyvinyl carbazole, a fluorene-based derivative, NN-bis(3-methylphenyl)-N,N-diphenyl-[1,1-biphenyl]-4,4′-diamine (TPD), a triphenylamine-based derivative such as 4,4′,4″-tris(N-carbazolyl)triphenylamine (TCTA), N,N-di(naphthalene-1-yl)-N,N-diphenyl-benzidine (NPB), 4,4′-cyclohexylidene bis[N,N-bis(4-methylphenyl]benzenamine](TAPC), 4,4′-bis[N,N-(3-tolyl)amino]-3,3′-dimethylbiphenyl (HMTPD), 1,3-bis(N-carbazolyl)benzene (mCP), etc.

In an embodiment, the hole transport regions HTR1 and HTR2 may each independently further include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport regions HTR1 and HTR2 may each independently have a thickness in a range of about 100 Å to about 10,000 Å. For example, the hole transport regions HTR1 and HTR2 may each independently have a thickness in a range of about 100 Å to about 5,000 Å. When the first hole transport region HTR1 includes the first hole injection layer HIL1, the first hole injection layer HIL may have a thickness in a range of about 30 Å to about 1,000 Å. When the first hole transport region HTR1 includes the first hole transport layer HTL1, the first hole transport layer HTL1 may have a thickness in a range of about 30 Å to about 1,000 Å. When the first hole transport region HTR1 includes the first electron blocking layer (not shown), the first electron blocking layer (not shown) may have a thickness in a range of about 10 Å to about 1,000 Å. If the thicknesses of the first hole transport region HTR1, the first hole injection layer HIL1, the first hole transport layer HTL1, and the first electron blocking layer (not shown) satisfy the above-described ranges, satisfactory hole transport properties may be obtained without a substantial increase in driving voltage.

The hole transport regions HTR1 and HTR2 may each independently further include a p-dopant, in addition to the aforementioned materials. The p-dopant may be dispersed uniformly or non-uniformly in the first hole transport region HTR1. The p-dopant may include at least one of a halogenated metal compound, a quinone derivative, a metal oxide, and a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f:2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

The emission layers EML1 and EML2 may respectively include red emission layers EML-R1 and EML-R2 overlapping the first light emitting region PXA-R, green emission layers EML-G1 and EML-G2 overlapping the second light emitting region PXA-G, and blue emission layers EML-B1 and EML-B2 overlapping the third light emitting region PXA-B. The emission layers EML1 and EML2 may each independently have a thickness in a range of about 100 Å to about 1,000 Å. For example, the emission layers EML1 and EML2 may each independently have a thickness in a range of about 100 Å to about 300 Å. The emission layers EML1 and EML2 may each independently be a layer consisting of a single material, a layer including different materials, or a structure including multiple layers including different materials.

The emission layers EML1 and EML2 may each independently include an anthracene derivative, a pyrene derivative, a fluoranthene derivative, a chrysene derivative, a dihydrobenzanthracene derivative, or a triphenylene derivative. For example, the emission layers EML1 and EML2 may each independently include an anthracene derivative or a pyrene derivative.

Each of the emission layers EML1 and EML2 may be formed using various methods as a vacuum deposition method, a spin coating method, a cast method, a Langmuir-Blodgett (LB) method, an inkjet printing method, a laser printing method, and a laser induced thermal imaging (LITI) method.

The emission layers EML1 and EML2 may each include a host and a dopant. In an embodiment, the first emission layer EML1 may include a compound represented by Formula E-1. For example, the first blue emission layer EML-B1 may include a compound represented by Formula E-1. The compound represented by Formula E-1 may be used as a fluorescent host material.

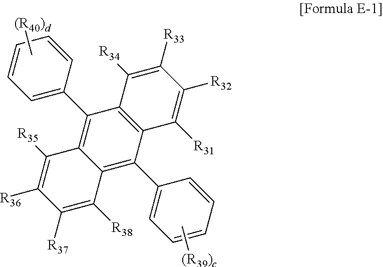

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

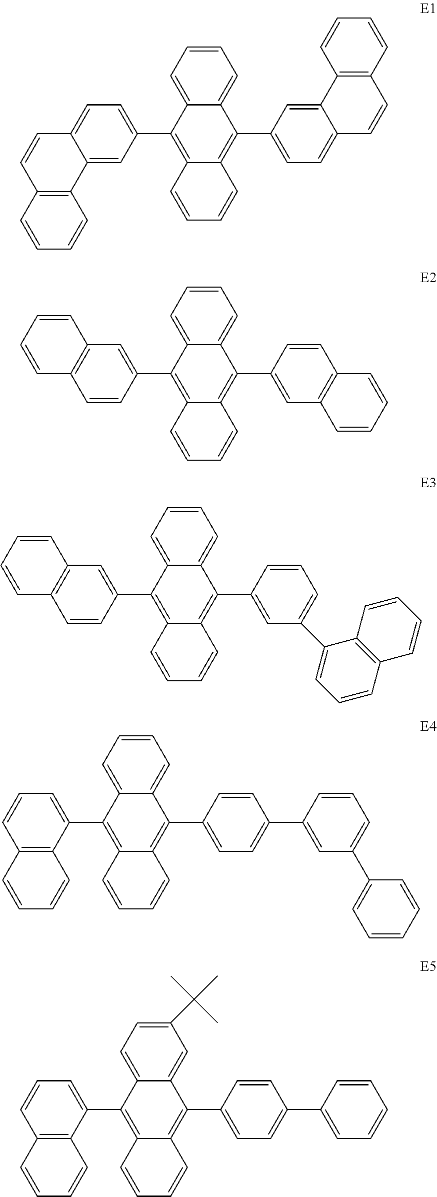

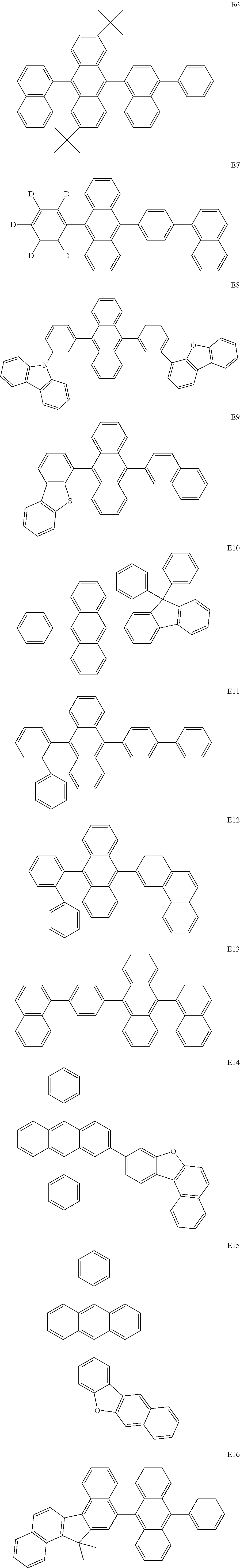

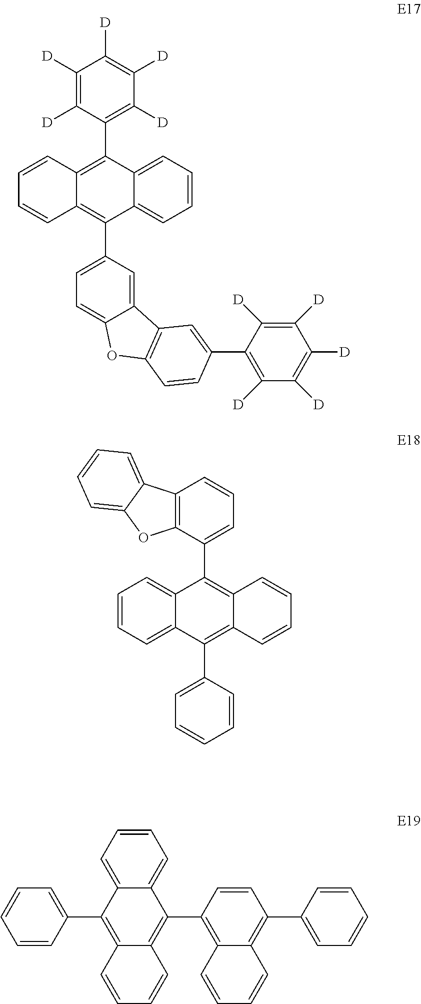

In an embodiment, the emission layers EML1 and EML2 may each independently include a compound represented by Formula E-2a and/or a compound represented by Formula E-2b. For example, the red emission layers EML-R1 and EML-R2, and the green emission layers EML-G1 and EML-G2 may each independently include a compound represented by Formula E-2a and/or a compound represented by Formula E-2b. The compound represented by Formula E-2a or the compound represented by Formula E-2b may be used as a phosphorescent host material.

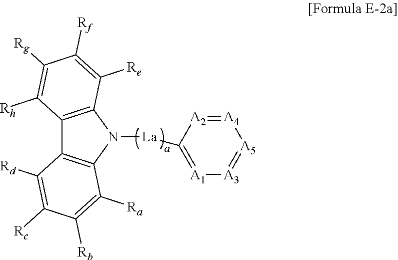

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

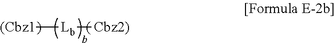

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10. When b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or the compound represented by Formula E-2b may be any compound selected from Compound Group E-2. However, the compounds listed in Compound Group E-2 are only examples, and the compound represented by Formula E-2a or the compound represented by Formula E-2b is not limited to Compound Group E-2.

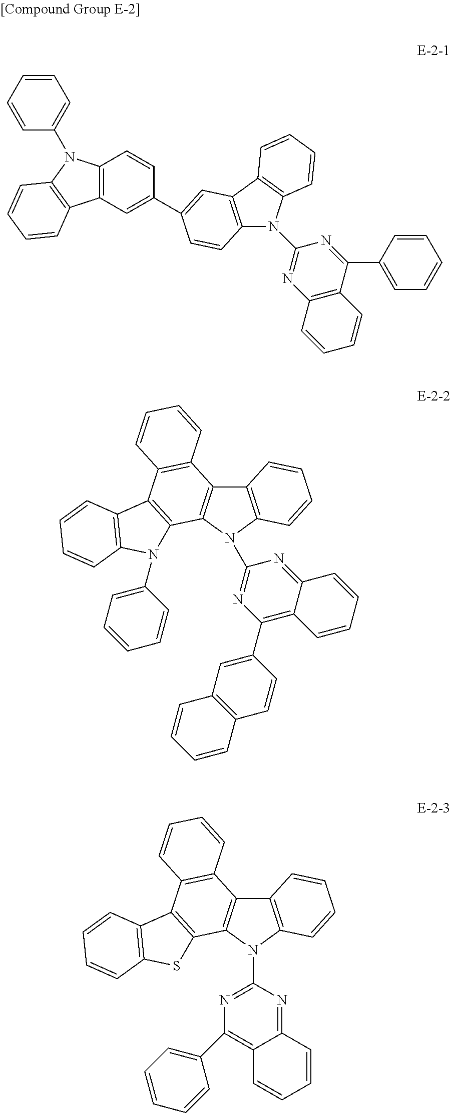 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

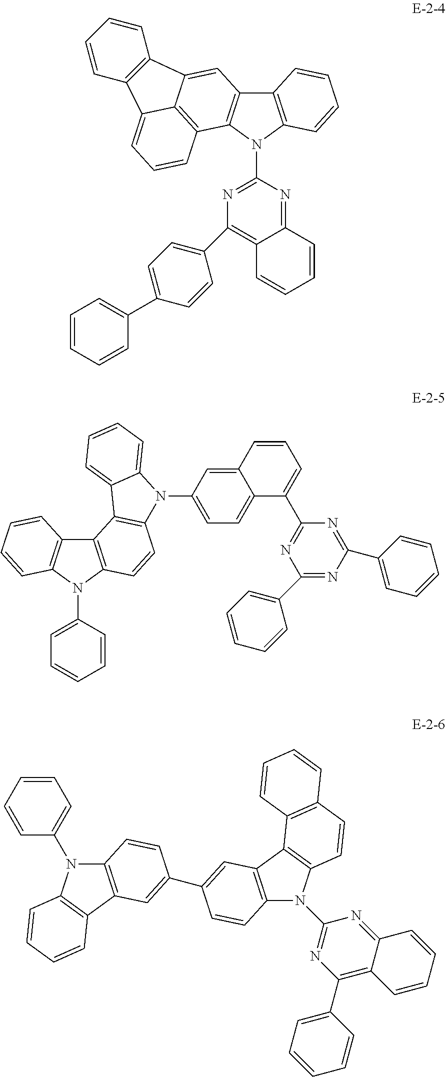 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

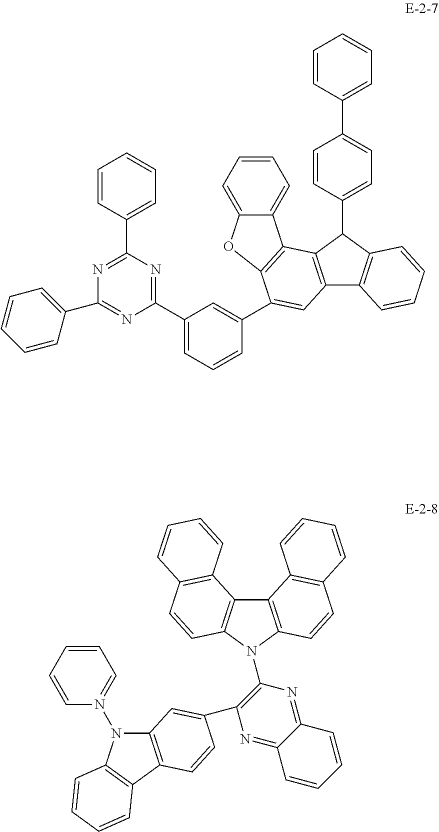

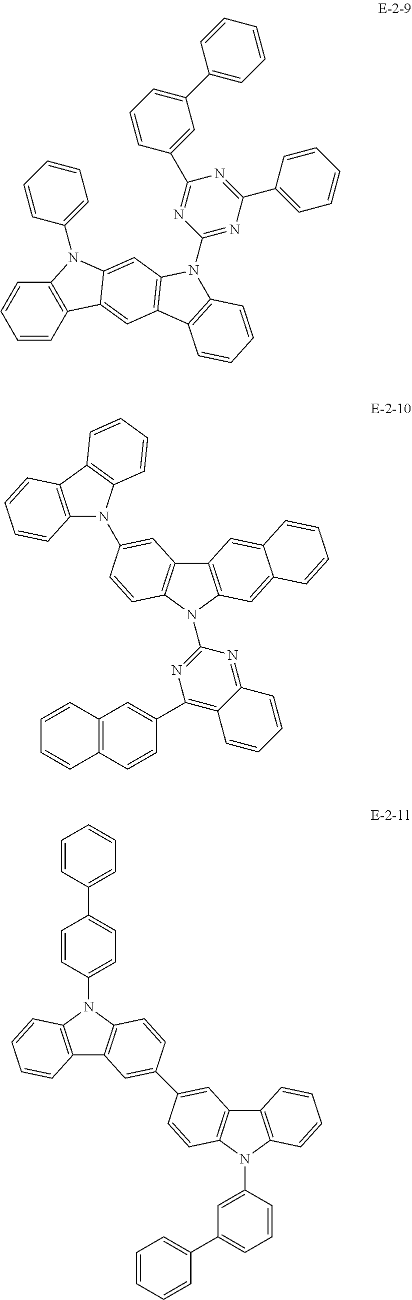 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

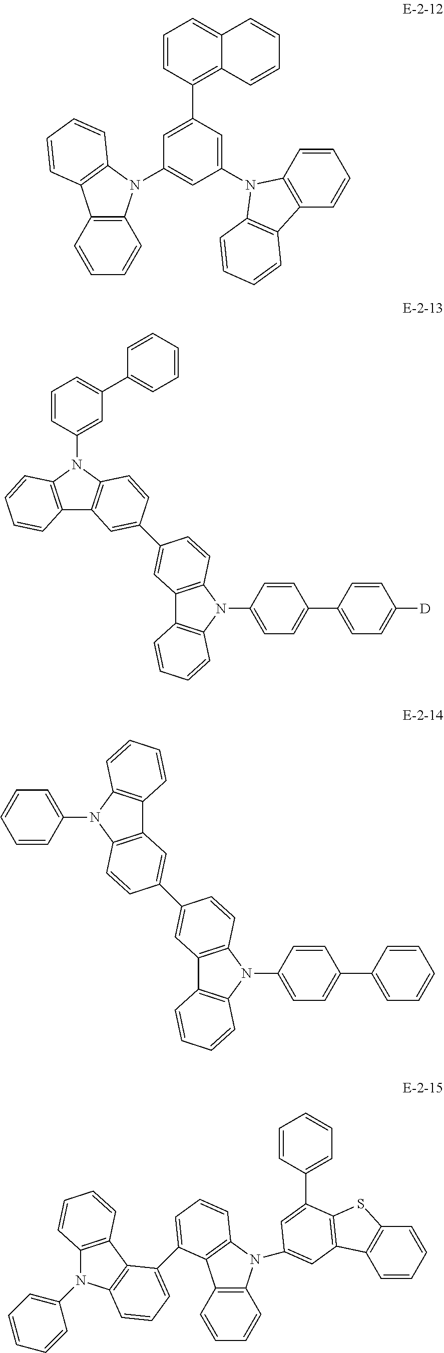 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

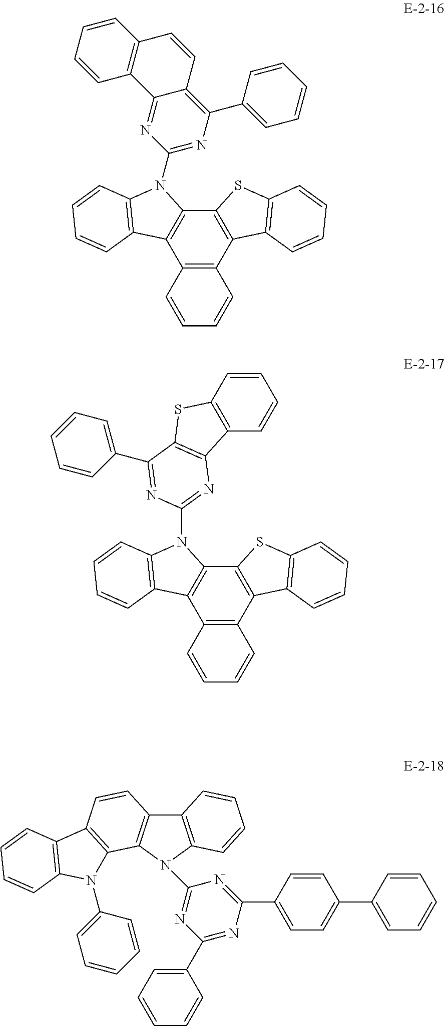 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

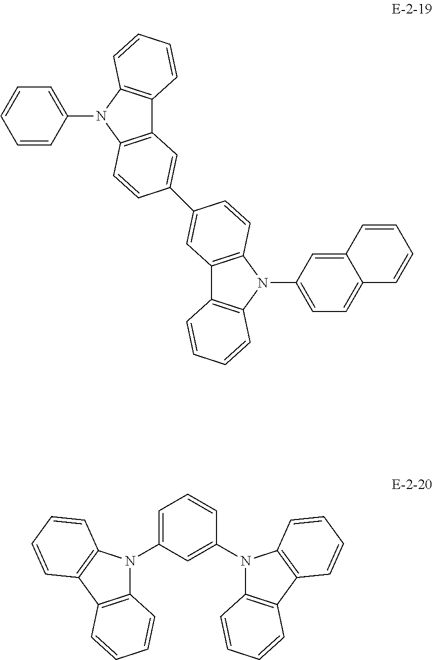 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1]

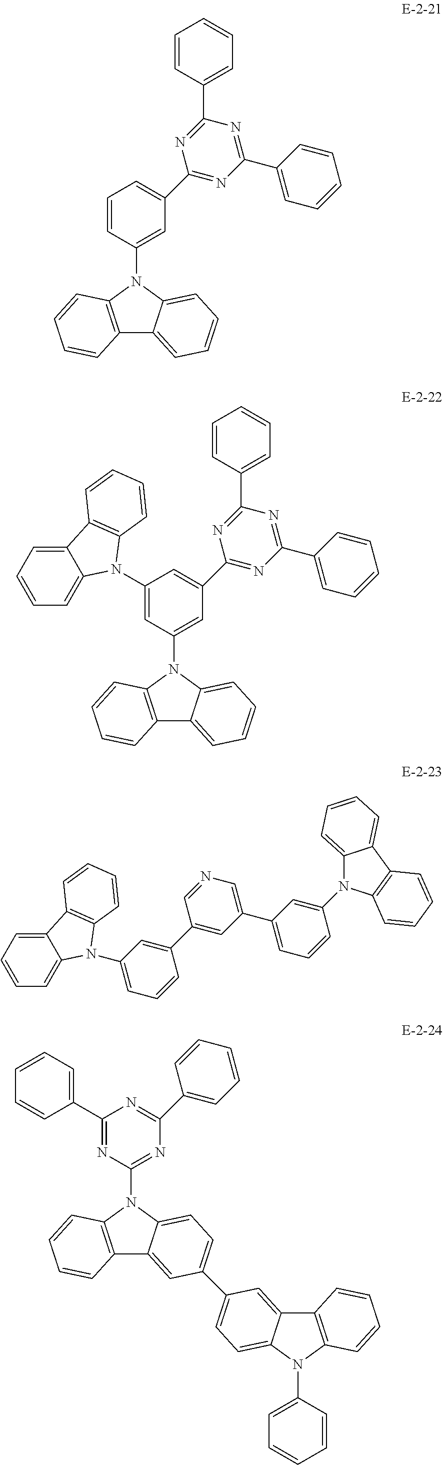 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layers EML1 and EML2 may each independently further include a material of the related art as a host material. For example, the emission layers EML1 and EML2 may each independently include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In an embodiment, the emission layers EML1 and EML2 may each independently include a compound represented by Formula M-a. For example, the red emission layers EML-R1 and EML-R2, and the green emission layers EML-G1 and EML-G2 may each independently include the compound represented by Formula M-a. The compound represented by Formula M-a may be used as a phosphorescent dopant material.

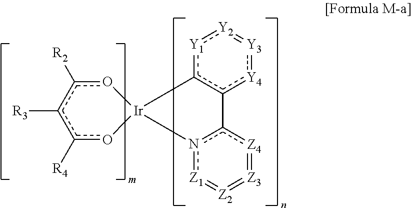

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

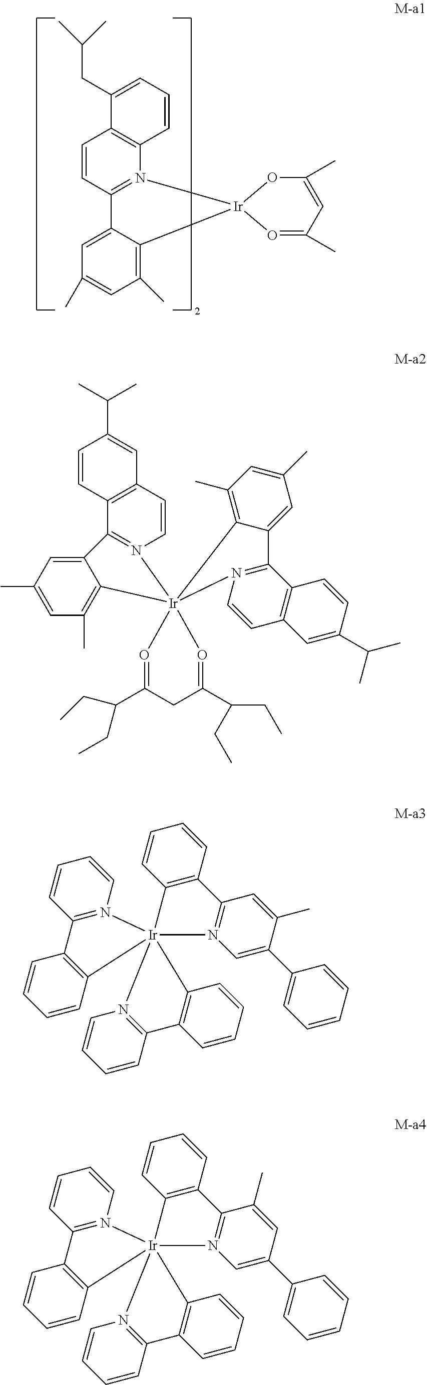

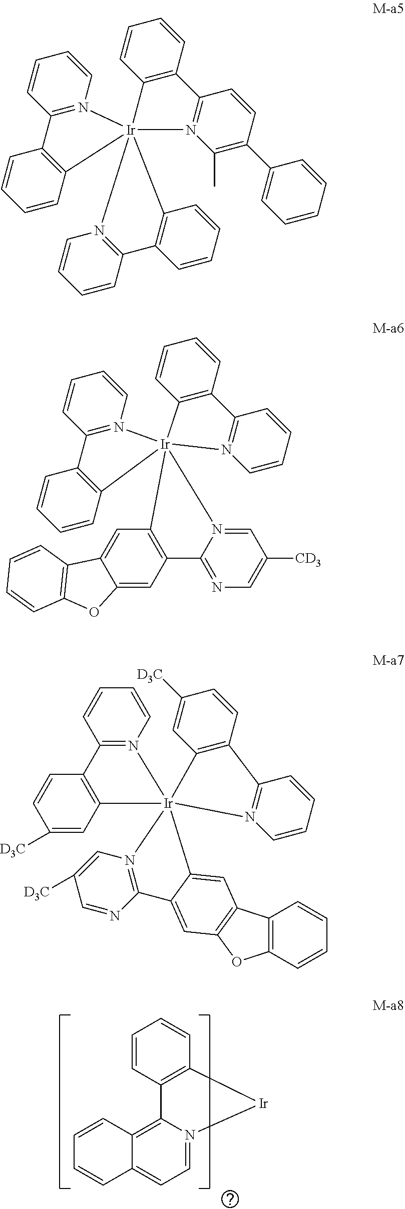

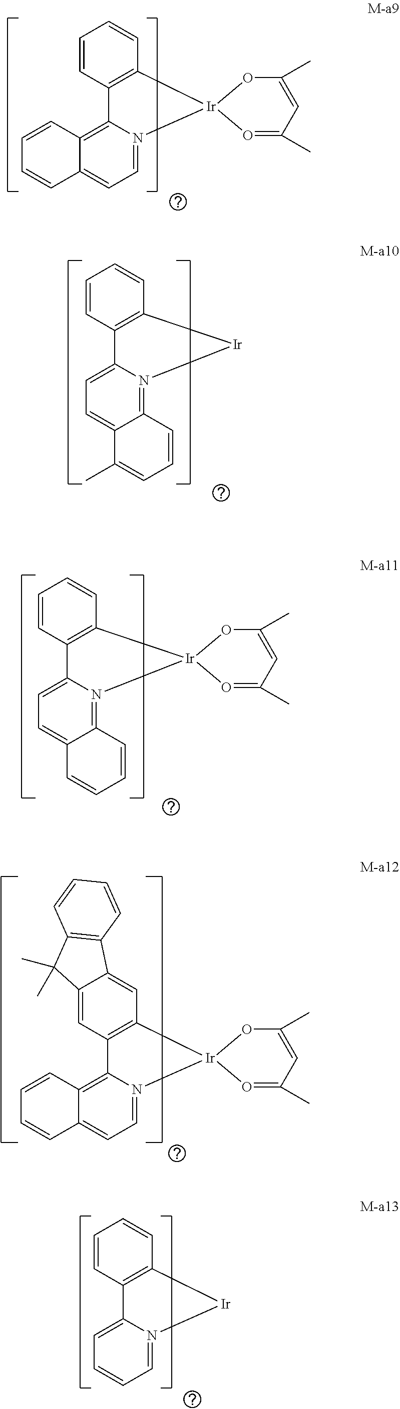

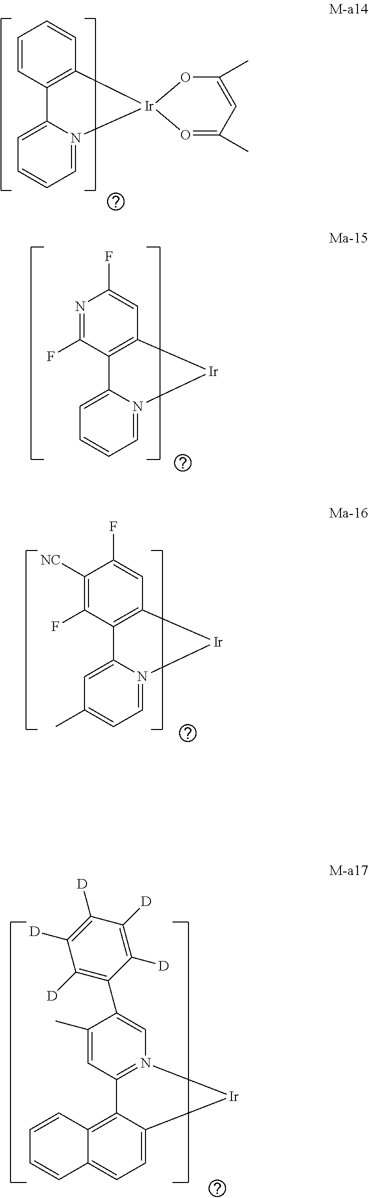

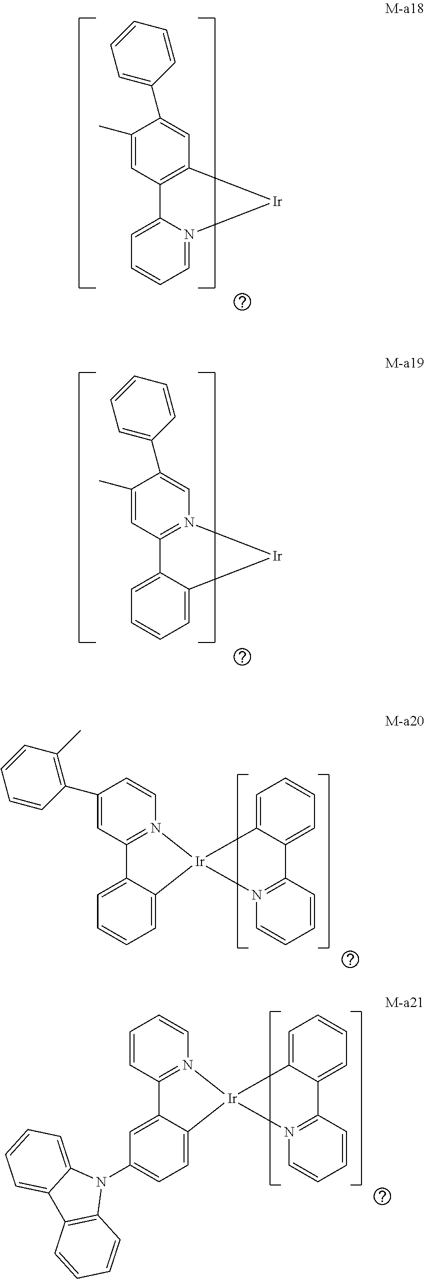

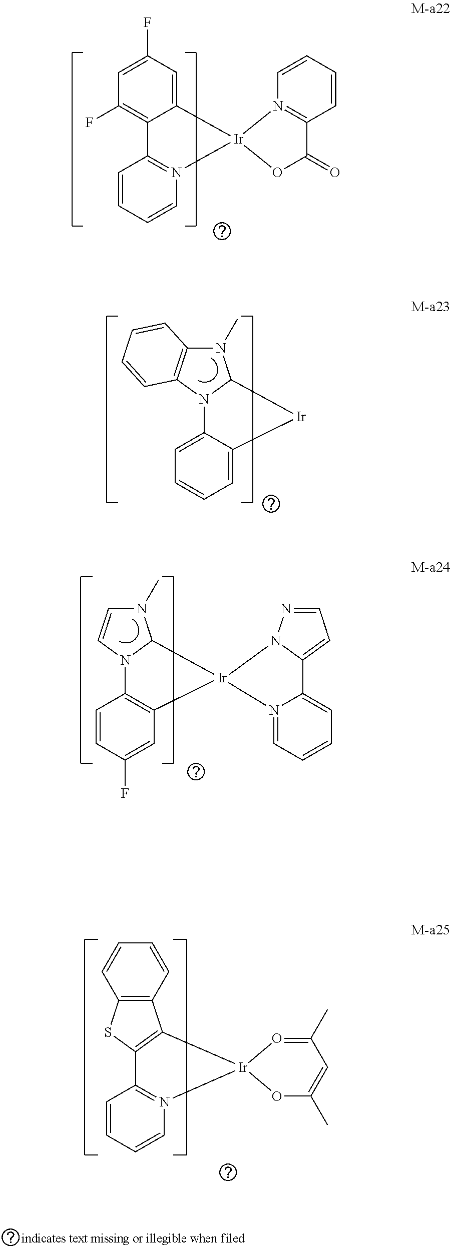

In an embodiment, the emission layers EML1 and EML2 may each independently include a compound represented by one of Formula F-a to Formula F-c. For example, the blue emission layers EML-B1 and EML-B2 may each independently include a compound represented by one of Formula F-a to Formula F-c. The compounds represented by one of Formula F-a to Formula F-c may be used as a fluorescent dopant material.

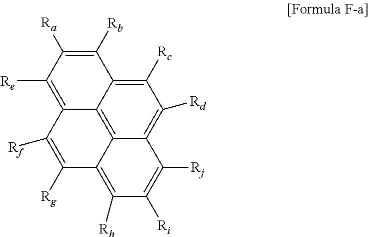

In Formula F-a, two of Rₐ to Rⱼ may each independently be substituted with a group represented by *—NAr₁Ar₂. The remainder of Rₐ to Rⱼ that are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may each independently be a heteroaryl group including O or S as a ring-forming atom.

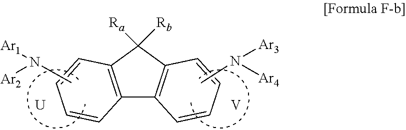

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may be a heteroaryl group including O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be present at the portion indicated by U or V, and when the number of U or V is 0, a fused ring may not be present at the portion indicated by U or V. When the number of U is 0 and the number of V is 1, or when the number of U is 1 and the number of V is 0, a fused ring having the fluorene core of Formula F-b may be a cyclic compound having four rings. When the number of U and V is each 0, a fused ring having the fluorene core of Formula F-b may be a cyclic compound having three rings. When the number of U and V is each 1, a fused ring having the fluorene core of Formula F-b may be a cyclic compound having five rings.

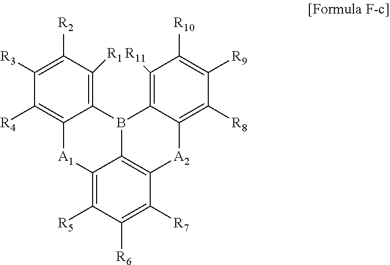

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula F-c, A₁ and A₂ may each independently be bonded to substituents of an adjacent ring to form a fused ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layers EML1 and EML2 may each independently further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi)), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layers EML1 and EML2 may each independently further include a phosphorescent dopant material of the related art. For example, the phosphorescent dopant may include a metal complex containing iridium (Ir), platinum (Pt), osmium (Os), gold (Au), titanium (Ti), zirconium (Zr), hafnium (Hf), europium (Eu), terbium (Tb), or thulium (Tm). For example, iridium(III) bis(4,6-difluorophenylpyridinato-N,C2′)picolinate) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In an embodiment, the emission layers EML1 and EML2 may each independently include a quantum dot material. The quantum dot may be a Group II-VI compound, a Group III-VI compound, a Group 1-III-VI compound, a Group III-V compound, a Group III-II-V compound, a Group IV-VI compound, a Group IV element, a Group IV compound, or a combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof; or any combination thereof.

Examples of a Group III-VI compound may include: a binary compound such as In₂S₃ or In₂Se₃; a ternary compound such as InGaS₃ or InGaSe₃; or any combination thereof.

Examples of a Group 1-III-VI compound may include: a ternary compound selected from the group consisting of AgInS, AgInS₂, CuInS, CuInS₂, AgGaS₂, CuGaS₂CuGaO₂, AgGaO₂, AgAlO₂, and a mixture thereof, a quaternary compound such as AgInGaS₂ or CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof, or any combination thereof. In an embodiment, a Group III-V compound may further include a Group II metal. Examples of a Group III-II-V compound may include InZnP, etc.

Examples of a Group IV-VI compound may include: a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, a quaternary compound selected from the group consisting of SnPbSSe, SnPbSeTe, SnPbSTe, and a mixture thereof, or any combination thereof. Examples of a Group IV element may include Si, Ge, and a mixture thereof. Examples of a Group IV compound may include a binary compound selected from the group consisting of SiC, SiGe, and a mixture thereof.

Each element included in a binary compound, a ternary compound, or a quaternary compound may be present in a particle at a uniform concentration distribution or at a non-uniform concentration distribution. For example, a formula may indicate the elements that are included in a compound, but an elemental ratio in the compound may vary. For example, AgInGaS₂ may indicate AgInₓGa₁₋ₓS₂ (where x is a real number of 0 to 1).

In embodiments, the quantum dot may have a single structure, or the quantum dot may have a core-shell structure in which a quantum dot surrounds another quantum dot. A material included in the core may be different from a material included in the shell.

The shell of a quantum dot may serve as a protection layer that prevents the chemical deformation of the core to maintain semiconductor properties, and/or may serve as a charging layer to impart electrophoresis properties to the quantum dot. The shell may be single-layered or multilayered. An interface between the core and the shell may have a concentration gradient in which the concentration of an element present in the shell decreases towards the core.

Examples of a shell of a quantum dots may include a metal oxide, a non-metal oxide, a semiconductor compound, or a combination thereof.

Examples of a metal oxide or a non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission spectrum equal to or less than about 45 nm. For example, the quantum dot may have a FWHM of an emission spectrum equal to or less than about 40 nm. For example, the quantum dot may have a FWHM of an emission spectrum equal to or less than about 30 nm. Within any of the above ranges, color purity or color reproducibility may be improved. Light that is emitted through a quantum dot may be emitted in all directions, so that a wide viewing angle may be improved.

The form of the quantum dot is not particularly limited, and may be any shape that is used in the related art. For example, a quantum dot may have a spherical shape, a pyramidal shape, a multi-arm shape, or a cubic shape, or the quantum dot may be in the form of nanoparticles, nanotubes, nanowires, nanofibers, nanoplate particles, etc.

As a size of a quantum dot is adjusted or an elemental ratio of a quantum dot compound is adjusted, the energy band gap may be accordingly controlled, so that light in various wavelength ranges may be obtained from a quantum dot emission layer. Therefore, by implementing quantum dots as described above (be using different sizes of quantum dots or different elemental ratios in quantum dot compounds), a light emitting element, which emits light in various wavelengths, may be implemented. For example, the size of a quantum dot or the elemental ratio of a quantum dot compound may be adjusted so that the quantum dots emit red light, green light, and/or blue light. In an embodiment, quantum dots may be configured to emit white light by combining various colors of light.

The electron transport regions ETR1 and ETR2 may each independently include at least one of a hole blocking layer (not shown), electron transport layers ETL1 and ETL2, and electron injection layers EIL1 and EIL2, but embodiments are not limited thereto.

The electron transport regions ETR1 and ETR2 may each independently be a layer consisting of a single material, a layer including different materials, or a structure including multiple layers including different materials.

In embodiments, the electron transport regions ETR1 and ETR2 may each independently have a single layer structure of electron injection layers EIL1 and EIL2 or electron transport layers ETL1 and ETL2, or may each independently have a single layer structure formed of an electron injection material and an electron transport material. In embodiments, the electron transport regions ETR1 and ETR2 may each independently have a single-layered structure formed of different materials, or may each independently have a structure in which electron transport layers ETL1 and ETL2/electron injection layers EIL1 and EIL2, or hole blocking layers (not shown)/electron transport layers ETL1 and ETL2/electron injection layers EIL1 and EIL2 are stacked in their respective stated order from the emission layers EML1 and EML2, but embodiments are not limited thereto. The electron transport regions ETR1 and ETR2 may each independently have a thickness, for example, in a range of about 1,000 Å to about 1,500 Å.

Each of the electron transport regions ETR1 and ETR2 may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport regions ETR1 and ETR2 may each independently include a compound represented by Formula ET-1:

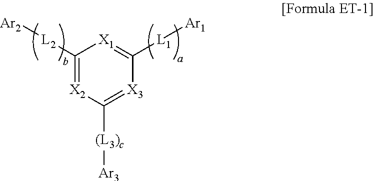

In Formula ET-1, at least one of X₁ to X₃ may each be N, and the remainder of X₁ to X₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-1, Ar₁ to Arₙ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport regions ETR1 and ETR2 may each independently include an anthracene-based compound. However, embodiments are not limited thereto, and the electron transport regions ETR1 and ETR2 may each independently include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benz[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport regions ETR1 and ETR2 may each independently include at least one compound selected from Compounds ET1 to ET38:

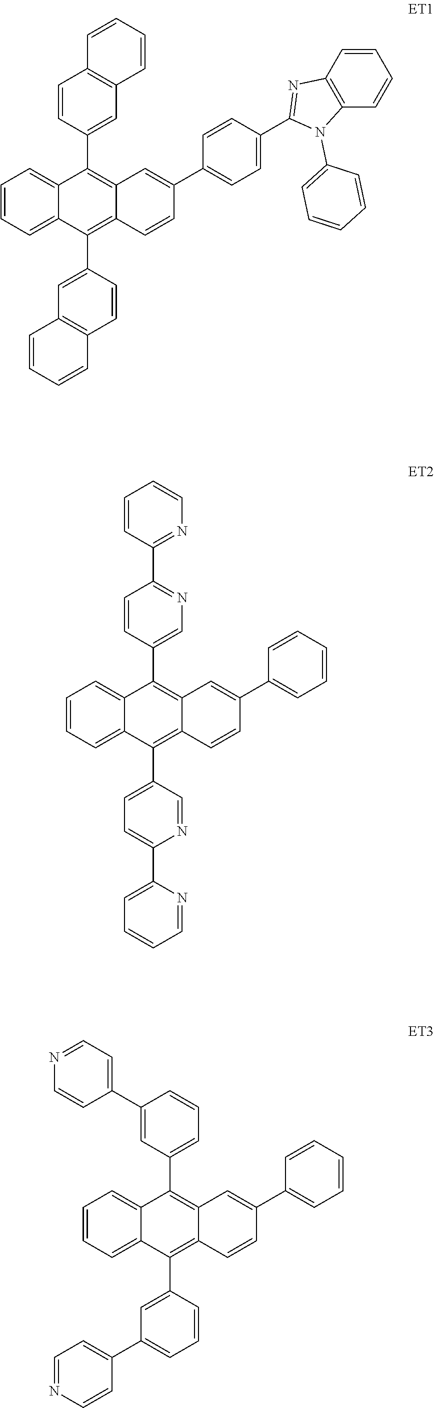 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

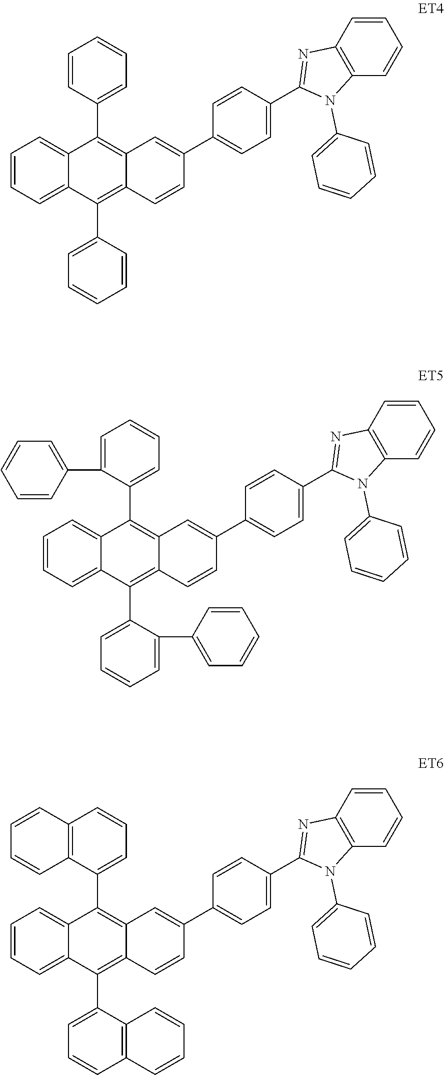 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

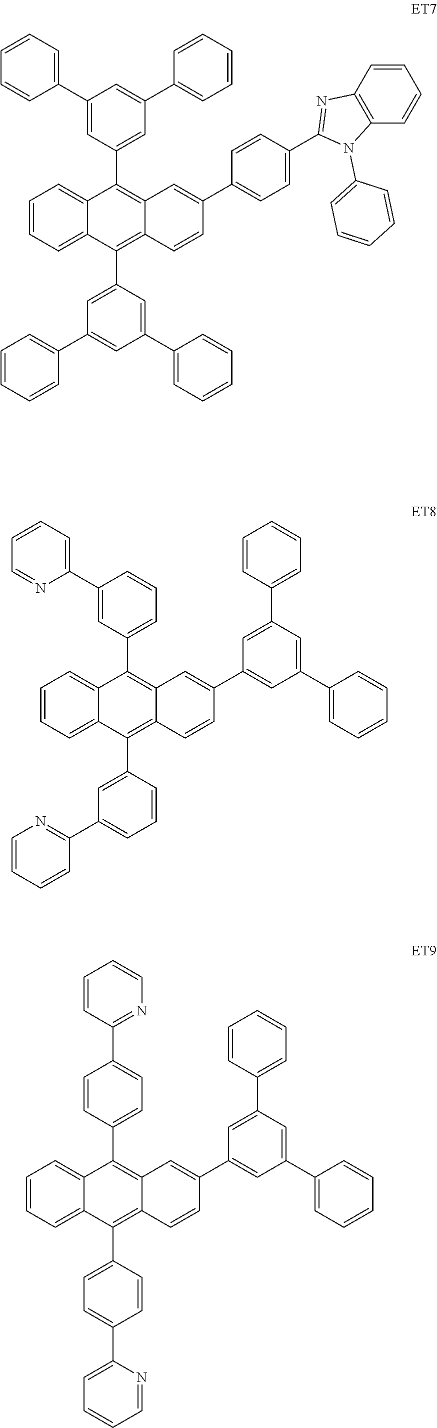 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

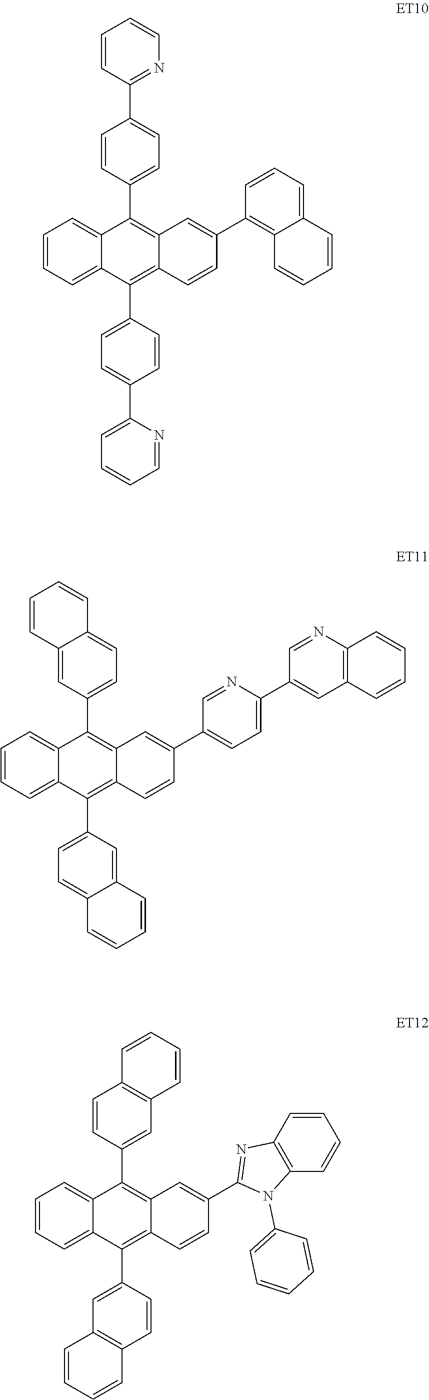 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

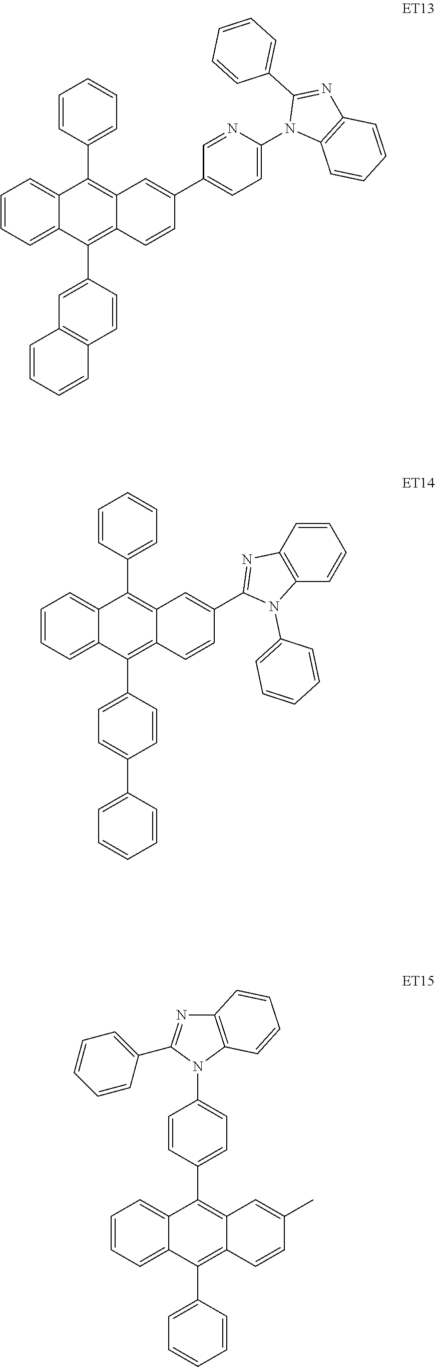 [SMILES: c1ccc(-c2c3ccccc3c(-c3ccc4ccccc4c3)c3ccc(-c4ccc(-n5c(-c6ccccc6)nc6ccccc65)nc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

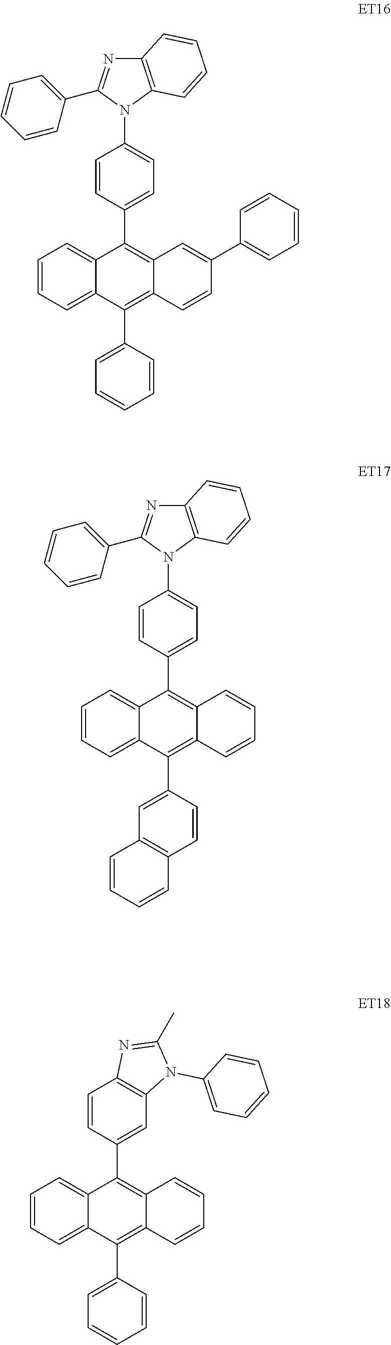 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3c4ccccc4c(-c4ccccc4)c4ccccc34)cc2n1-c1ccccc1]

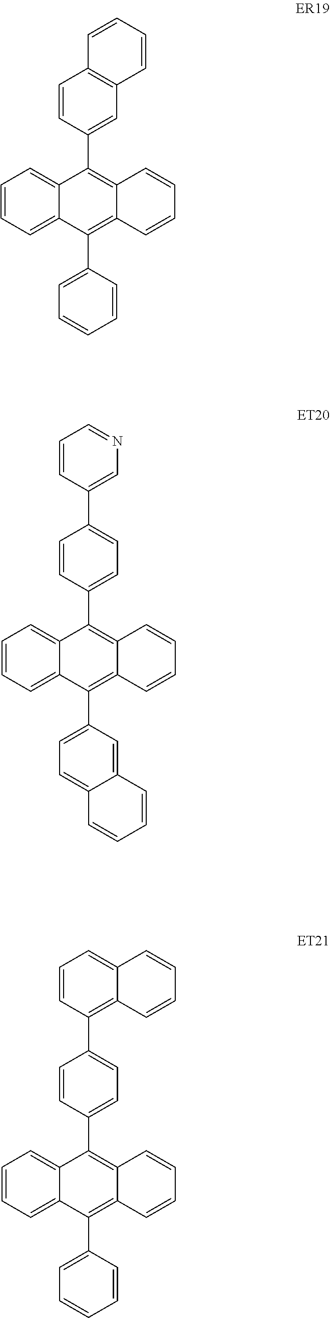

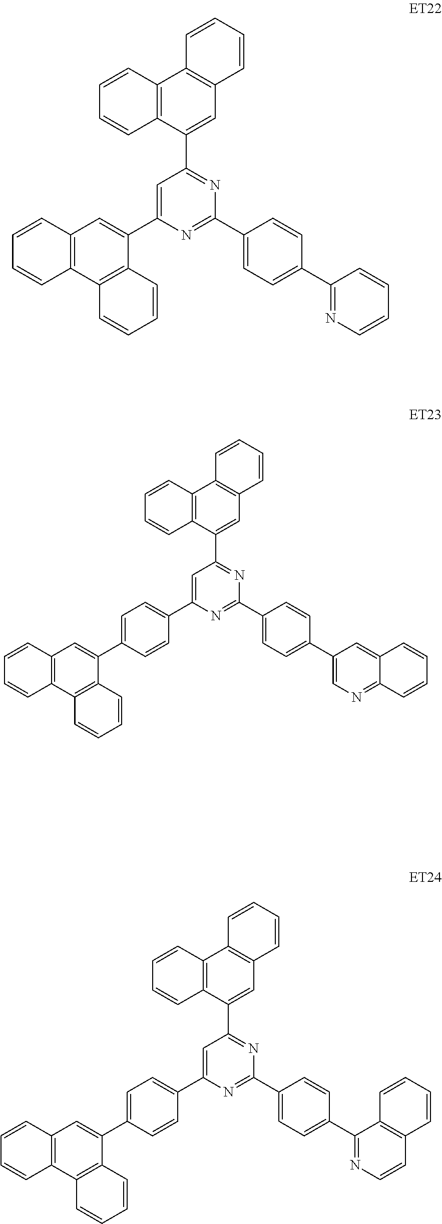 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5ccc(-c6cc7ccccc7c7ccccc67)cc5)cc(-c5cc6ccccc6c6ccccc56)n4)cc3)nccc2c1]

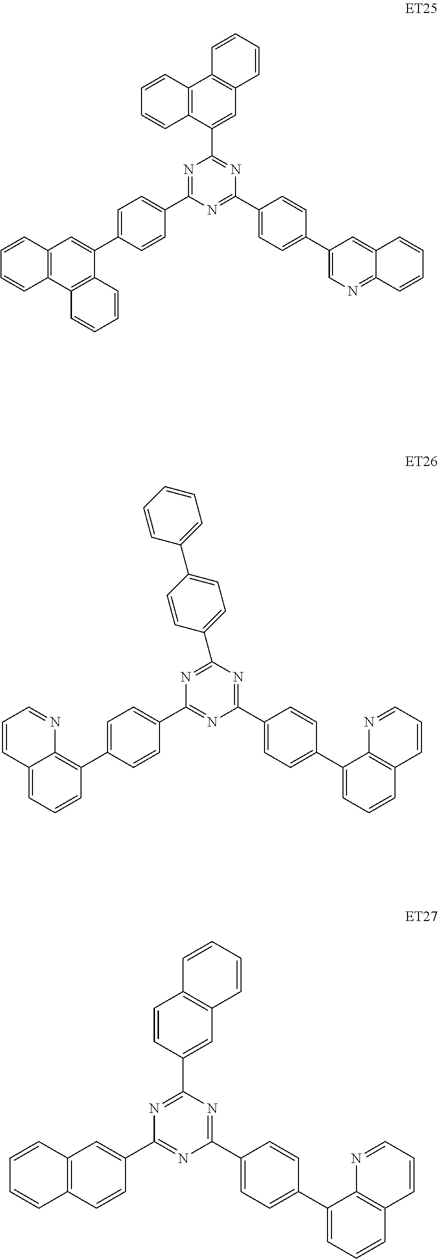 [SMILES: c1ccc2ncc(-c3ccc(-c4nc(-c5ccc(-c6cc7ccccc7c7ccccc67)cc5)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

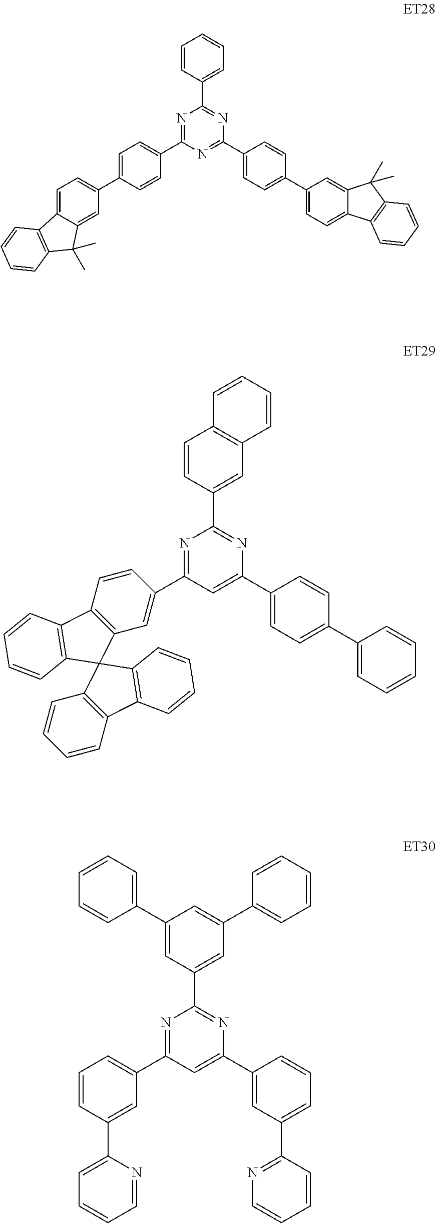 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)cc(-c4cccc(-c5ccccn5)c4)n3)c2)cc1]

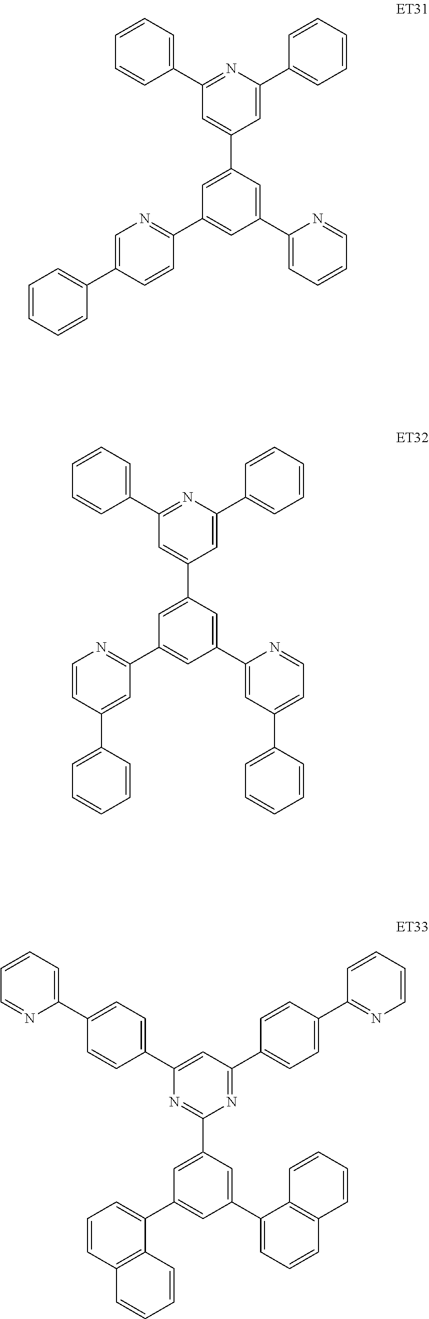 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

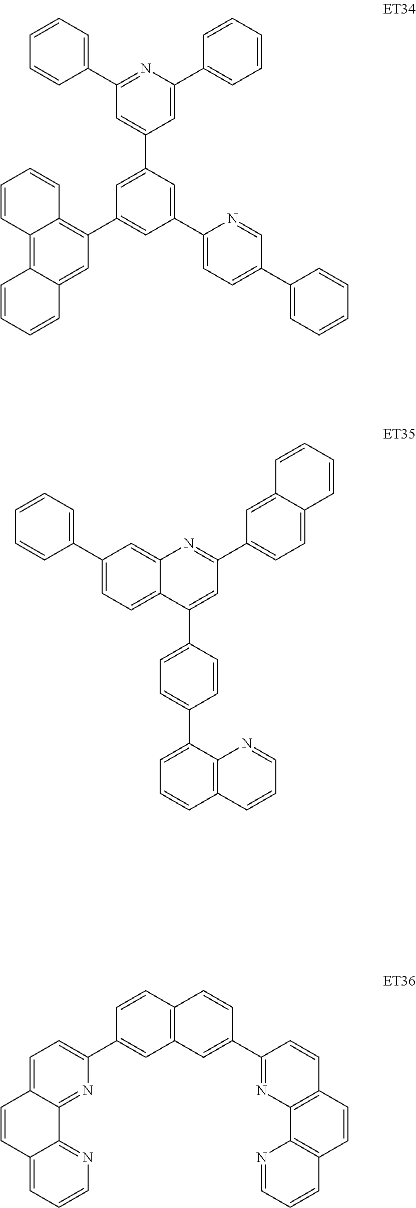 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

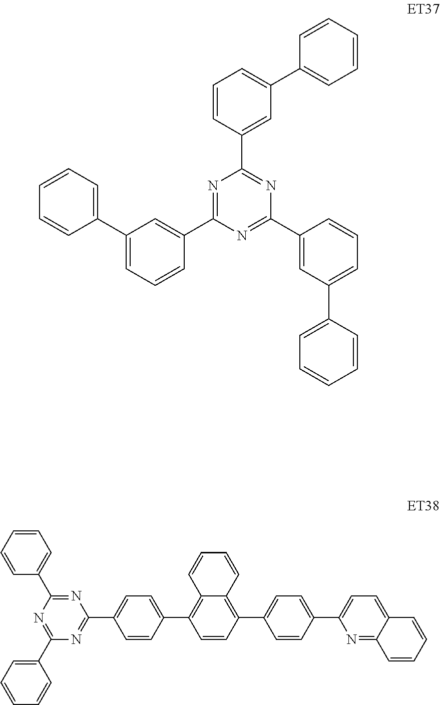 [SMILES: c1ccc(-c2cccc(-c3nc(-c4cccc(-c5ccccc5)c4)nc(-c4cccc(-c5ccccc5)c4)n3)c2)cc1 ; c1ccc(-c2nc(-c3ccccc3)nc(-c3ccc(-c4ccc(-c5ccc(-c6ccc7ccccc7n6)cc5)c5ccccc45)cc3)n2)cc1]

In an embodiment, the electron transport regions ETR1 and ETR2 may each independently include a metal halide such as LiF, NaCl, CsF, RbCl, RbI, CuI, and KI; a lanthanide metal such as Yb; or a co-deposited material of a metal halide and a lanthanide metal. For example, the first electron transport region ETR1 may include K:Yb, RbI:Yb, LiF:Yb, etc., as a co-deposited material. The electron transport regions ETR1 and ETR2 may each include a metal oxide such as Li₂O or BaO, or 8-hydroxyl-lithium quinolate (Liq), etc., but embodiments are not limited thereto. The electron transport region ETR may also be formed of a mixture material that includes an electron transport material and an insulating organometallic salt. The insulating organometallic salt may be a material having an energy band gap equal to or greater than about 4 eV. For example, the insulating organometallic salt may include a metal acetate, a metal benzoate, a metal acetoacetate, a metal acetylacetonate, or a metal stearate.

The electron transport regions ETR1 and ETR2 may each independently further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen), in addition to the aforementioned materials, but embodiments are not limited thereto.

The electron transport regions ETR1 and ETR2 may each independently include the above-described electron transport compounds in at least one of the electron injection layers EIL1 and EIL2, the electron transport layers ETL1 and ETL2, and the hole blocking layers (not shown).

When the electron transport regions ETR1 and ETR2 include the electron transport layers ETL1 and ETL2, respectively, the electron transport layers ETL1 and ETL2 may each independently have a thickness in a range of about 100 Å to about 1,000 Å. For example, the electron transport layers ETL1 and ETL2 may each independently have a thickness in a range of about 150 Å to about 500 Å. If the thicknesses of the electron transport layers ETL1 and ETL2 each satisfy any of the above-described ranges, satisfactory electron transport properties may be obtained without a substantial increase in driving voltage. When the electron transport regions ETR1 and ETR2 includes the electron injection layers EIL1 and EIL2, respectively, the electron injection layers EIL1 and EIL2 may each independently have a thickness in a range of about 1 Å to about 100 Å. For example, the electron injection layers EIL1 and EIL2 may each independently have a thickness in a range of about 3 Å to about 90 Å. If the thicknesses of the electron injection layers EIL1 and EIL2 each satisfy any of the above-described ranges, satisfactory electron injection properties may be obtained without a substantial increase in driving voltage.

In FIGS. 3A to 3D, the respective components constituting the first light emitting unit OL1 and the second light emitting unit OL2 are illustrated to correspond to each other, but a stacked structure of each of the first light emitting unit OL1 and the second light emitting unit OL2 is not limited to the configuration as illustrated therein, and may be provided in various combinations according to the display quality characteristics that are required in the light emitting element ED. For example, in the light emitting element ED according to an embodiment, the second hole transport region HTR2 of the second light emitting unit OL2 may have a structure that includes the second emission-auxiliary layers SE-R2, SE-G2, and SE-B2, and the first hole transport region HTR1 of the first light emitting unit OL1 may have a structure that does not include the first emission-auxiliary layers SE-R1, SE-G1, and SE-B1. For example, in the light emitting element ED according to another embodiment, the second electron transport region ETR2 of the second light emitting unit OL2 may have a structure that includes the second electron injection layer EIL2, and the first electron transport region ETR1 of the first light emitting unit OL1 may have a structure that does not include the first electron injection layer EIL1.

The charge generation unit CGL is disposed between the first light emitting unit OL1 and the second light emitting unit OL2. The charge generation unit CGL may generate charges (electrons and holes) by forming a complex through an oxidation-reduction reaction when a voltage is applied thereto. The charge generation unit CGL may provide the generated charges to each of the adjacent light emitting units OL1 and OL2. The charge generation unit CGL may increase the efficiency of current generated in each of the adjacent light emitting units OL1 and OL2, and may serve to adjust the balance of charges between the adjacent light emitting units OL1 and OL2.

The charge generation unit CGL includes a p-type charge generation layer p-CGL and an n-type charge generation layer n-CGL. The charge generation unit CGL may have a stacked structure in which the p-type charge generation layer p-CGL and the n-type charge generation layer n-CGL contact (for example, directly contact) each other. The charge generation unit CGL may have a structure in which the n-type charge generation layer n-CGL and the p-type charge generation layer p-CGL are sequentially stacked from the first light emitting unit OL1.

The n-type charge generation layer n-CGL may be a charge generation layer that provides electrons to the adjacent light emitting units OL1 and OL2. The n-type charge generation layer n-CGL may include an n-dopant. The n-type charge generation layer n-CGL may be a layer in which the n-dopant is doped in abase material. The p-type charge generation layer p-CGL may be a charge generation layer that provides holes to the adjacent light emitting units OL1 and OL2. The p-type charge generation layer p-CGL may include a p-dopant. The p-type charge generation layer p-CGL may be a layer in which the p-dopant is doped in the base material. Although not illustrated in the drawings, the charge generation unit CGL may further include a buffer layer disposed between the n-type charge generation layer n-CGL and the p-type charge generation layer p-CGL.

The charge generation layers n-CGL and p-CGL may each include an n-type aryl amine-based material or a p-type metal oxide. For example, the charge generation layers n-CGL and p-CGL may each independently include a charge generation compound including an aryl amine-based organic compound, a carbazole-based compound, a metal, a metal oxide, a metal carbide, a metal fluoride, or a mixture thereof.

For example, the aryl amine-based organic compound may be N,N′-di(naphthalene-1-yl)-N,N′-diphenyl-benzidine (α-NPD), 4,4′,4″-tris[N(2-naphthyl)-N-phenylamino]-triphenylamine (2-TNATA), 4,4′4″-tris(N,N-diphenylamino)triphenylamine (TDATA), 4,4′,4″-[tris(3-methylphenyl)phenylamino]triphenylamine (m-TDATA), spiro-TAD, or spiro-NPB. For example, the carbazole-based compound may be 4,4′-bis(carbazol-9-yl)biphenyl (CBP). For example, the metal may be cesium (Cs), molybdenum (Mo), vanadium (V), titanium (Ti), tungsten (W), barium (Ba), or lithium (Li). Examples of a metal oxide, a metal carbide, or a metal fluoride may include Re₂O₇, MoO₃, V₂O₅, WO₃, TiO₂, Cs₂CO₃, BaF, LiF, or CsF.

The second electrode EL2 is provided on the second electron transport region ETR2. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgAg). In an embodiment, the second electrode EL2 may have a multi-layered structure including a reflective layer or a transflective layer formed of the above-described materials, and a transparent conductive layer formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, resistance of the second electrode EL2 may decrease.

The first capping layer CPL1 is disposed on the second electrode EL2 of the light emitting element ED, and the second capping layer CPL2 is disposed on the first capping layer CPL1. The first capping layer CPL1 may be directly disposed on the second electrode EL2, and the second capping layer CPL2 may be directly disposed on the first capping layer CPL1.

The first capping layer CPL1 includes a first compound represented by Formula 1. In an embodiment, the first capping layer CPL1 may be an organic layer that includes the first compound.

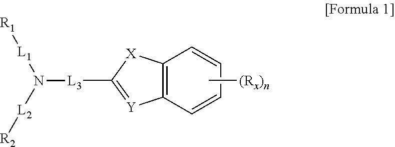

In Formula 1, L₁ to L₃ may each independently be a direct linkage, a substituted or unsubstituted arylene group having 6 to 12 ring-forming carbon atoms, or a substituted or unsubstituted heteroarylene group having 5 to 11 ring-forming carbon atoms. For example, L₁ to L₃ may each independently be a direct linkage, an unsubstituted phenylene group, an unsubstituted divalent biphenyl group, or an unsubstituted divalent terphenyl group.

In Formula 1, X may be O or S; and Y may be N or C(R_{y}).

In Formula 1, R₁, R₂, Rₓ, and R_{y} may each independently be a hydrogen atom, a deuterium atom, a halogen atom, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In an embodiment, R₁ and R₂ may each independently be a substituted or unsubstituted amine group, a substituted or unsubstituted phenyl group, a substituted or unsubstituted naphthyl group, a substituted or unsubstituted benzoxazole group, a substituted or unsubstituted benzothiazole group, a substituted or unsubstituted benzofuran group, or a substituted or unsubstituted benzothiophene group. In an embodiment, Rₓ and R_{y} may each independently be a hydrogen atom or a deuterium atom. In an embodiment, R₁ or R₂ may be an amine group substituted with an aryl group or a heteroaryl group, so that the first compound represented by Formula 1 may be a diamine compound.

In Formula 1, n may be an integer from 0 to 4. If n is 0, the first compound may not be substituted with Rₓ. A case where n is 4 and four Rₓ groups are all hydrogen atoms may be the same as a case where n is 0. If n is 2 or greater, multiple Rₓ groups may all be the same, or at least one thereof may be different from the remainder.

In an embodiment, the first compound represented by Formula 1 may be represented by any one of Formula 1-1 to Formula 1-3:

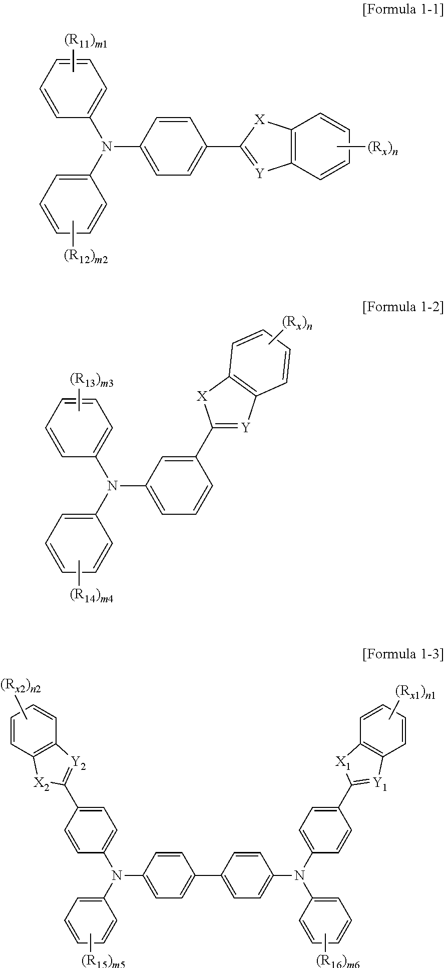

In Formula 1-1 to Formula 1-3, R₁₁ to R₁₆ may each independently be a hydrogen atom, a deuterium atom, a halogen atom, a cyano group, a substituted or unsubstituted amine group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, R₁₁ to R₁₆ may each independently be a substituted or unsubstituted phenyl group, a substituted or unsubstituted terphenyl group, a substituted or unsubstituted naphthyl group, a substituted or unsubstituted benzoxazole group, a substituted or unsubstituted benzothiazole group, a substituted or unsubstituted benzofuran group, or a substituted or unsubstituted benzothiophene group.

In Formula 1-3, Rₓ₁ and Rₓ₂ may each independently be a hydrogen atom, a deuterium atom, a halogen atom, a substituted or unsubstituted amine group, a substituted or unsubstituted alkyl group having 1 to 20 carbon atoms, a substituted or unsubstituted alkenyl group 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₓ₁ and Rₓ₂ may each independently be a hydrogen atom or a deuterium atom.

In Formula 1-1 to Formula 1-3, X₁ and X₂ may each independently be O or S; and Y₁ and Y₂ may each independently be N or C(R_{y}).

In Formula 1-1 to Formula 1-3, m1 to m6 may each independently be an integer from 0 to 5. If m1 to m6 are each 0, the first compound may not be substituted with R₁₁ to R₁₆, respectively. A case where m1 to m6 are each 5 and five groups of each of R₁₁ to R₁₆ are all hydrogen atoms may be the same as a case where m1 to m6 are each 0. If m1 to m6 are each 2 or greater, multiple groups of each of R₁₁ to R₁₆ may all be the same or at least one thereof may be different from the remainder.

In Formula 1-3, n1 and n2 may each independently be an integer from 0 to 4. If n1 and n2 are each 0, the first compound may not be substituted with Rₓ₁ and Rₓ₂, respectively. A case where n1 and n2 are each 4 and four Rₓ₁ groups and four Rₓ₂ groups are all hydrogen atoms may be the same as a case where n1 and n2 are each 0. If n1 and n2 are each 2 or greater, multiple Rₓ₁ groups and multiple Rₓ₂ groups may all be the same or at least one thereof may be different from the remainder.

In Formula 1-1 to Formula 1-3, X, Y, Rₓ, R_{y}, and n are the same as described in Formula 1.

In an embodiment, the first compound may be any compound selected from Compound Group 1. In an embodiment, in the light emitting element ED, the first capping layer CPL1 may include at least one first compound selected from Compound Group 1.

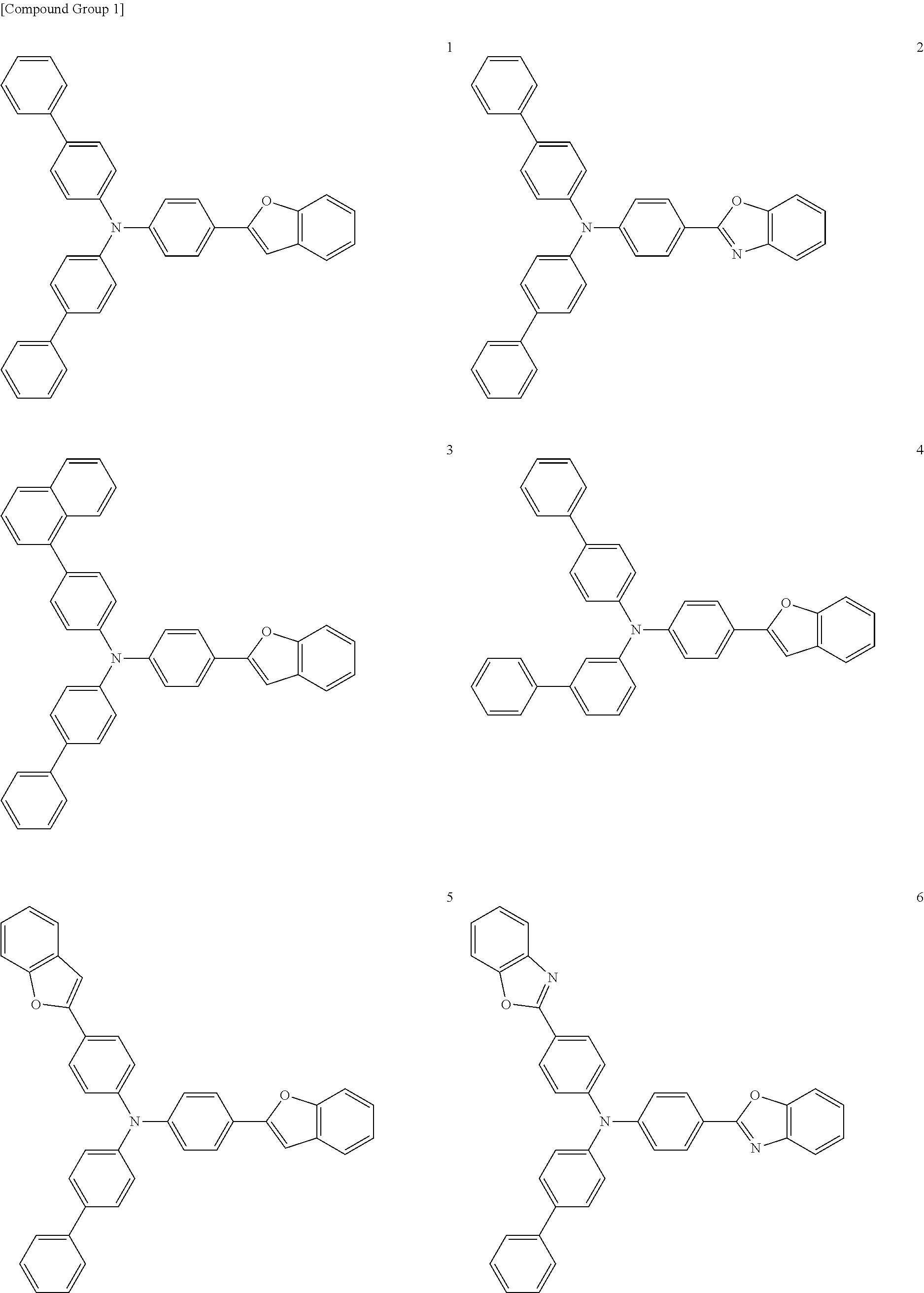 [SMILES: c1ccc(-c2ccc(N(c3ccc(-c4ccccc4)cc3)c3ccc(-c4cc5ccccc5o4)cc3)cc2)cc1 ; c1ccc(-c2ccc(N(c3ccc(-c4ccccc4)cc3)c3ccc(-c4nc5ccccc5o4)cc3)cc2)cc1 ; c1ccc(-c2ccc(N(c3ccc(-c4cc5ccccc5o4)cc3)c3ccc(-c4cccc5ccccc45)cc3)cc2)cc1 ; c1ccc(-c2ccc(N(c3ccc(-c4cc5ccccc5o4)cc3)c3cccc(-c4ccccc4)c3)cc2)cc1 ; c1ccc(-c2ccc(N(c3ccc(-c4cc5ccccc5o4)cc3)c3ccc(-c4cc5ccccc5o4)cc3)cc2)cc1 ; c1ccc(-c2ccc(N(c3ccc(-c4nc5ccccc5o4)cc3)c3ccc(-c4nc5ccccc5o4)cc3)cc2)cc1]

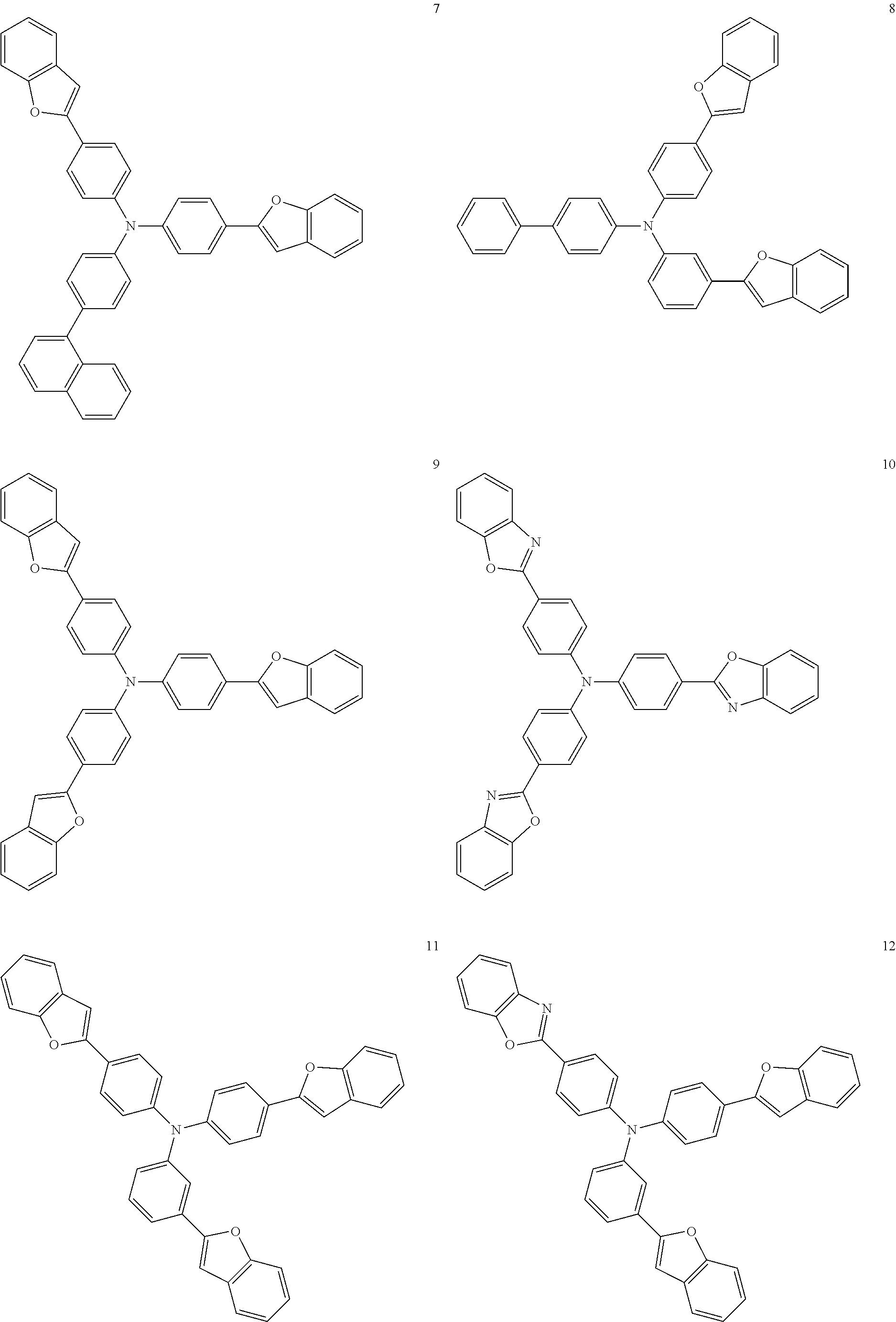 [SMILES: c1ccc2oc(-c3ccc(N(c4ccc(-c5cc6ccccc6o5)cc4)c4ccc(-c5cccc6ccccc56)cc4)cc3)cc2c1 ; c1ccc(-c2ccc(N(c3ccc(-c4cc5ccccc5o4)cc3)c3cccc(-c4cc5ccccc5o4)c3)cc2)cc1 ; c1ccc2oc(-c3ccc(N(c4ccc(-c5cc6ccccc6o5)cc4)c4ccc(-c5cc6ccccc6o5)cc4)cc3)cc2c1 ; c1ccc2oc(-c3ccc(N(c4ccc(-c5nc6ccccc6o5)cc4)c4ccc(-c5nc6ccccc6o5)cc4)cc3)nc2c1 ; c1cc(-c2cc3ccccc3o2)cc(N(c2ccc(-c3cc4ccccc4o3)cc2)c2ccc(-c3cc4ccccc4o3)cc2)c1 ; c1cc(-c2cc3ccccc3o2)cc(N(c2ccc(-c3cc4ccccc4o3)cc2)c2ccc(-c3nc4ccccc4o3)cc2)c1]

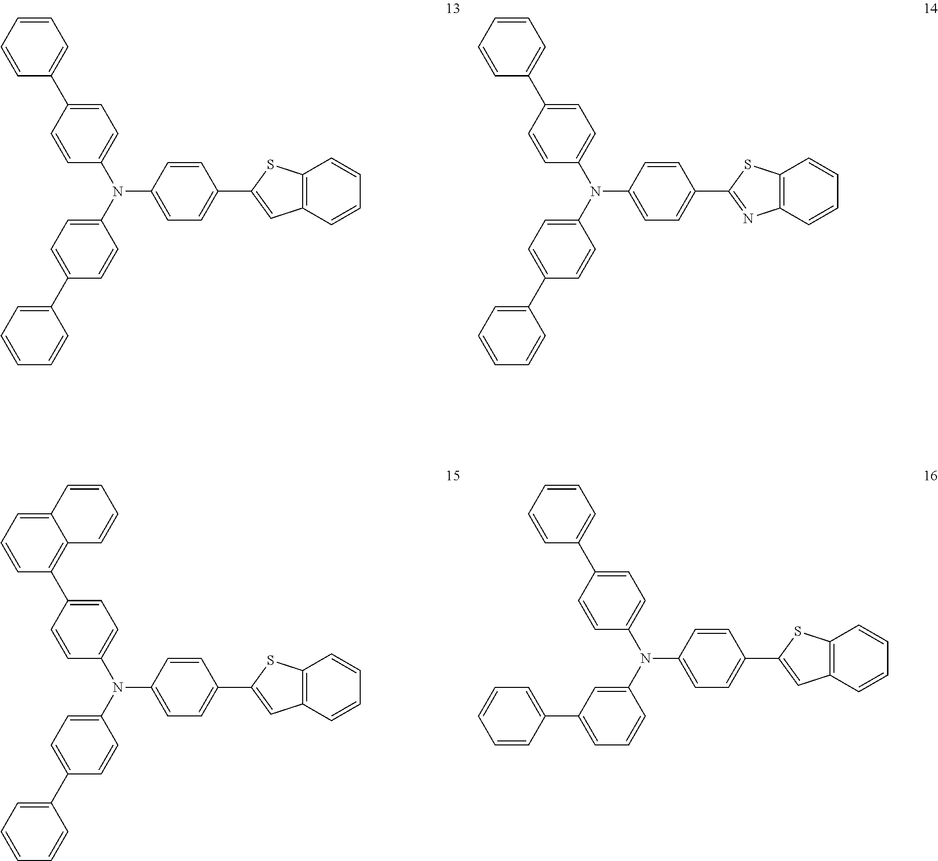 [SMILES: c1ccc(-c2ccc(N(c3ccc(-c4ccccc4)cc3)c3ccc(-c4cc5ccccc5s4)cc3)cc2)cc1 ; c1ccc(-c2ccc(N(c3ccc(-c4ccccc4)cc3)c3ccc(-c4nc5ccccc5s4)cc3)cc2)cc1 ; c1ccc(-c2ccc(N(c3ccc(-c4cc5ccccc5s4)cc3)c3ccc(-c4cccc5ccccc45)cc3)cc2)cc1 ; c1ccc(-c2ccc(N(c3ccc(-c4cc5ccccc5s4)cc3)c3cccc(-c4ccccc4)c3)cc2)cc1]

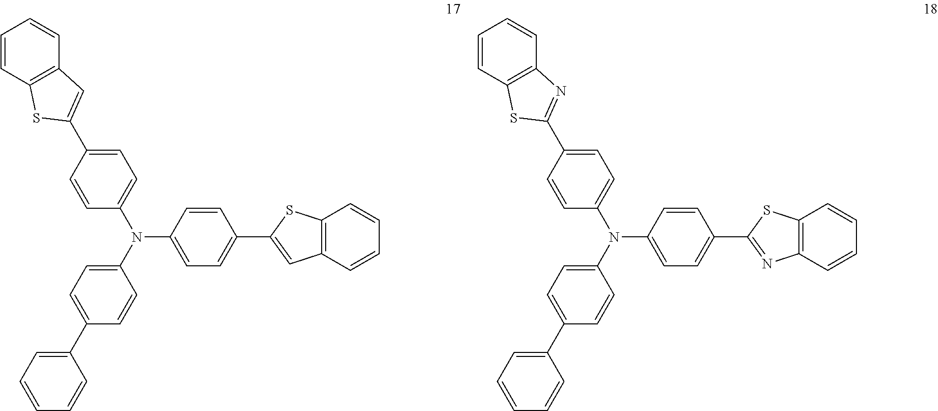 [SMILES: c1ccc(-c2ccc(N(c3ccc(-c4cc5ccccc5s4)cc3)c3ccc(-c4cc5ccccc5s4)cc3)cc2)cc1 ; c1ccc(-c2ccc(N(c3ccc(-c4nc5ccccc5s4)cc3)c3ccc(-c4nc5ccccc5s4)cc3)cc2)cc1]

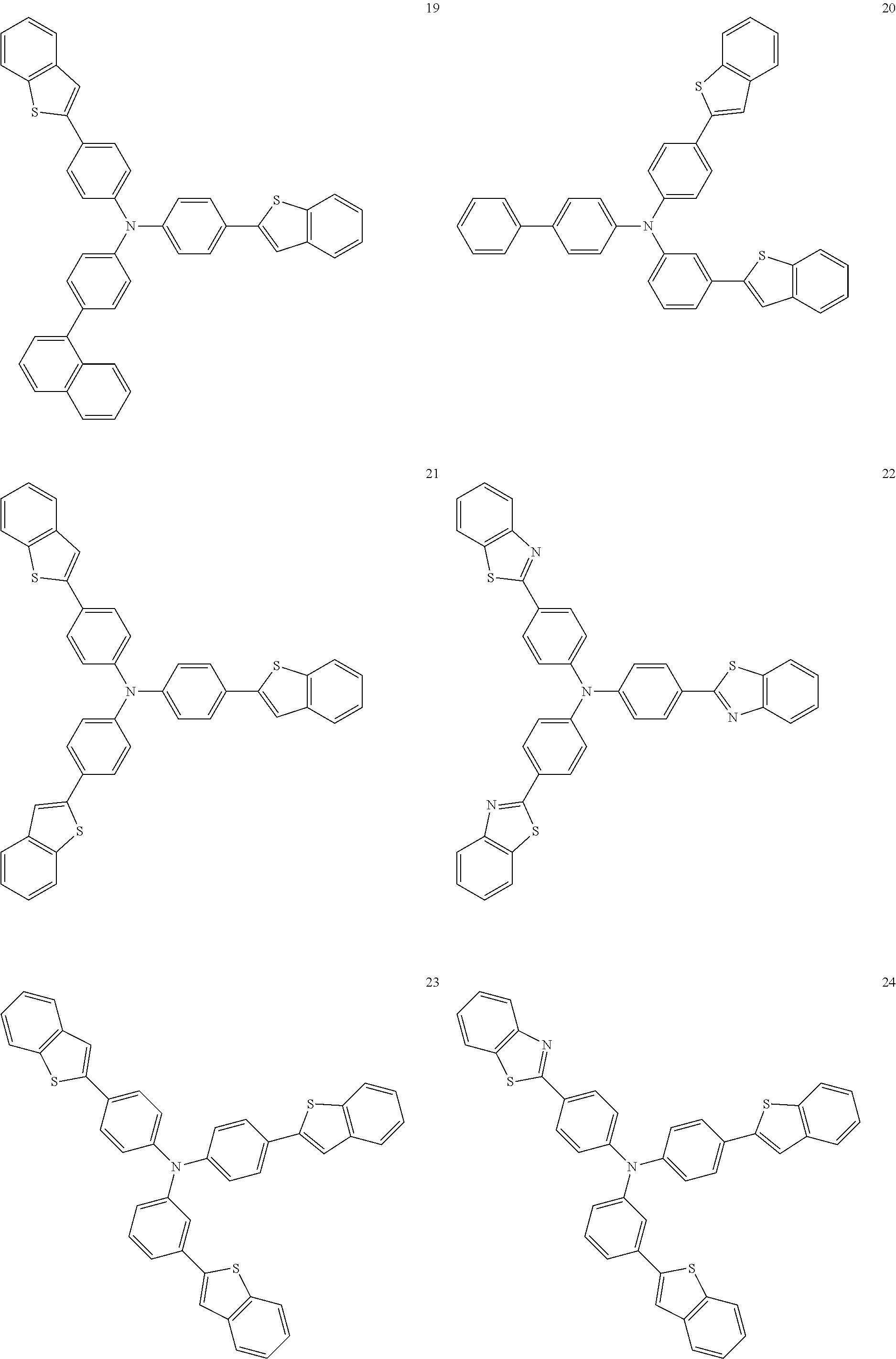 [SMILES: c1ccc2sc(-c3ccc(N(c4ccc(-c5cc6ccccc6s5)cc4)c4ccc(-c5cccc6ccccc56)cc4)cc3)cc2c1 ; c1ccc(-c2ccc(N(c3ccc(-c4cc5ccccc5s4)cc3)c3cccc(-c4cc5ccccc5s4)c3)cc2)cc1 ; c1ccc2sc(-c3ccc(N(c4ccc(-c5cc6ccccc6s5)cc4)c4ccc(-c5cc6ccccc6s5)cc4)cc3)cc2c1 ; c1ccc2sc(-c3ccc(N(c4ccc(-c5nc6ccccc6s5)cc4)c4ccc(-c5nc6ccccc6s5)cc4)cc3)nc2c1 ; c1cc(-c2cc3ccccc3s2)cc(N(c2ccc(-c3cc4ccccc4s3)cc2)c2ccc(-c3cc4ccccc4s3)cc2)c1 ; c1cc(-c2cc3ccccc3s2)cc(N(c2ccc(-c3cc4ccccc4s3)cc2)c2ccc(-c3nc4ccccc4s3)cc2)c1]

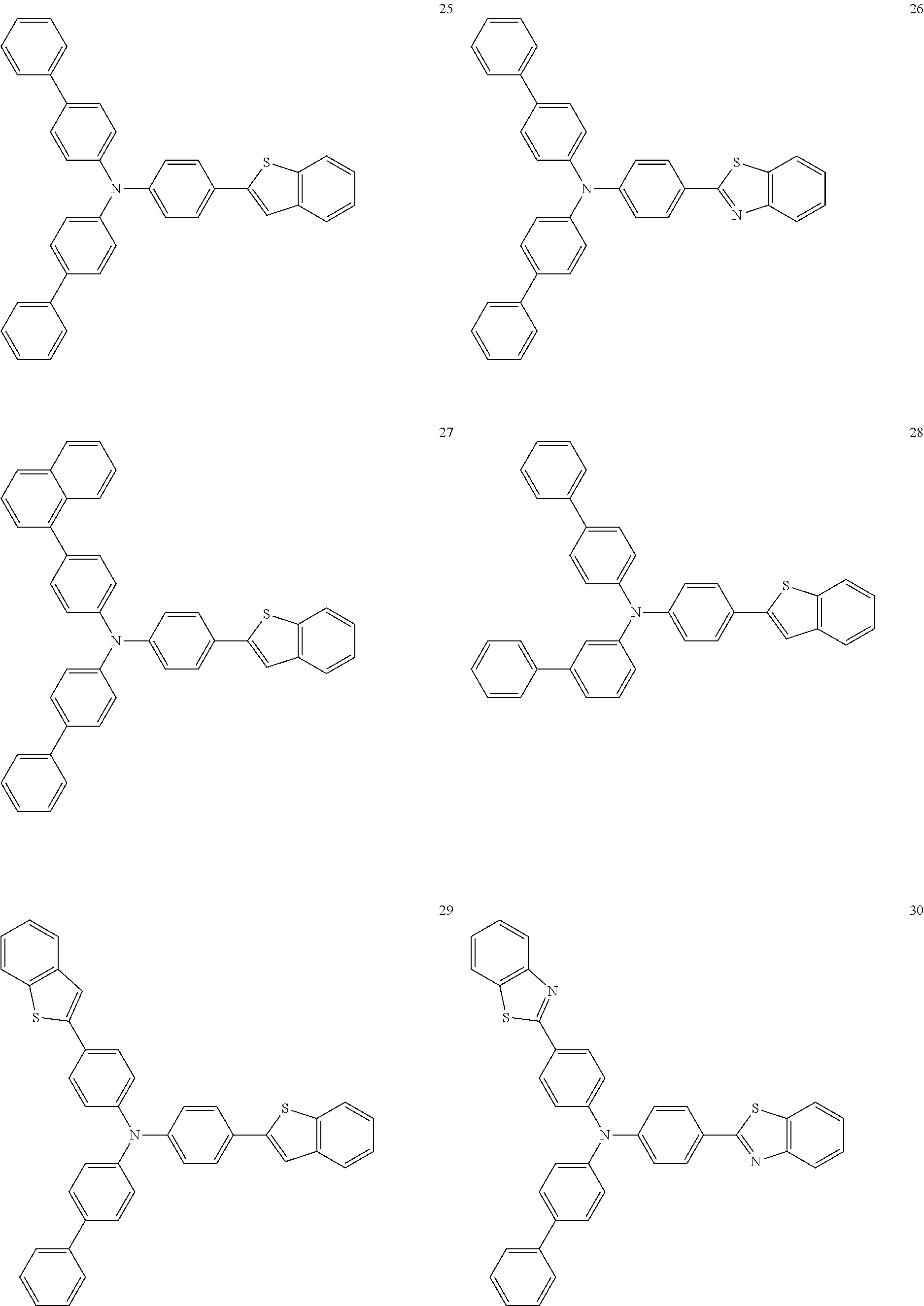 [SMILES: c1ccc(-c2ccc(N(c3ccc(-c4ccccc4)cc3)c3ccc(-c4cc5ccccc5s4)cc3)cc2)cc1 ; c1ccc(-c2ccc(N(c3ccc(-c4ccccc4)cc3)c3ccc(-c4nc5ccccc5s4)cc3)cc2)cc1 ; c1ccc(-c2ccc(N(c3ccc(-c4cc5ccccc5s4)cc3)c3ccc(-c4cccc5ccccc45)cc3)cc2)cc1 ; c1ccc(-c2ccc(N(c3ccc(-c4cc5ccccc5s4)cc3)c3cccc(-c4ccccc4)c3)cc2)cc1 ; c1ccc(-c2ccc(N(c3ccc(-c4cc5ccccc5s4)cc3)c3ccc(-c4cc5ccccc5s4)cc3)cc2)cc1 ; c1ccc(-c2ccc(N(c3ccc(-c4nc5ccccc5s4)cc3)c3ccc(-c4nc5ccccc5s4)cc3)cc2)cc1]

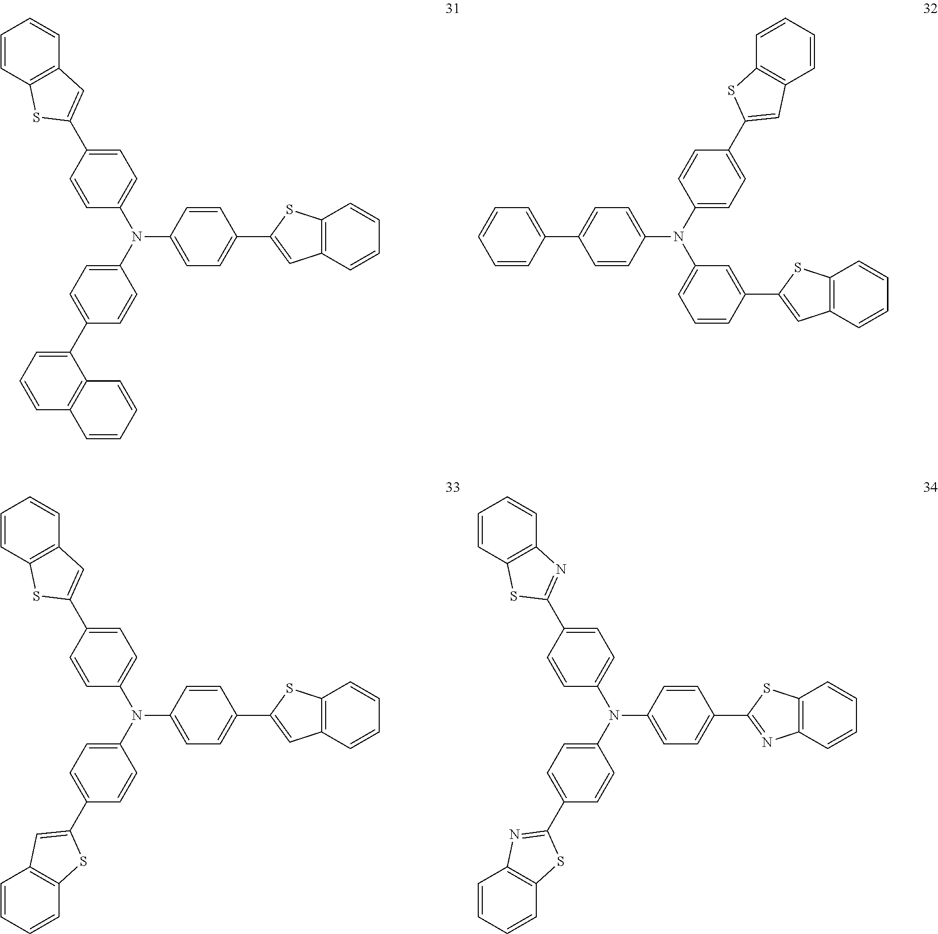 [SMILES: c1ccc2sc(-c3ccc(N(c4ccc(-c5cc6ccccc6s5)cc4)c4ccc(-c5cccc6ccccc56)cc4)cc3)cc2c1 ; c1ccc(-c2ccc(N(c3ccc(-c4cc5ccccc5s4)cc3)c3cccc(-c4cc5ccccc5s4)c3)cc2)cc1 ; c1ccc2sc(-c3ccc(N(c4ccc(-c5cc6ccccc6s5)cc4)c4ccc(-c5cc6ccccc6s5)cc4)cc3)cc2c1 ; c1ccc2sc(-c3ccc(N(c4ccc(-c5nc6ccccc6s5)cc4)c4ccc(-c5nc6ccccc6s5)cc4)cc3)nc2c1]

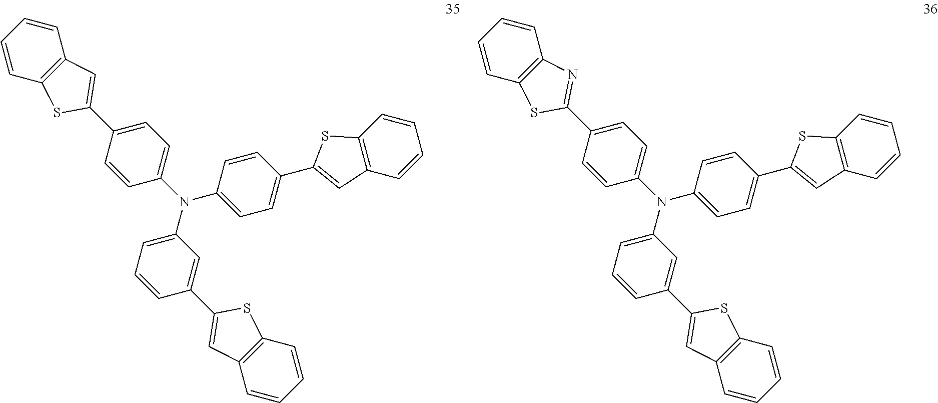 [SMILES: c1cc(-c2cc3ccccc3s2)cc(N(c2ccc(-c3cc4ccccc4s3)cc2)c2ccc(-c3cc4ccccc4s3)cc2)c1 ; c1cc(-c2cc3ccccc3s2)cc(N(c2ccc(-c3cc4ccccc4s3)cc2)c2ccc(-c3nc4ccccc4s3)cc2)c1]

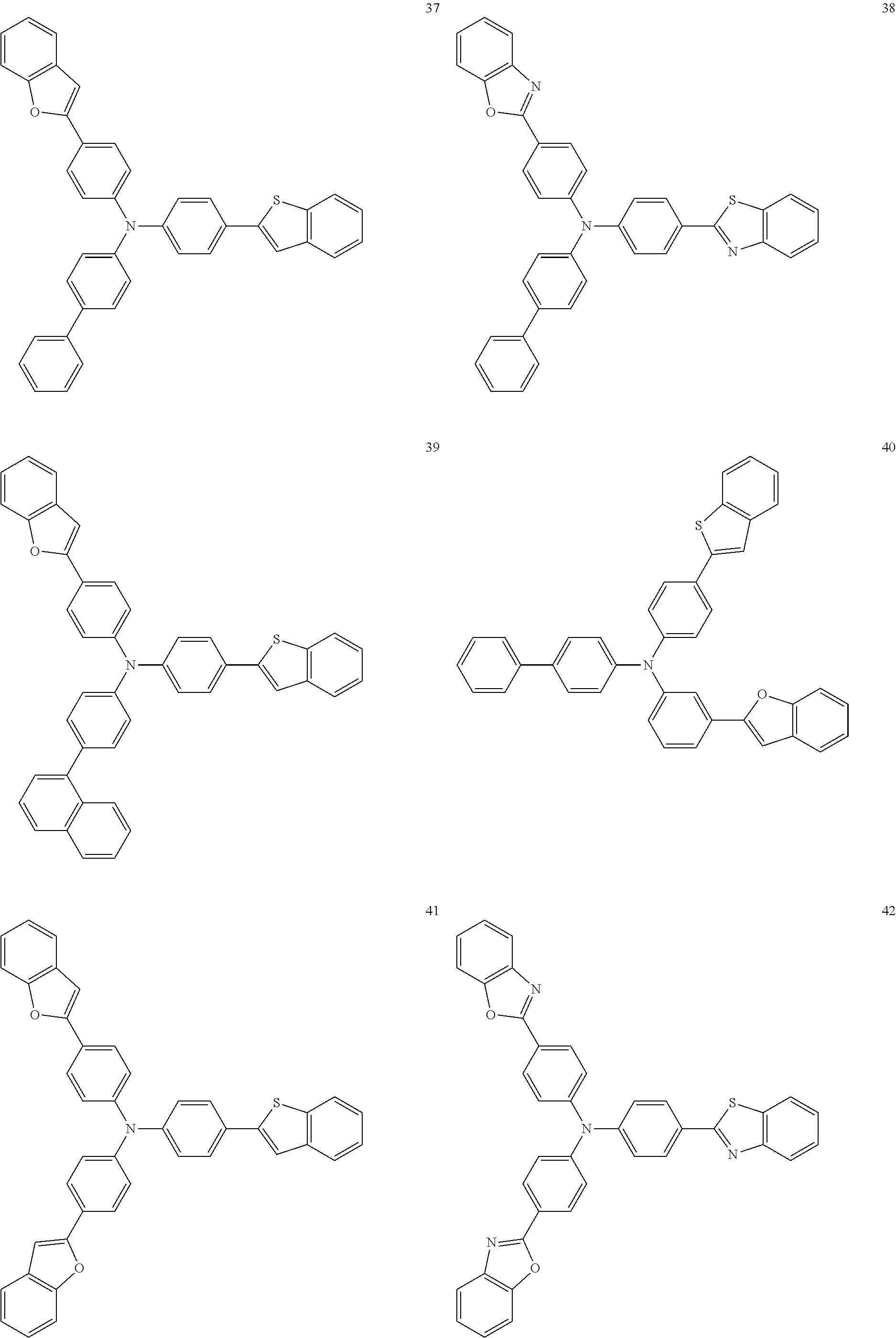 [SMILES: c1ccc(-c2ccc(N(c3ccc(-c4cc5ccccc5o4)cc3)c3ccc(-c4cc5ccccc5s4)cc3)cc2)cc1 ; c1ccc(-c2ccc(N(c3ccc(-c4nc5ccccc5o4)cc3)c3ccc(-c4nc5ccccc5s4)cc3)cc2)cc1 ; c1ccc2oc(-c3ccc(N(c4ccc(-c5cc6ccccc6s5)cc4)c4ccc(-c5cccc6ccccc56)cc4)cc3)cc2c1 ; c1ccc(-c2ccc(N(c3ccc(-c4cc5ccccc5s4)cc3)c3cccc(-c4cc5ccccc5o4)c3)cc2)cc1 ; c1ccc2oc(-c3ccc(N(c4ccc(-c5cc6ccccc6o5)cc4)c4ccc(-c5cc6ccccc6s5)cc4)cc3)cc2c1 ; c1ccc2oc(-c3ccc(N(c4ccc(-c5nc6ccccc6o5)cc4)c4ccc(-c5nc6ccccc6s5)cc4)cc3)nc2c1]

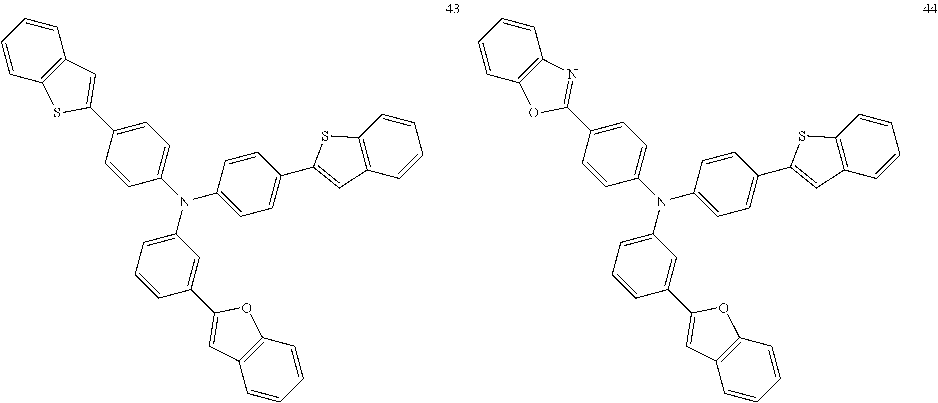 [SMILES: c1cc(-c2cc3ccccc3o2)cc(N(c2ccc(-c3cc4ccccc4s3)cc2)c2ccc(-c3cc4ccccc4s3)cc2)c1 ; c1cc(-c2cc3ccccc3o2)cc(N(c2ccc(-c3nc4ccccc4o3)cc2)c2ccc(-c3cc4ccccc4s3)cc2)c1]

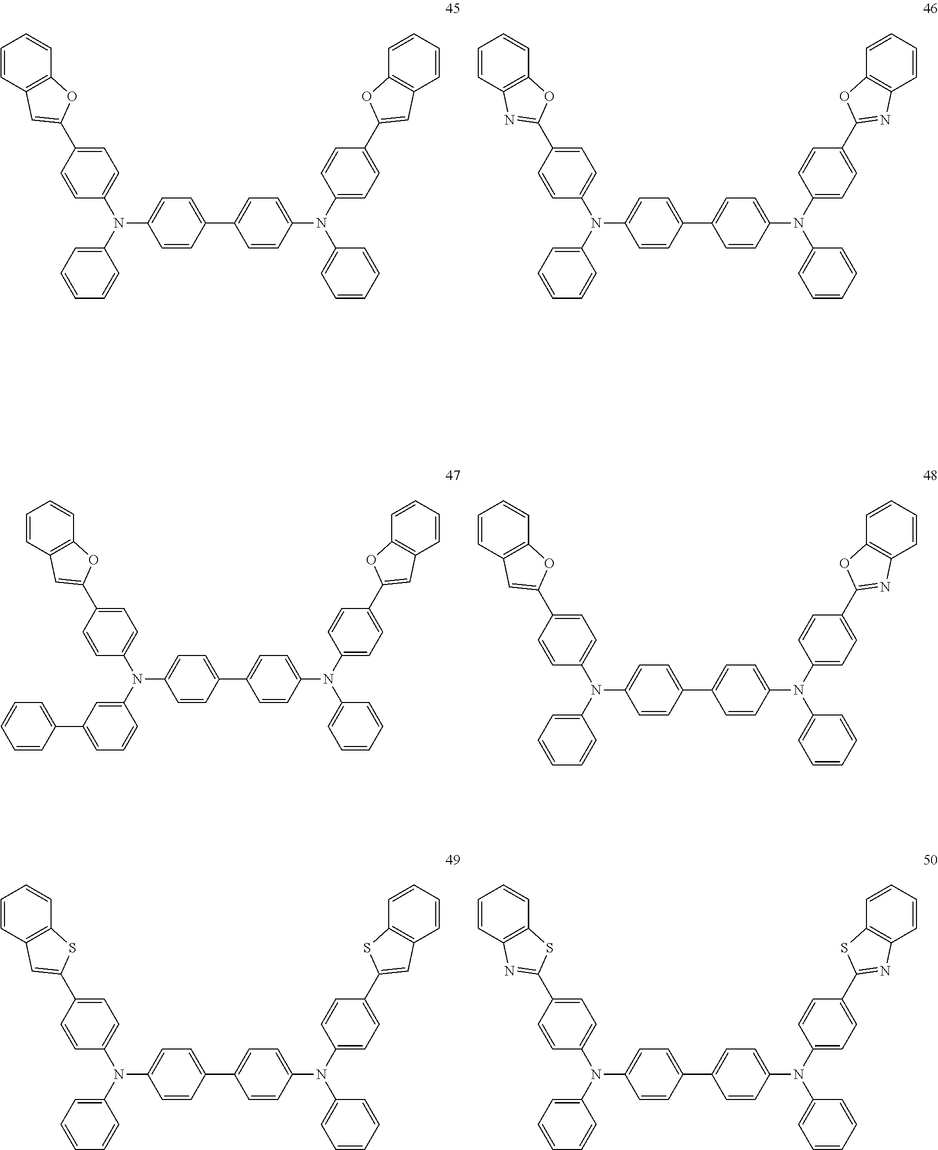

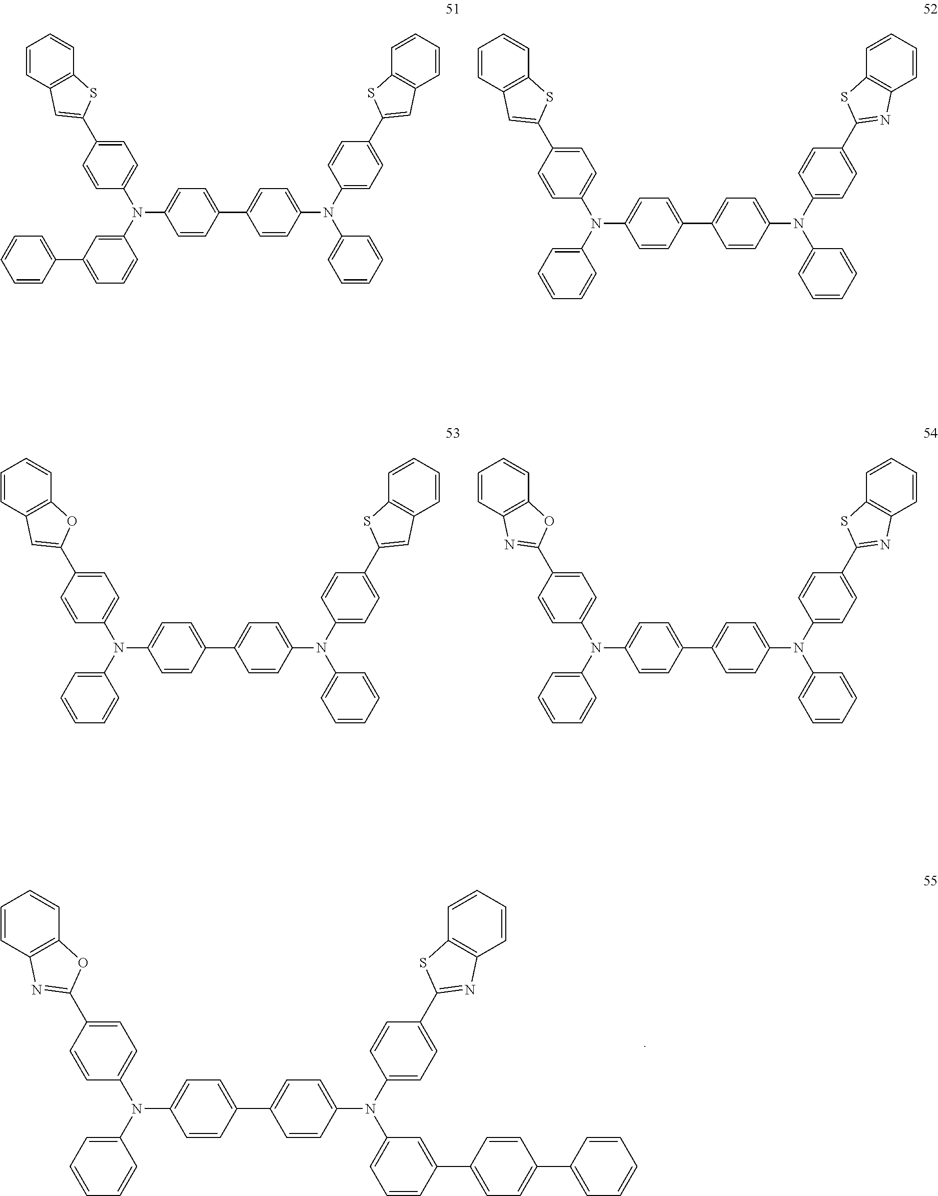

The second capping layer CPL2 includes a second compound represented by Formula 2-1 or Formula 2-2.

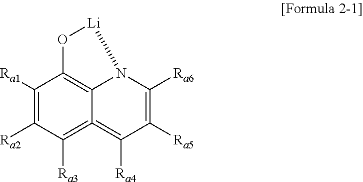

In Formula 2-1, Rₐ₁ to Rₐ₆ may each independently be a hydrogen atom, a deuterium atom, a halogen atom, a cyano group, a substituted or unsubstituted amine group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, Rₐ₁ to Rₐ₆ may each independently be a hydrogen atom, a deuterium atom, or a substituted or unsubstituted phenyl group. As another example, Rₐ₁ to Rₐ₆ may each be bonded to an adjacent group to form a polycyclic ring that is fused to a benzene moiety in Formula 2-1. For example, when Rₐ₂ and Rₐ₆ are each independently a substituted or unsubstituted alkyl group having 1 to 20 carbon atoms or a substituted or unsubstituted alkenyl group having 2 to 20 carbon atoms, and Rₐ₂, Rₐ₃, and the benzene moiety in Formula 2-1 are bonded to each other, a functional group linked to the O atom in Formula 2-1 may include a naphthalene moiety.

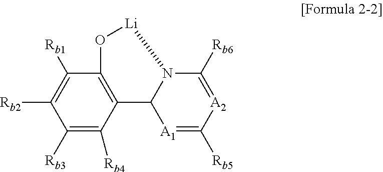

In Formula 2-2, A₁ and A₂ may each independently be N or C(R_{z}).

In Formula 2-2, R_{z} and R_{b1} to R_{b6} may each independently be a hydrogen atom, a deuterium atom, a halogen atom, a cyano group, a substituted or unsubstituted amine group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, R_{z} and R_{b1} to R_{b6} may each independently be a hydrogen atom, a deuterium atom, or a substituted or unsubstituted phenyl group. As another example, R_{z} and R_{b1} to R_{b6} may each be bonded to an adjacent group to form a polycyclic ring. For example, when R_{b3} and R_{b4} are each independently a substituted or unsubstituted alkyl group having 1 to 20 carbon atoms or a substituted or unsubstituted alkenyl group having 2 to 20 carbon atoms, and R_{b3}, R_{b4}, and the benzene moiety in Formula 2-2 are bonded to each other, a functional group linked to the O atom in Formula 2-2 may include a naphthalene moiety. As yet another example, when A₁ is C(R_{z}), R_{z} and R_{b5} are each independently a substituted or unsubstituted alkyl group having 1 to 20 carbon atoms or a substituted or unsubstituted alkenyl group having 2 to 20 carbon atoms, and R_{z}, R_{b5}, and a pyridine moiety in Formula 2-2 are bonded to each other, the L₁ atom in Formula 2-2 may be linked to a functional group including a quinoline moiety.

In an embodiment, the second compound may be any compound selected from Compound Group 2. In an embodiment, in the light emitting element ED, the second capping layer CPL2 may include at least one second compound selected from Compound Group 2.

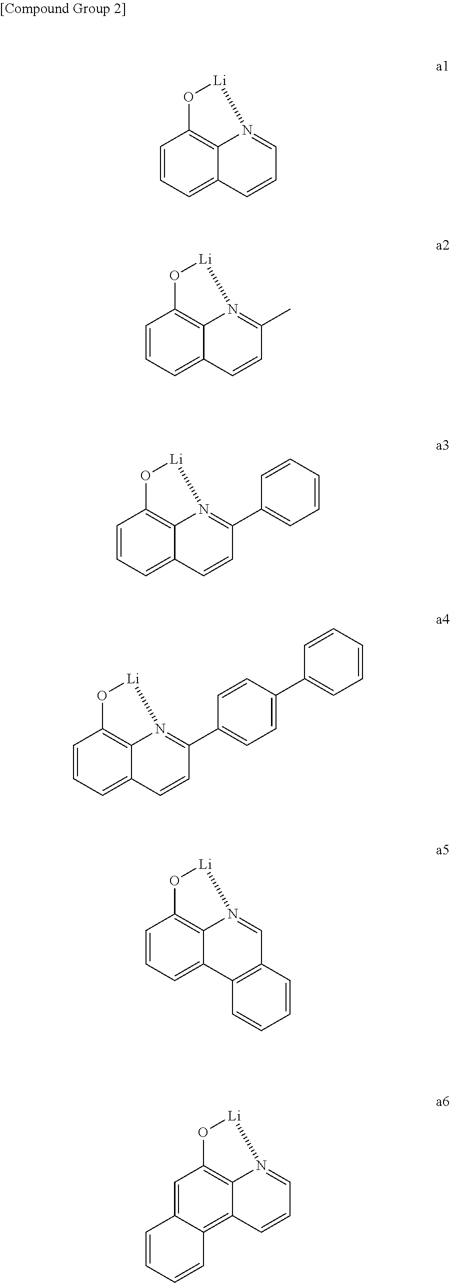

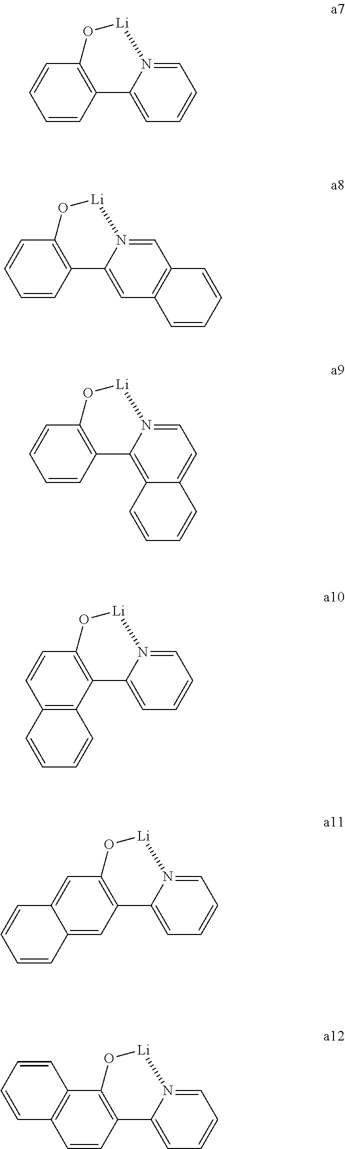

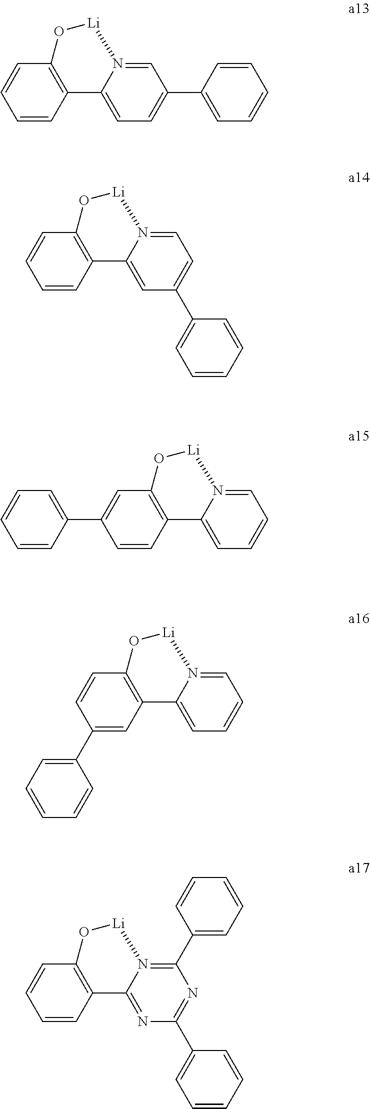

In an embodiment, the first capping layer CPL1 may further include an organic material, in addition to the first compound. In an embodiment, the second capping layer CPL2 may further include an organic material, in addition to the second compound. The first capping layer CPL1 or the second capping layer CPL2 may each independently further include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″,N4′-tetra(biphenyl-4-yl)biphenyl-4,4′-diamine (TPD15), 4,4′,4″-tris (carbazol-9-yl)triphenylamine (TCTA), etc., or may each independently further include an epoxy resin, or an acrylate such as methacrylate. However, embodiments are not limited thereto, and the first capping layer CPL1 or the second capping layer CPL2 may each independently include at least one of Compounds P1 to P5, in addition to the first compound or the second compound.

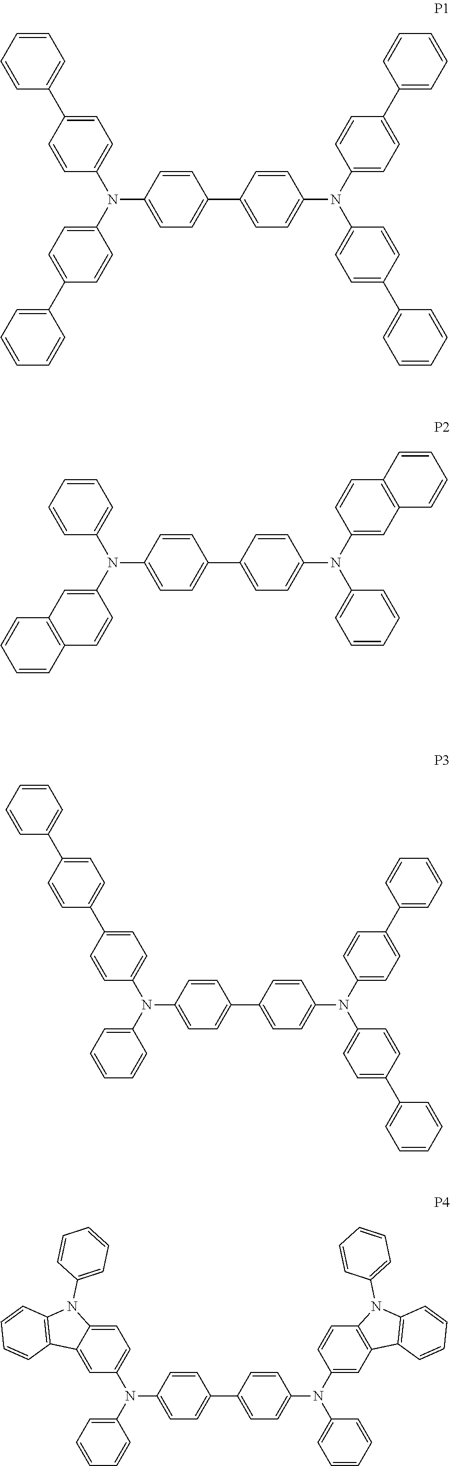 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

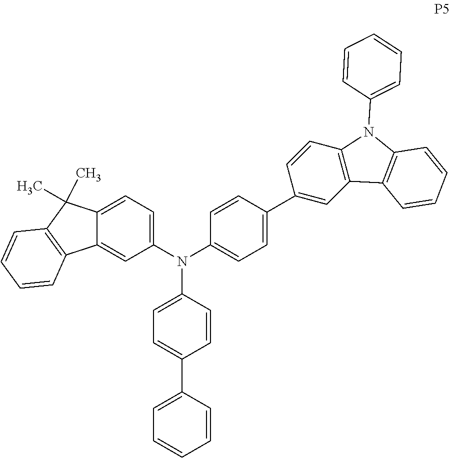 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In an embodiment, the first capping layer CPL1 may further include an inorganic material, in addition to the first compound. In an embodiment, the second capping layer CPL2 may further include an inorganic material, in addition to the second compound. The first capping layer CPL1 or the second capping layer CPL2 may each independently further include an alkaline metal compound (e.g., LiF), an alkaline earth metal compound (e.g., MgF₂), SiON, SiNₓ, SiO_{y}, etc.

A refractive index of the first capping layer CPL1 may be higher than a refractive index of the second capping layer CPL2. In an embodiment, a refractive index of the first capping layer CPL1 with respect to visible light may be higher than a refractive index of the second capping layer CPL2 with respect to visible light. For example, a refractive index of the first capping layer CPL1 may be higher than a refractive index of the second capping layer CPL2, with respect to visible light having a wavelength of about 450 nm. In an embodiment, the first capping layer CPL1 may have a refractive index in a range of about 2.2 to about 6.0, with respect to visible light having a wavelength of about 450 nm. In an embodiment, the second capping layer CPL2 may have a refractive index in a range of about 1.0 to about 2.0, with respect to visible light having a wavelength of about 450 nm.

In an embodiment, a sum of a thickness of the first capping layer CPL1 and a thickness of the second capping layer CPL2 may be in a range of about 100 nm to about 300 nm. In an embodiment, a vertical distance from the upper surface of the second electrode EL2 to the upper surface of the second capping layer CPL2 in the third direction DR3 may be in a range of about 100 nm to about 300 nm. In an embodiment, a thickness of the first capping layer CPL1 may be greater than a thickness of the second capping layer CPL2. In an embodiment, the first capping layer CPL1 may have a thickness in a range of about 50 nm to about 80 nm, and the second capping layer CPL2 may have a thickness in a range of about 30 nm to about 60 nm.

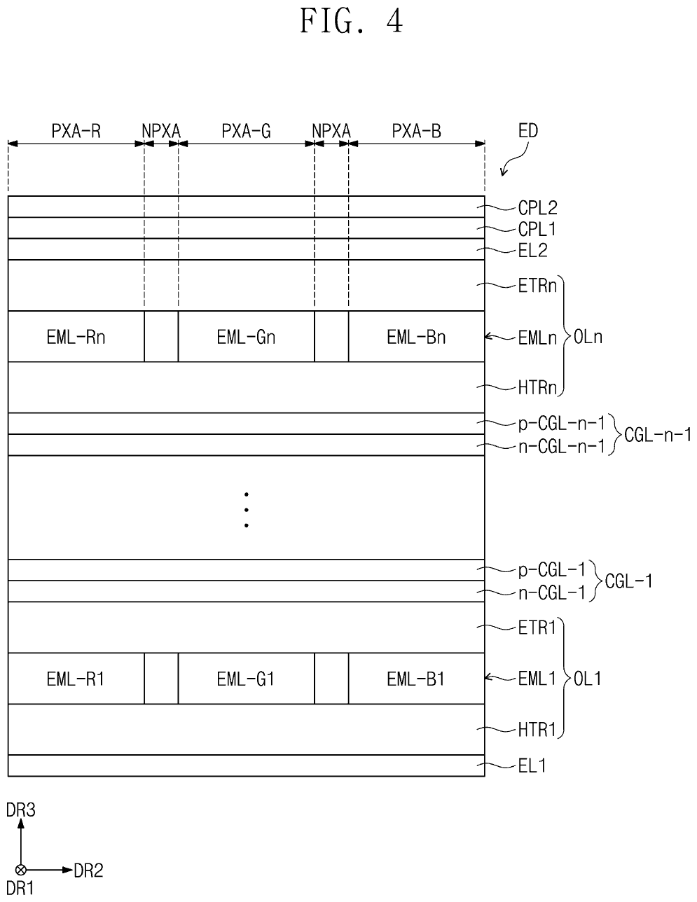

FIG. 4 is a schematic cross-sectional view of a light emitting element according to an embodiment.

In contrast to FIGS. 3A to 3D, FIG. 4 is different at least in that it illustrates that the light emitting element ED includes n light emitting units OL1 to OLn. In the specification, in FIG. 4 n may be any integer equal to or greater than 3.

Referring to FIG. 4, the light emitting element ED according to an embodiment may include a first electrode EL1, a second electrode EL2, n light emitting units OL1 to OLn sequentially stacked in a thickness direction between the first electrode EL1 and the second electrode EL2, and n−1 charge generation layers CGL-1 to CGL-n−1 respectively disposed between neighboring pairs among the light emitting units OL1 to OLn. The first to nth light emitting units OL1 to OLn may respectively include first to nth hole transport regions HTR1 to HTRn, first to nth emission layers EML1 to EMLn, and first to nth electron transport regions ETR1 to ETRn, which are respectively stacked in that order. The first to nth light emitting layers EML1 to EMLn may include first to nth red emission layers EML-R1 to EML-Rn, first to nth green emission layers EML-G1 to EML-Gn, and first to nth blue emission layers EML-B1 to EML-Bn, respectively. The charge generation layers CGL-1 to CGL-n−1 that are disposed between neighboring pairs of the light emitting units OL1 to OLn may include p-type charge generation layers p-CGL-1 to p-CGL-n−1 and n-type charge generation layers n-CGL-1 to n-CGL-n−1, respectively.

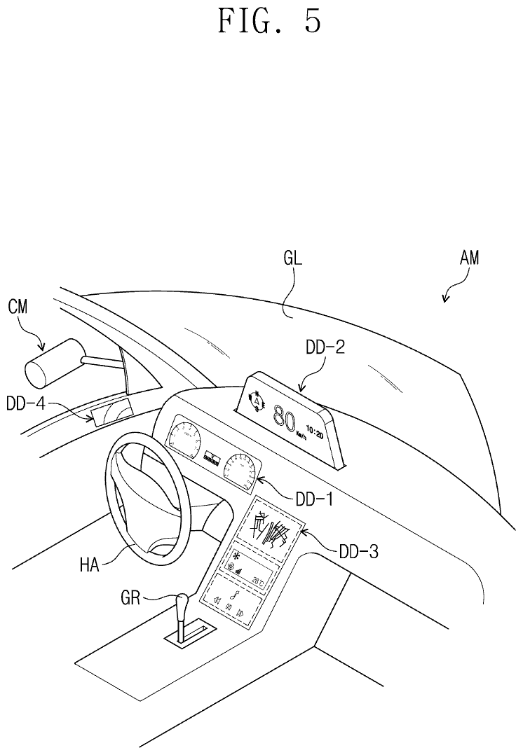

FIG. 5 is a schematic perspective view of a vehicle in which display devices are disposed according to an embodiment.

Referring to FIG. 5, an electronic device according to an embodiment may be in the form of a vehicle AM and may include display devices DD-1, DD-2, DD-3, and DD-4. At least one of the first to fourth display devices DD-1, DD-2, DD-3, and DD-4 may each independently have a structure according to the display device DD, as described with reference to FIG. 1.

FIG. 5 illustrates the first to fourth display devices DD-1, DD-2, DD-3, and DD-4 as display devices disposed inside a vehicle AM. However, this is only an example, and the first to fourth display devices DD-1, DD-2, DD-3, and DD-4 may be disposed in various transportation means, such as a bicycle, a motorcycle, a train, a ship, and an airplane. In an embodiment, at least one of the first to fourth display devices DD-1, DD-2, DD-3, and DD-4, each independently having a structure according to the display device DD, may be included in a personal computer, a laptop computer, a personal digital terminal, a game console, a portable electronic device, a television, a monitor, a billboard, or the like. However, these are merely provided as examples, and the display device may be included in other electronic apparatuses.

At least one of the first to fourth display devices DD-1, DD-2, DD-3, and DD-4 may each independently include a light emitting element ED according to an embodiment as described with reference to any of FIG. 2, FIGS. 3A to 3E, and FIG. 4.

Referring to FIG. 5, the vehicle AM may include a steering wheel HA and a gearshift GR for driving the vehicle AM. The vehicle AM may include a windshield GL that is disposed so as to face the driver.

The first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates an engine speed (for example, as revolutions per minute (RPM)), a gauge that indicates fuel level, etc. The first scale and the second scale may each be represented by digital images.

The second display device DD-2 may be disposed in a second region facing the driver's seat and overlapping the windshield GL. The driver's seat may be a seat in which the steering wheel HA is disposed. For example, the second display device DD-2 may be a head up display (HUD) that displays second information of the vehicle AM. The second display device DD-2 may be optically transparent. The second information may include digital numbers that indicate a driving speed, and may further include information such as the current time. Although not shown in the drawings, in an embodiment, the second information of the second display device DD-2 may be displayed by being projected onto the windshield GL.

The third display device DD-3 may be disposed in a third region adjacent to the gearshift GR. For example, the third display device DD-3 may be disposed between the driver's seat and the passenger seat and may be a center information display (CID) for the vehicle AM that displays third information. The passenger seat may be a seat spaced that is apart from the driver's seat, and the gearshift GR may be disposed the driver's seat and the passenger seat. The third information may include information about traffic or road conditions (e.g., navigation information), about music or radio that is playing, about a video (or an image) that is being displayed, about temperatures inside the vehicle AM, etc.

The fourth display device DD-4 may be spaced apart from the steering wheel HA and the gearshift GR, and may be disposed in a fourth region that is adjacent to a side of the vehicle AM. For example, the fourth display device DD-4 may be a digital side-view mirror that displays fourth information. The fourth display device DD-4 may display an image that is exterior to the vehicle AM taken by a camera module CM disposed outside the vehicle AM. The fourth information may include an image of the exterior of the vehicle AM.

The first to fourth information as described above are only provided as examples, and the first to fourth display devices DD-1, DD-2, DD-3, and DD-4 may further display information about the interior and exterior of the vehicle AM. The first to fourth information may include information that is different from each other. However, embodiments are not limited thereto, and a part of the first to fourth information may include the same information.

Hereinafter, a light emitting element according to an embodiment will be described with reference to the Examples, the Comparative Examples, and FIGS. 3A to 3D. The Examples described below are only provided as illustrations to assist in understanding the disclosure, and the scope thereof is not limited thereto.

### 1. Manufacture of Light Emitting Element

The light emitting elements of Examples and Comparative Examples were manufactured by the following method.

### (Manufacture of Light Emitting Element of Example 1)

In the light emitting element of Example 1, a glass substrate (made by Corning Co.), on which an ITO/Ag/ITO (120 Å/500 Å/120 Å) electrode of about 15 Ω/cm² is formed as a first electrode, was cut to a size of about 50 mm×50 mm×0.7 mm, cleansed by ultrasonic waves by using isopropyl alcohol and pure water for about five minutes each, irradiated with ultraviolet rays for about 30 minutes, and exposed to ozone and cleansed. The glass substrate was installed on a vacuum deposition apparatus.

On an upper portion of the first electrode, a first light emitting unit was formed. Compound H-1-1 as a hole injection material was doped with a p-dopant (2%) of F4-TCNQ, and the doped hole injection material of Compound H-1-1 was deposited on an upper portion of the first electrode at a thickness of about 10 nm. Compound H-1-1 as a hole transport material was deposited thereon at a thickness of about 30 nm, thereby forming a first hole transport region as a common layer. A light emitting host of Compound E-2-1 was doped with a light emitting dopant (3%) of Compound M-a1, and the doped light emitting host of Compound E-2-1 was deposited on an upper portion of the first hole transport region at a thickness of about 40 nm to overlap a first light emitting region, thereby forming a first red emission layer. A light emitting host of Compound E-2-24 was doped with a light emitting dopant (8%) of Compound M-a20, and the doped light emitting host of Compound E-2-24 was deposited on an upper portion of the first hole transport region at a thickness of about 30 nm to overlap a second light emitting region, thereby forming a first green emission layer. A light emitting host of Compound ET 19 was doped with a light emitting dopant (2%) of Compound BD, and the doped light emitting host of Compound ET19 was deposited on an upper portion of the first hole transport region at a thickness of about 20 nm to overlap a third light emitting region, thereby forming a first blue emission layer. Thus, a first emission layer was formed as a pattern layer. An electron transporting host of Compound ET38 was deposited at a thickness of about 30 nm to form a first electron transport region as a common layer.

A charge generation unit was formed on the first electron transport region. An electron transporting material of Compound ET36 was doped with a Yb dopant (3%), and the doped electron transporting material was deposited at a thickness of about 15 nm to form an n-type charge generation layer as a common layer. A hole transporting material of Compound H-1-19 was doped with a p-dopant (8%) of F4-TCNQ, and the doped hole transporting material of Compound H-1-19 was deposited on an upper portion of the n-type charge generation layer at a thickness of about 10 nm, and a hole transporting material of Compound H-1-19 was deposited thereon at a thickness of about 30 nm, thereby forming a p-type charge generation layer as a common layer.

A second light emitting unit was formed on an upper portion of the p-type charge generation layer. Compound H-1-9 was deposited on an upper portion of the p-type charge generation layer so as to overlap the first light emitting region, thereby forming a 50-nm second red emission-auxiliary layer. Compound H-1-11 was deposited so as to overlap the second light emitting region, thereby forming a 20-nm second green emission-auxiliary layer. Compound H-1-9 was deposited so as to overlap the third light emitting region, thereby forming a 10-nm second blue emission-auxiliary layer. Thus, the second emission-auxiliary layer was formed as a pattern layer. A second red emission layer, a second green emission layer, and a second blue emission layer of the second emission layer were formed to have a same thickness on an upper portion of the second emission-auxiliary layer by using the same materials as the first red emission layer, the first green emission layer, and the first blue emission layer of the first emission layer, respectively, thereby forming the second emission layer as a pattern layer. An electron transporting material of Compound ET28 was deposited to form a 10-nm first electron-auxiliary layer, and an electron transporting material of Compound ET38 was deposited to form a 30-nm second electron transport region as a common layer.

Ag:Mg (10%) was deposited on an upper portion of the second electron transport region to form a 90-A thick second electrode. Compound 1 of Compound Group 1 was deposited on an upper portion of the second electrode to form a 50-nm first capping layer, Compound a1 of Compound Group 2 was deposited on an upper portion of the first capping layer to form a 30-nm second capping layer, thereby manufacturing a light emitting element. Each layer was formed by a vacuum deposition method.

### (Manufacture of Light Emitting Elements of Examples 2 to 8)

Light emitting elements of Examples 2 to 8 were manufactured in the same manner as in the stacked structure of the light emitting element of Example 1. The light emitting elements of Examples 2 to 8 were manufactured in the same manner as the light emitting element of Example 1, except that the compounds used in the forming of the first capping layer and the second capping layer were different from those used in Example 1. Materials used in the forming of the first capping layer or the second capping layer in Examples 2 to 8 are shown in Table 1 below.

### (Manufacture of Light Emitting Element of Comparative Example 1)

The light emitting element of Comparative Example 1 was manufactured in the same manner, except that the light emitting element had a structure without including the second capping layer compared to the stacked structure of the light emitting element in Example 1, and the compound used in the forming of the first capping layer was different from that used in Example 1. Materials used in the forming of the first capping layer in Comparative Example 1 are shown in Table 1 below.

### (Manufacture of Light Emitting Elements of Comparative Examples 2 to 4)

Light emitting elements of Comparative Examples 2 to 4 were manufactured in the same manner as in the stacked structure of the light emitting element of Example 1. The light emitting elements of Examples 2 to 4 were manufactured in the same manner as the light emitting element of Example 1, except that the compounds used in the forming of the first capping layer and the second capping layer were different from those used in Example 1. Materials used in the forming of the first capping layer or the second capping layer in Comparative Examples 2 to 4 are shown in Table 1 below.

TABLE 1

| | Material for first | Material for second |
|---|---|---|
| | capping layer | capping layer |
| Example 1 | Compound 1 | Compound a1 |
| Example 2 | Compound 9 | Compound a1 |
| Example 3 | Compound 21 | Compound a1 |
| Example 4 | Compound 38 | Compound a1 |
| Example 5 | Compound 1 | Compound a7 |
| Example 6 | Compound 9 | Compound a7 |
| Example 7 | Compound 21 | Compound a7 |
| Example 8 | Compound 38 | Compound a7 |
| Comparative Example 1 | H-1-20 | — |
| Comparative Example 2 | H-1-20 | Compound a1 |
| Comparative Example 3 | Compound 1 | Alq₃ |
| Comparative Example 4 | Compound 1 | LiF |

Compounds used for manufacturing the light emitting elements of Examples and Comparative Examples are disclosed below. The materials below were used to manufacture the elements by subjecting commercial products to sublimation purification.

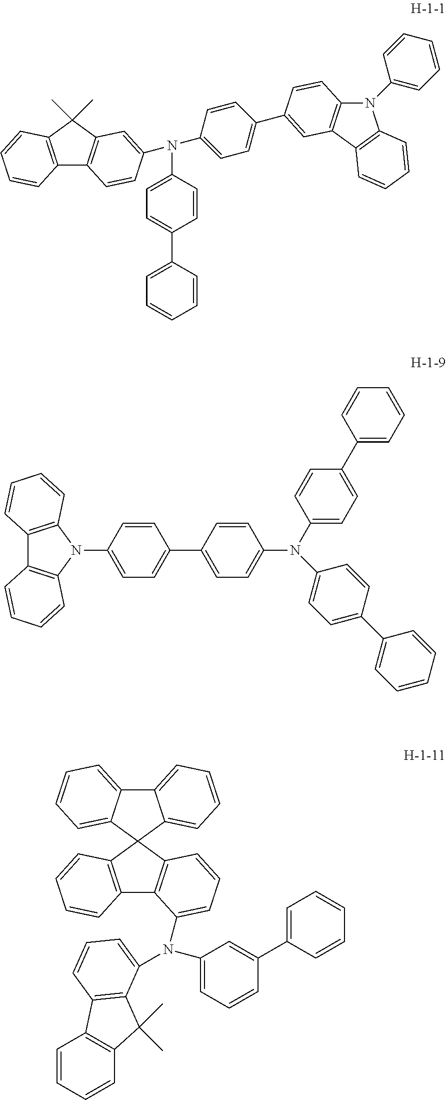 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2cccc(N(c3cccc(-c4ccccc4)c3)c3cccc4c3-c3ccccc3C43c4ccccc4-c4ccccc43)c21]

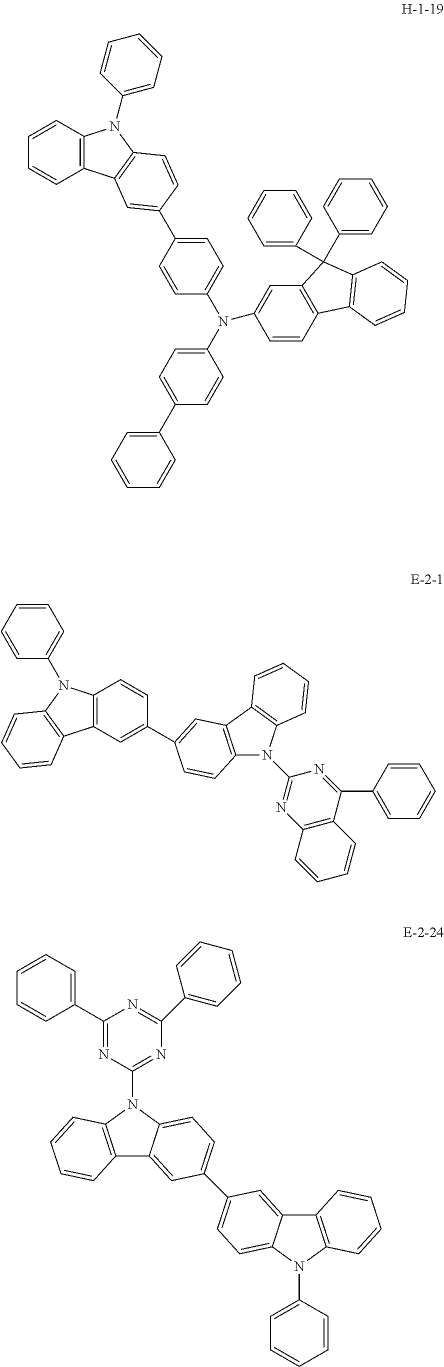 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-c3ccccc3)nc(-n3c4ccccc4c4cc(-c5ccc6c(c5)c5ccccc5n6-c5ccccc5)ccc43)n2)cc1]

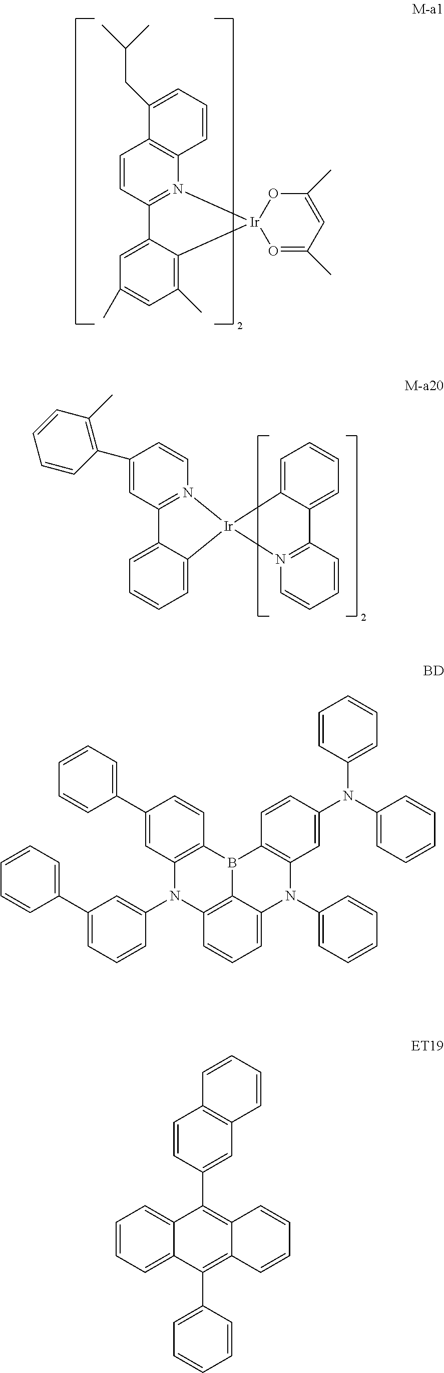

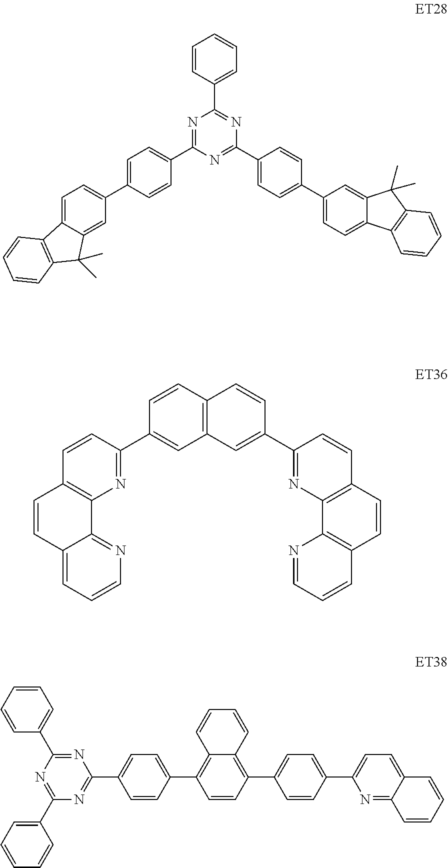 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1cnc2c(c1)ccc1ccc(-c3ccc4ccc(-c5ccc6ccc7cccnc7c6n5)cc4c3)nc12 ; c1ccc(-c2nc(-c3ccccc3)nc(-c3ccc(-c4ccc(-c5ccc(-c6ccc7ccccc7n6)cc5)c5ccccc45)cc3)n2)cc1]

### 2. Characterization of Light Emitting Elements

Element efficiencies and element service lives of the light emitting elements of Examples 1 to 8 and Comparative Examples 1 to 4 as described above were evaluated. Table 1 shows the evaluation results of the light emitting elements of Examples 1 to 8 and Comparative Examples 1 to 4. In order to characterize the light emitting elements manufactured in Examples 1 to 8 and Comparative Examples 1 to 4, the front luminous efficiency (Cd/A/y) was measured using a luminance meter SR-3AR, and a relative service life was calculated based on the light emitting element of Comparative Example 1, and the results are shown in Table 2.

TABLE 2

| | Materials within | Materials within | Front luminous |
|---|---|---|---|
| | first capping | second capping | efficiency |
| | layer CPL1 | layer CPL2 | (Cd/A/y) |
| Example 1 | Compound 1 | Compound a1 | 109% |
| Example 2 | Compound 9 | Compound a1 | 112% |
| Example 3 | Compound 21 | Compound a1 | 110% |
| Example 4 | Compound 38 | Compound a1 | 108% |
| Example 5 | Compound 1 | Compound a7 | 108% |
| Example 6 | Compound 9 | Compound a7 | 110% |
| Example 7 | Compound 21 | Compound a7 | 111% |
| Example 8 | Compound 38 | Compound a7 | 108% |
| Comparative | H-1-20 | X | 100% |
| Example 1 | | | |
| Comparative | H-1-20 | Compound a1 | 102% |
| Example 2 | | | |
| Comparative | Compound 1 | Alq3 | 103% |
| Example 3 | | | |
| Comparative | Compound 1 | LiF | 102% |
| Example 4 | | | |

Referring to Table 2, the light emitting elements of Examples 1 to 8 each include the first capping layer CPL1 disposed on the second electrode, and the second capping layer CPL2 disposed on the first capping layer CPL1. The light emitting elements of Examples 1 to 8 each include the first compound in the first capping layer CPL1 and the second compound in the second capping layer CPL2. By comparison, the light emitting element of Comparative Example 1 includes only the first capping layer CPL1 and does not include the second capping layer CPL2. The light emitting element of Comparative Example 2 includes the first and second capping layers CPL1 and CPL2, and the second capping layer CPL2 includes the second compound, but the first capping layer CPL1 does not include the first compound. The light emitting elements of Comparative Example 3 and Comparative Example 4 each include the first and second capping layers CPL1 and CPL2, and the first capping layer CPL1 includes the first compound, but the second capping layer CPL2 does not include the second compound. Referring to the luminous efficiency result values of the Examples and the Comparative Examples of Table 1, it may be confirmed that the light emitting elements according to embodiments have higher luminous efficiencies than the light emitting elements of the Comparative Examples. It may be confirmed that the light emitting elements of Examples 1 to 8 have higher luminous efficiencies than the light emitting elements of Comparative Examples 1 to 4. The light emitting element according to an embodiment includes the first capping layer CPL1 and the second capping layer CPL2 disposed on the first capping layer CPL1, includes the first compound in the first capping layer CPL1, and includes the second compound in the second capping layer CPL2, and thus may achieve relatively high luminous efficiency. The display device including the light emitting element according to an embodiment may have improved reliability and display characteristics.

According to an embodiment, a tandem-type light emitting element including multiple light emitting units includes the first capping layer and the second capping layer, and thus the luminous efficiency may be maximized.

According to an embodiment, it is possible to provide a display device having improved display efficiency by including the light emitting element according to embodiments.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

1. A light emitting element comprising:
A light emitting element comprising:
a first electrode;
a first light emitting unit disposed on the first electrode and comprising a first emission layer;
a charge generation unit disposed on the first light emitting unit;
a second light emitting unit disposed on the charge generation unit and comprising a second emission layer;
a second electrode disposed on the second light emitting unit;
a first capping layer disposed on the second electrode; and
a second capping layer disposed on the first capping layer, wherein
the first capping layer comprises a first compound represented by Formula 1, and
the second capping layer comprises a second compound represented by Formula 2-1 or Formula 2-2: 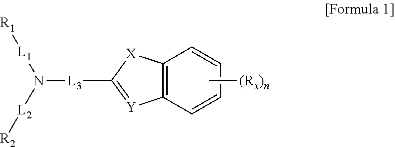
wherein in Formula 1,
L₁ to L₃ are each independently a direct linkage, a substituted or unsubstituted arylene group having 6 to 12 ring-forming carbon atoms, or a substituted or unsubstituted heteroarylene group having 5 to 11 ring-forming carbon atoms,
X is O or S,
Y is N or C(R_{y}),
R₁, R₂, Rₓ, and R_{y} are each independently a hydrogen atom, a deuterium atom, a halogen atom, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and
n is an integer from 0 to 4; 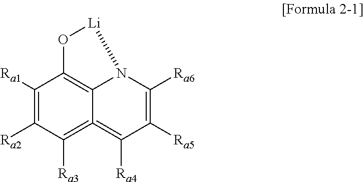
wherein in Formula 2-1,
Rₐ₁ to Rₐ₆ are each independently a hydrogen atom, a deuterium atom, a halogen atom, a cyano group, a substituted or unsubstituted amine group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring; and 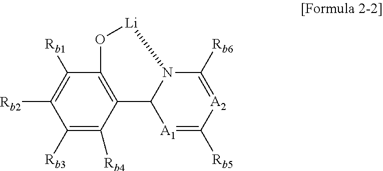
wherein in Formula 2-2,
A₁ and A₂ are each independently N or C(R_{z}), and
R_{z} and R_{b1} to R_{b6} are each independently a hydrogen atom, a deuterium atom, a halogen atom, a cyano group, a substituted or unsubstituted amine group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

2. The light emitting element of claim 1, wherein
the first capping layer has a refractive index in a range of about 2.2 to about 6.0, with respect to visible light having a wavelength of about 450 nm, and
the second capping layer has a refractive index in a range of about 1.0 to about 2.0, with respect to visible light having a wavelength of about 450 nm.

3. The light emitting element of claim 1, wherein in Formula 1, R₁ and R₂ are each independently a substituted or unsubstituted amine group, a substituted or unsubstituted phenyl group, a substituted or unsubstituted naphthyl group, a substituted or unsubstituted benzoxazole group, a substituted or unsubstituted benzothiazole group, a substituted or unsubstituted benzofuran group, or a substituted or unsubstituted benzothiophene group.

4. The light emitting element of claim 1, wherein in Formula 2-1 and Formula 2-2, Rₐ₁ to Rₐ₆ and R_{b1} to R_{b6} are each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted phenyl group, or bonded to an adjacent group to form a ring.

5. The light emitting element of claim 1, wherein the first compound is represented by one of Formula 1-1 to Formula 1-3: 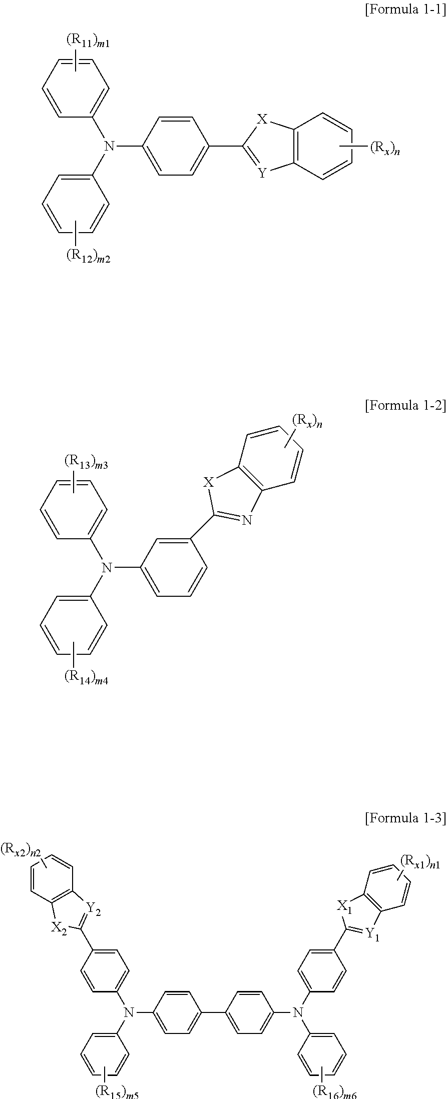
wherein in Formula 1-1 to Formula 1-3,
R₁₁ to R₁₆ are each independently a hydrogen atom, a deuterium atom, a halogen atom, a cyano group, a substituted or unsubstituted amine group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring,
Rₓ₁ and Rₓ₂ are each independently a hydrogen atom, a deuterium atom, a halogen atom, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
X₁ and X₂ are each independently O or S,
Y₁ and Y₂ are each independently N or C(R_{y}),
n1 and n2 are each independently an integer from 0 to 4,
m1 to m6 are each independently an integer from 0 to 5, and
X, Y, Rₓ, R_{y}, and n are the same as defined in Formula 1.

6. The light emitting element of claim 1, wherein the first compound comprises at least one compound selected from Compound Group 1:

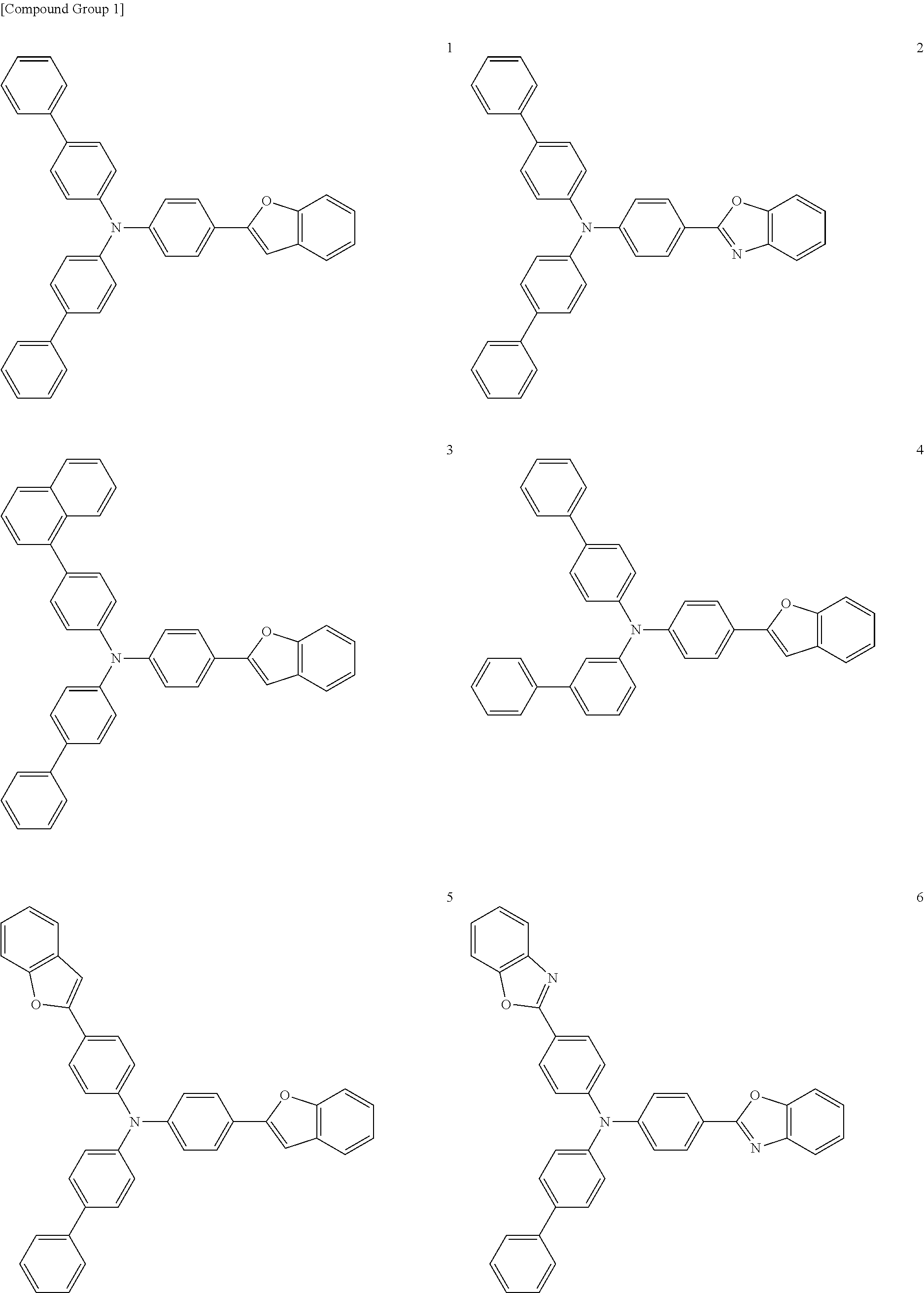 [SMILES: c1ccc(-c2ccc(N(c3ccc(-c4ccccc4)cc3)c3ccc(-c4cc5ccccc5o4)cc3)cc2)cc1 ; c1ccc(-c2ccc(N(c3ccc(-c4ccccc4)cc3)c3ccc(-c4nc5ccccc5o4)cc3)cc2)cc1 ; c1ccc(-c2ccc(N(c3ccc(-c4cc5ccccc5o4)cc3)c3ccc(-c4cccc5ccccc45)cc3)cc2)cc1 ; c1ccc(-c2ccc(N(c3ccc(-c4cc5ccccc5o4)cc3)c3cccc(-c4ccccc4)c3)cc2)cc1 ; c1ccc(-c2ccc(N(c3ccc(-c4cc5ccccc5o4)cc3)c3ccc(-c4cc5ccccc5o4)cc3)cc2)cc1 ; c1ccc(-c2ccc(N(c3ccc(-c4nc5ccccc5o4)cc3)c3ccc(-c4nc5ccccc5o4)cc3)cc2)cc1]

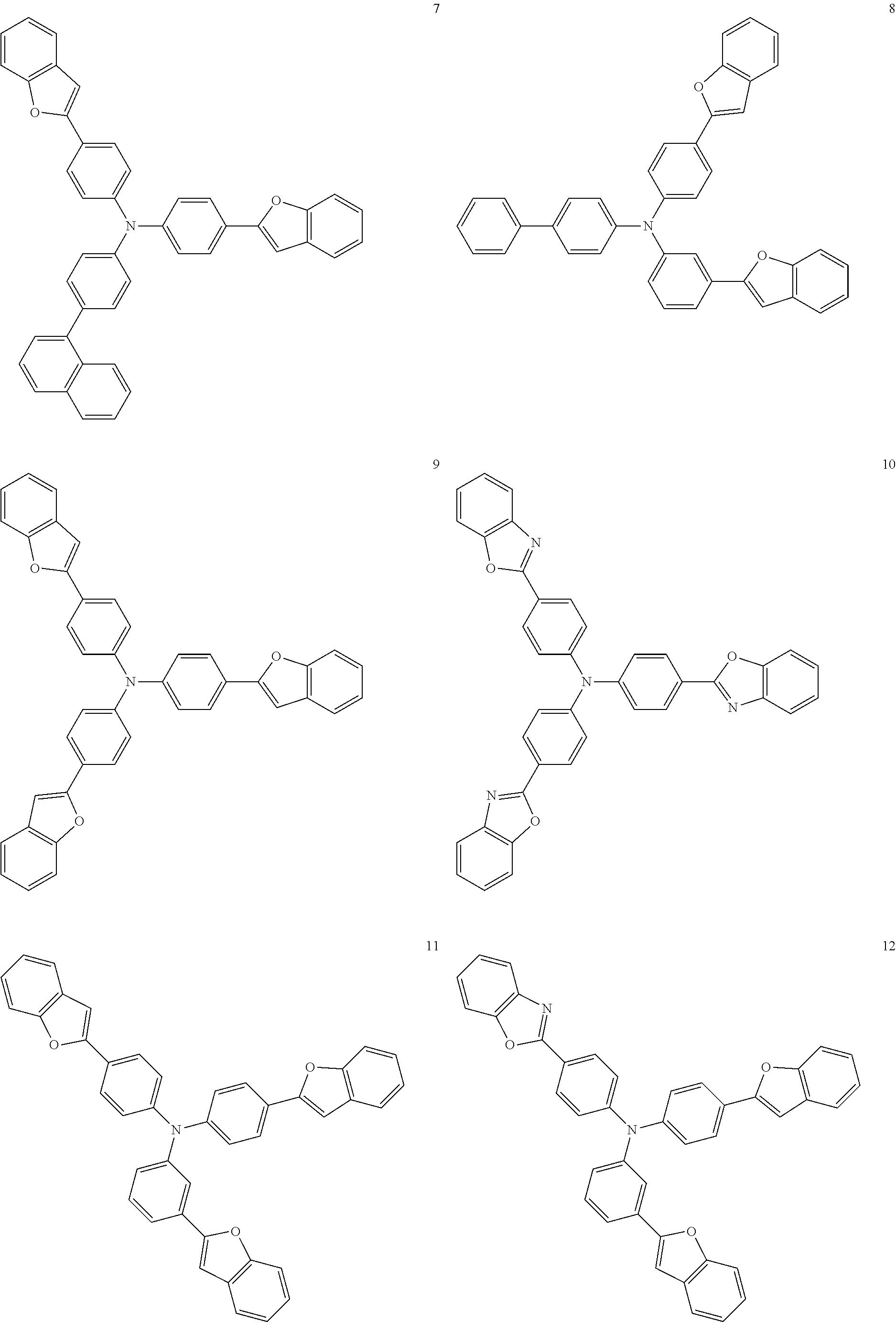 [SMILES: c1ccc2oc(-c3ccc(N(c4ccc(-c5cc6ccccc6o5)cc4)c4ccc(-c5cccc6ccccc56)cc4)cc3)cc2c1 ; c1ccc(-c2ccc(N(c3ccc(-c4cc5ccccc5o4)cc3)c3cccc(-c4cc5ccccc5o4)c3)cc2)cc1 ; c1ccc2oc(-c3ccc(N(c4ccc(-c5cc6ccccc6o5)cc4)c4ccc(-c5cc6ccccc6o5)cc4)cc3)cc2c1 ; c1ccc2oc(-c3ccc(N(c4ccc(-c5nc6ccccc6o5)cc4)c4ccc(-c5nc6ccccc6o5)cc4)cc3)nc2c1 ; c1cc(-c2cc3ccccc3o2)cc(N(c2ccc(-c3cc4ccccc4o3)cc2)c2ccc(-c3cc4ccccc4o3)cc2)c1 ; c1cc(-c2cc3ccccc3o2)cc(N(c2ccc(-c3cc4ccccc4o3)cc2)c2ccc(-c3nc4ccccc4o3)cc2)c1]

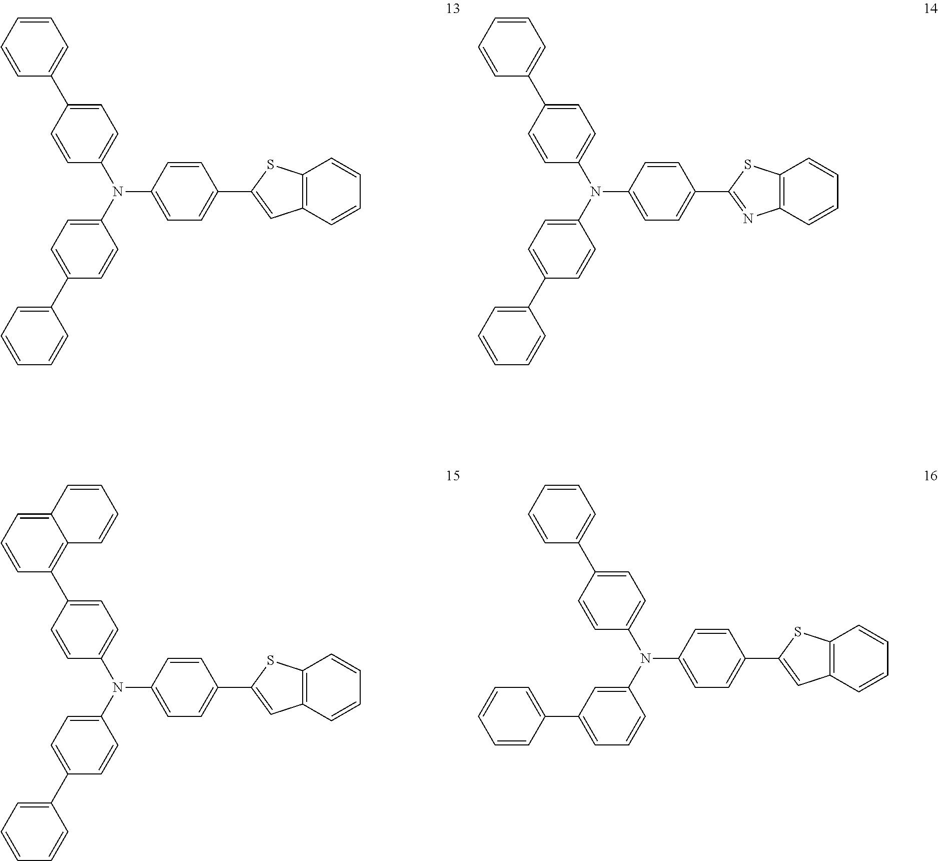 [SMILES: c1ccc(-c2ccc(N(c3ccc(-c4ccccc4)cc3)c3ccc(-c4cc5ccccc5s4)cc3)cc2)cc1 ; c1ccc(-c2ccc(N(c3ccc(-c4ccccc4)cc3)c3ccc(-c4nc5ccccc5s4)cc3)cc2)cc1 ; c1ccc(-c2ccc(N(c3ccc(-c4cc5ccccc5s4)cc3)c3ccc(-c4cccc5ccccc45)cc3)cc2)cc1 ; c1ccc(-c2ccc(N(c3ccc(-c4cc5ccccc5s4)cc3)c3cccc(-c4ccccc4)c3)cc2)cc1]

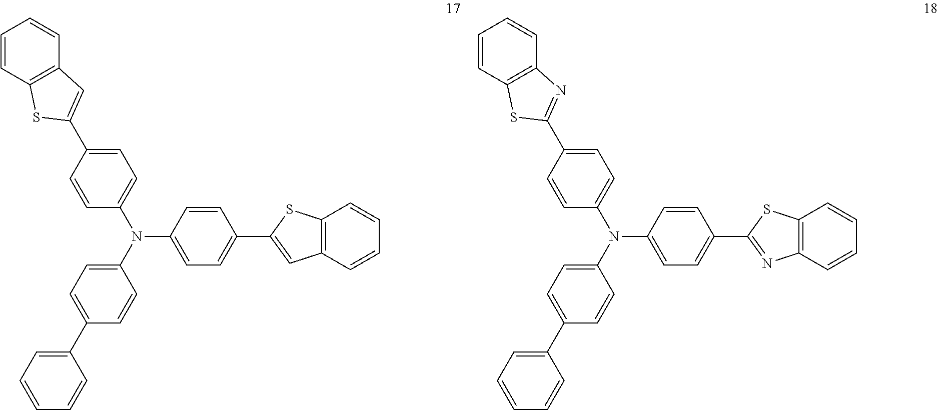 [SMILES: c1ccc(-c2ccc(N(c3ccc(-c4cc5ccccc5s4)cc3)c3ccc(-c4cc5ccccc5s4)cc3)cc2)cc1 ; c1ccc(-c2ccc(N(c3ccc(-c4nc5ccccc5s4)cc3)c3ccc(-c4nc5ccccc5s4)cc3)cc2)cc1]

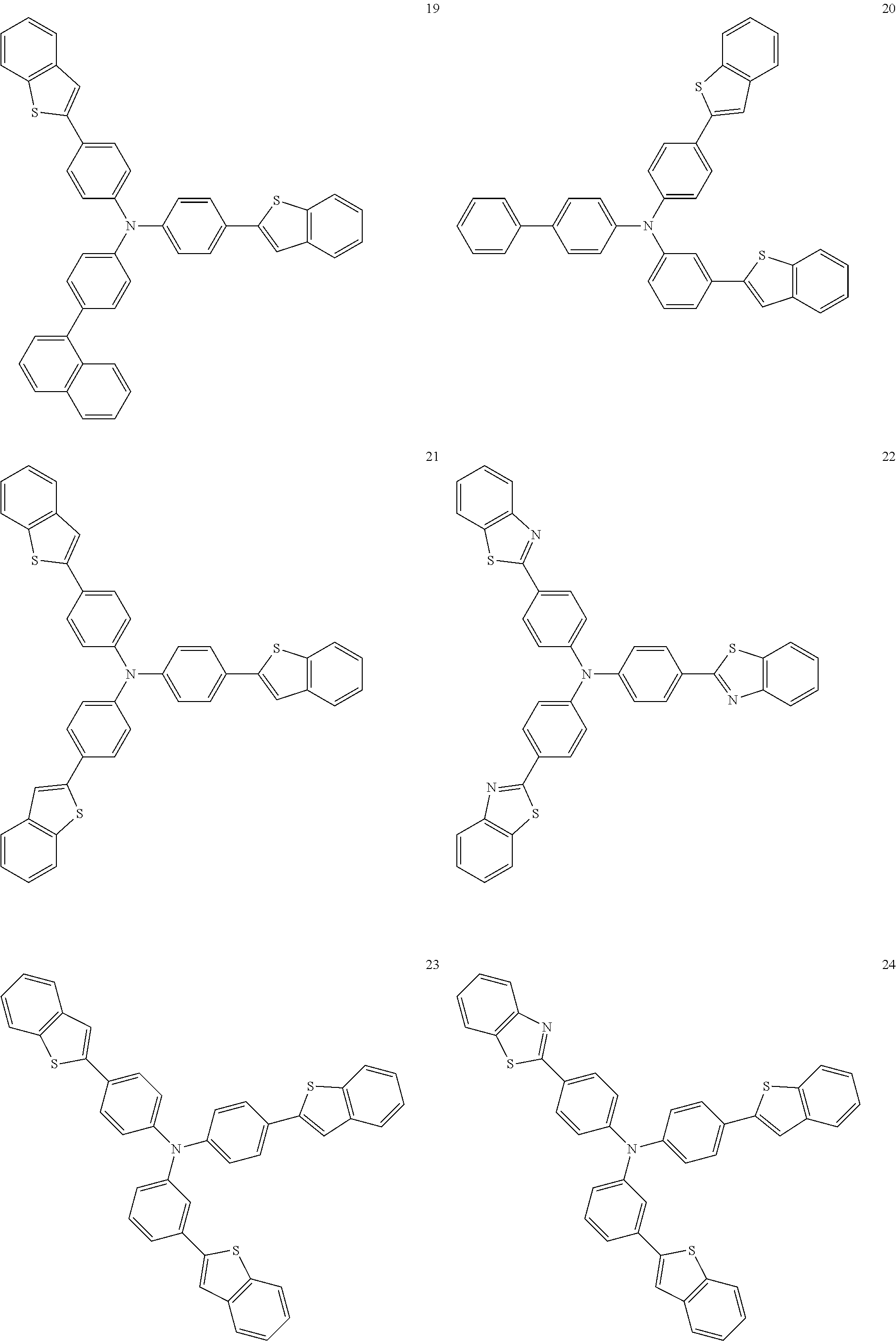 [SMILES: c1ccc2sc(-c3ccc(N(c4ccc(-c5cc6ccccc6s5)cc4)c4ccc(-c5cccc6ccccc56)cc4)cc3)cc2c1 ; c1ccc(-c2ccc(N(c3ccc(-c4cc5ccccc5s4)cc3)c3cccc(-c4cc5ccccc5s4)c3)cc2)cc1 ; c1ccc2sc(-c3ccc(N(c4ccc(-c5cc6ccccc6s5)cc4)c4ccc(-c5cc6ccccc6s5)cc4)cc3)cc2c1 ; c1ccc2sc(-c3ccc(N(c4ccc(-c5nc6ccccc6s5)cc4)c4ccc(-c5nc6ccccc6s5)cc4)cc3)nc2c1 ; c1cc(-c2cc3ccccc3s2)cc(N(c2ccc(-c3cc4ccccc4s3)cc2)c2ccc(-c3cc4ccccc4s3)cc2)c1 ; c1cc(-c2cc3ccccc3s2)cc(N(c2ccc(-c3cc4ccccc4s3)cc2)c2ccc(-c3nc4ccccc4s3)cc2)c1]

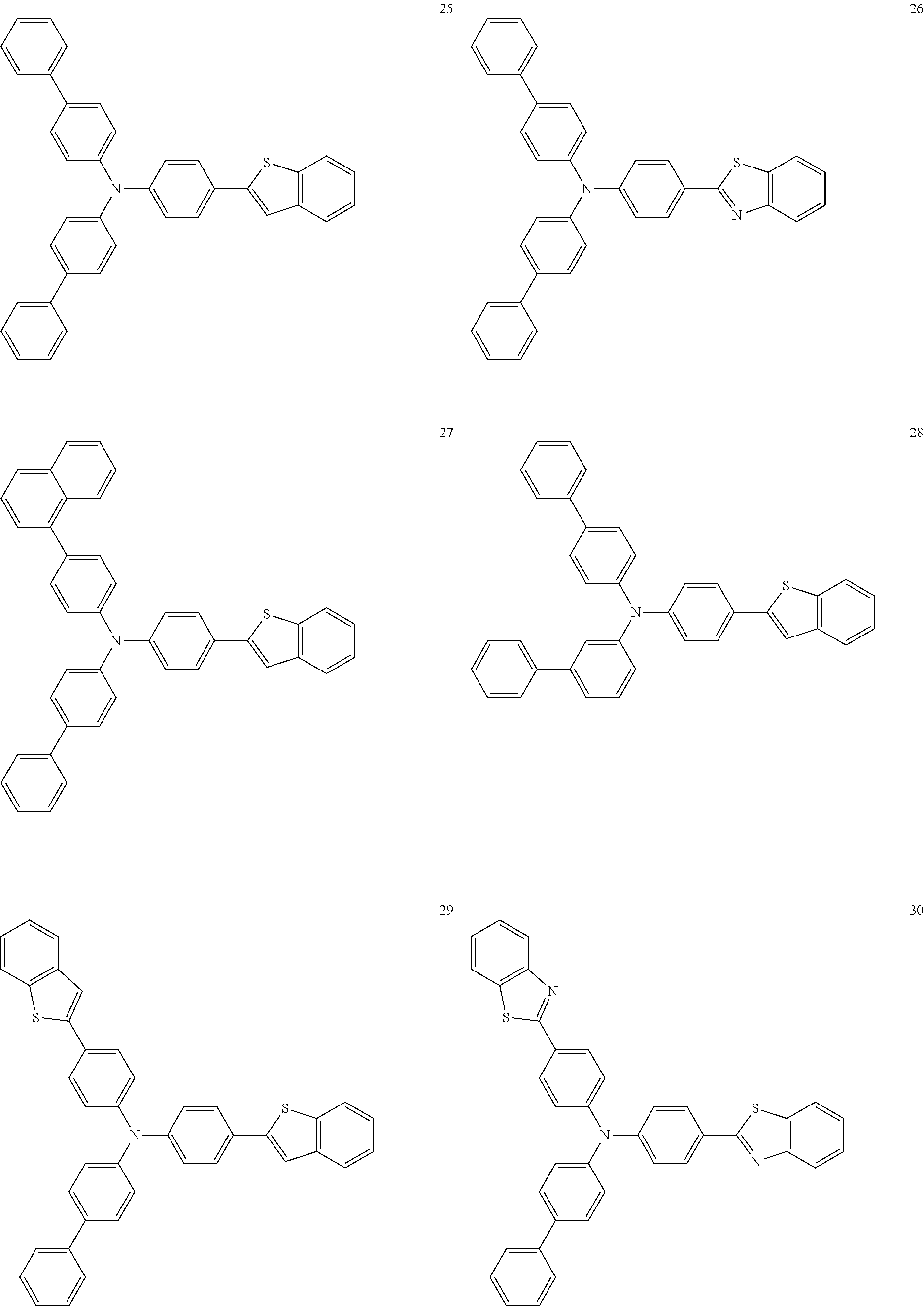 [SMILES: c1ccc(-c2ccc(N(c3ccc(-c4ccccc4)cc3)c3ccc(-c4cc5ccccc5s4)cc3)cc2)cc1 ; c1ccc(-c2ccc(N(c3ccc(-c4ccccc4)cc3)c3ccc(-c4nc5ccccc5s4)cc3)cc2)cc1 ; c1ccc(-c2ccc(N(c3ccc(-c4cc5ccccc5s4)cc3)c3ccc(-c4cccc5ccccc45)cc3)cc2)cc1 ; c1ccc(-c2ccc(N(c3ccc(-c4cc5ccccc5s4)cc3)c3cccc(-c4ccccc4)c3)cc2)cc1 ; c1ccc(-c2ccc(N(c3ccc(-c4cc5ccccc5s4)cc3)c3ccc(-c4cc5ccccc5s4)cc3)cc2)cc1 ; c1ccc(-c2ccc(N(c3ccc(-c4nc5ccccc5s4)cc3)c3ccc(-c4nc5ccccc5s4)cc3)cc2)cc1]

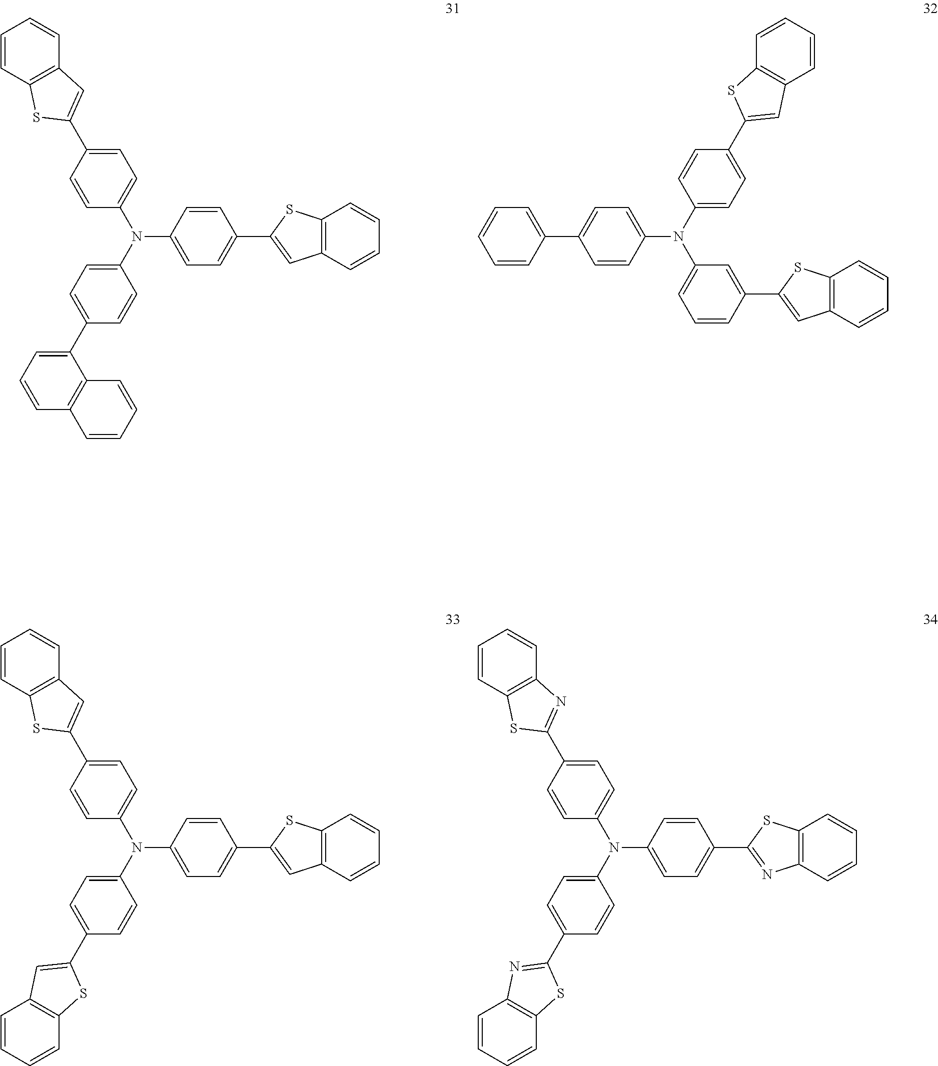 [SMILES: c1ccc2sc(-c3ccc(N(c4ccc(-c5cc6ccccc6s5)cc4)c4ccc(-c5cccc6ccccc56)cc4)cc3)cc2c1 ; c1ccc(-c2ccc(N(c3ccc(-c4cc5ccccc5s4)cc3)c3cccc(-c4cc5ccccc5s4)c3)cc2)cc1 ; c1ccc2sc(-c3ccc(N(c4ccc(-c5cc6ccccc6s5)cc4)c4ccc(-c5cc6ccccc6s5)cc4)cc3)cc2c1 ; c1ccc2sc(-c3ccc(N(c4ccc(-c5nc6ccccc6s5)cc4)c4ccc(-c5nc6ccccc6s5)cc4)cc3)nc2c1]

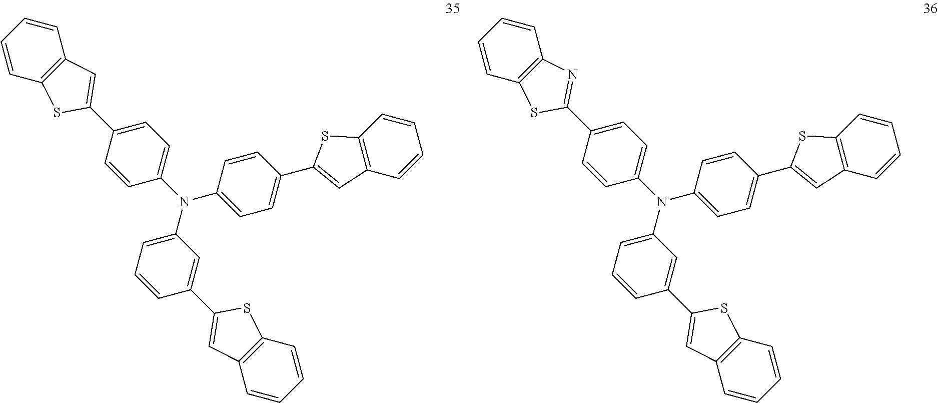 [SMILES: c1cc(-c2cc3ccccc3s2)cc(N(c2ccc(-c3cc4ccccc4s3)cc2)c2ccc(-c3cc4ccccc4s3)cc2)c1 ; c1cc(-c2cc3ccccc3s2)cc(N(c2ccc(-c3cc4ccccc4s3)cc2)c2ccc(-c3nc4ccccc4s3)cc2)c1]

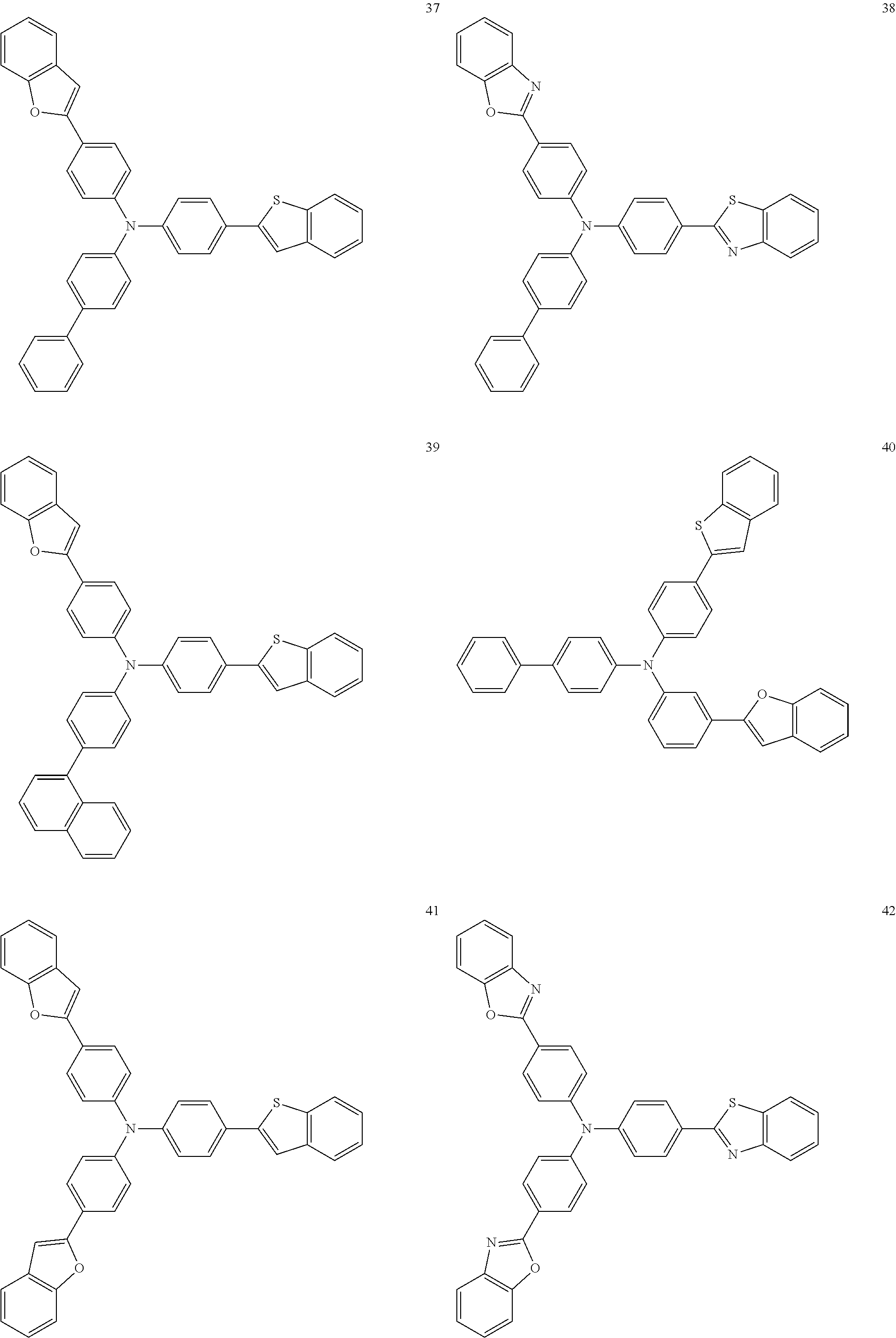 [SMILES: c1ccc(-c2ccc(N(c3ccc(-c4cc5ccccc5o4)cc3)c3ccc(-c4cc5ccccc5s4)cc3)cc2)cc1 ; c1ccc(-c2ccc(N(c3ccc(-c4nc5ccccc5o4)cc3)c3ccc(-c4nc5ccccc5s4)cc3)cc2)cc1 ; c1ccc2oc(-c3ccc(N(c4ccc(-c5cc6ccccc6s5)cc4)c4ccc(-c5cccc6ccccc56)cc4)cc3)cc2c1 ; c1ccc(-c2ccc(N(c3ccc(-c4cc5ccccc5s4)cc3)c3cccc(-c4cc5ccccc5o4)c3)cc2)cc1 ; c1ccc2oc(-c3ccc(N(c4ccc(-c5cc6ccccc6o5)cc4)c4ccc(-c5cc6ccccc6s5)cc4)cc3)cc2c1 ; c1ccc2oc(-c3ccc(N(c4ccc(-c5nc6ccccc6o5)cc4)c4ccc(-c5nc6ccccc6s5)cc4)cc3)nc2c1]

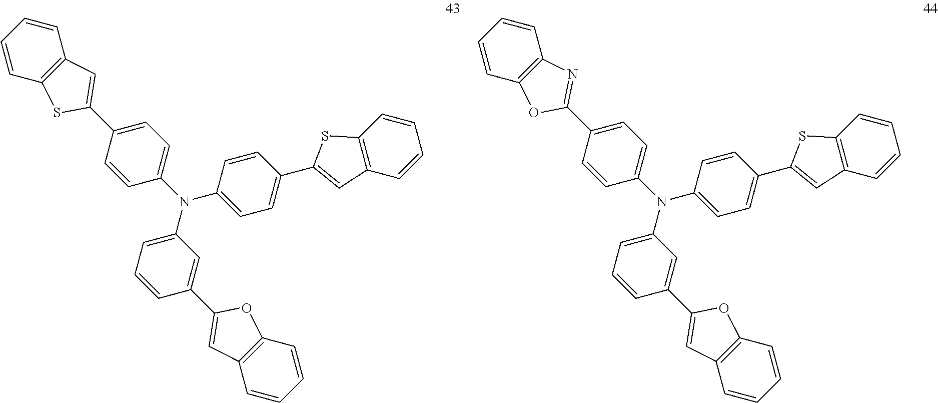 [SMILES: c1cc(-c2cc3ccccc3o2)cc(N(c2ccc(-c3cc4ccccc4s3)cc2)c2ccc(-c3cc4ccccc4s3)cc2)c1 ; c1cc(-c2cc3ccccc3o2)cc(N(c2ccc(-c3nc4ccccc4o3)cc2)c2ccc(-c3cc4ccccc4s3)cc2)c1]

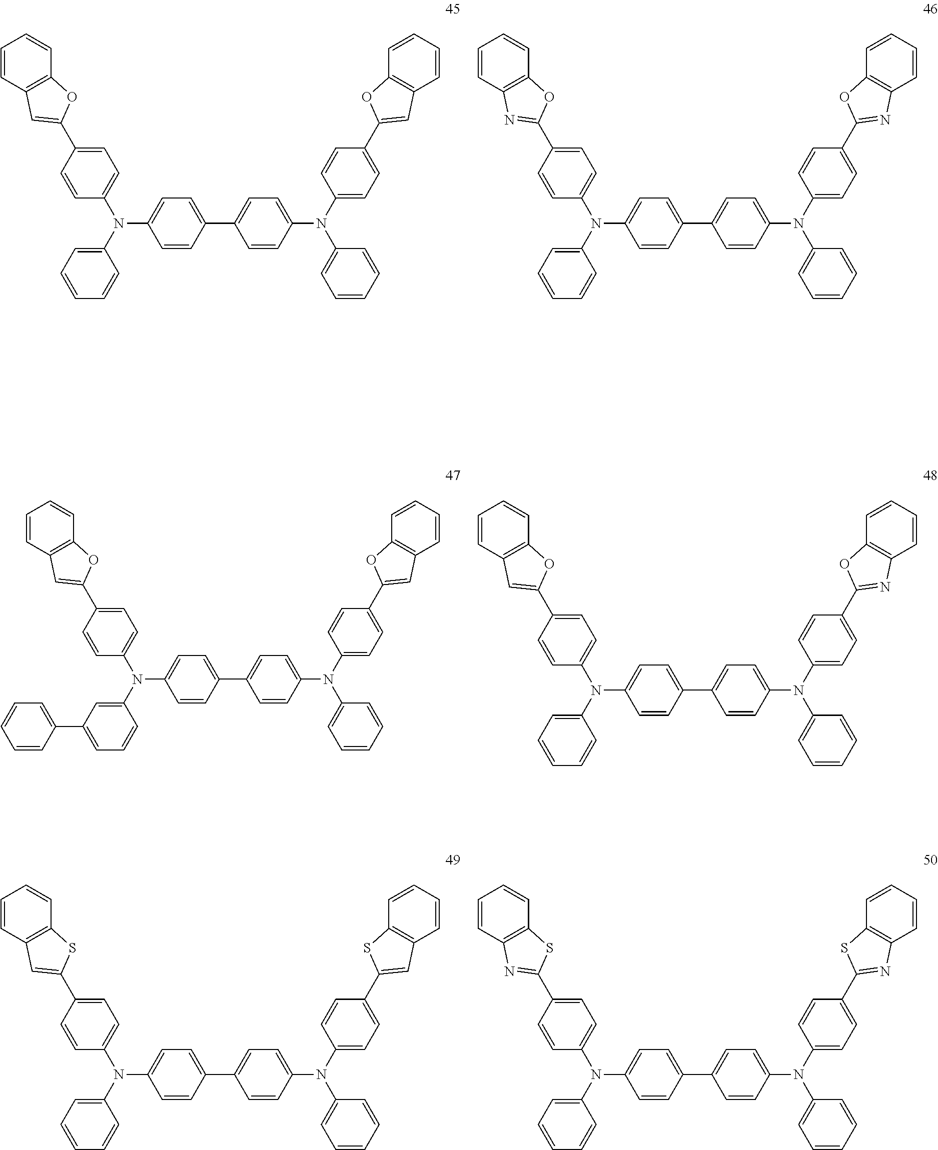

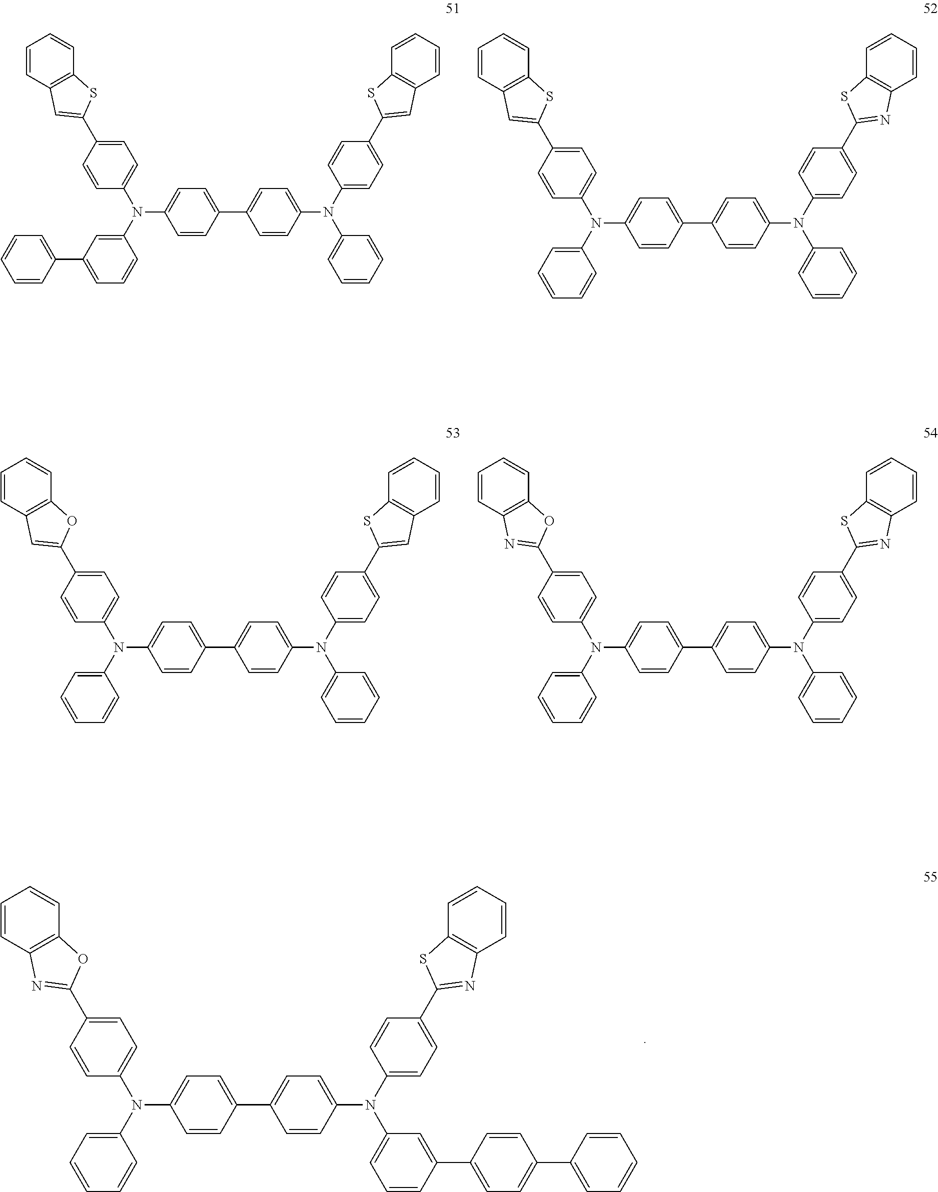

7. The light emitting element of claim 1, wherein the second compound comprises at least one compound selected from Compound Group 2:

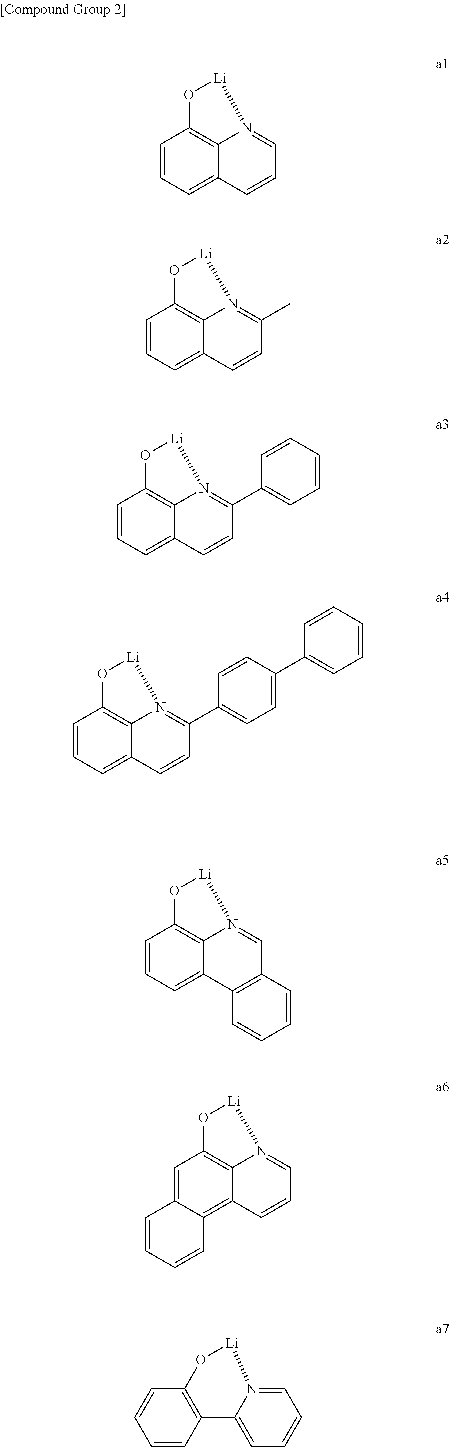

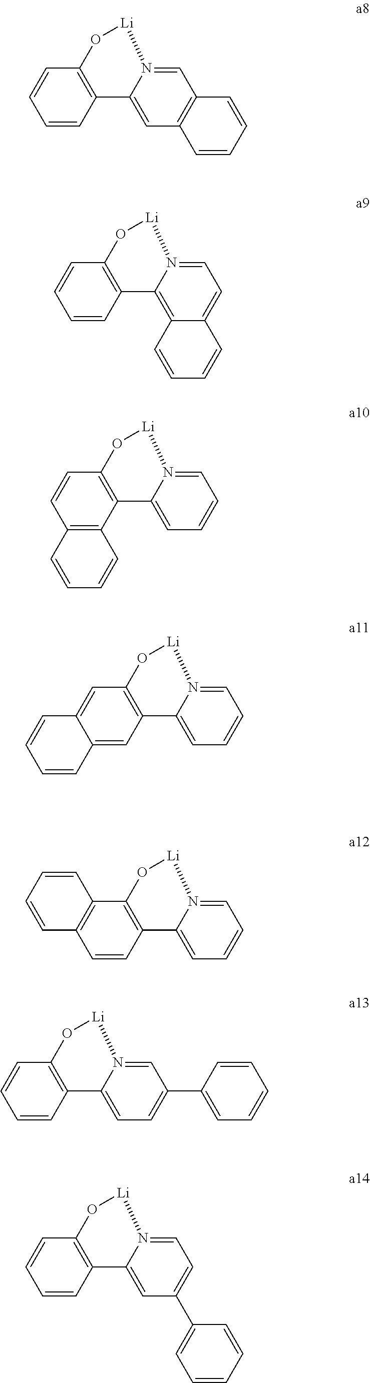

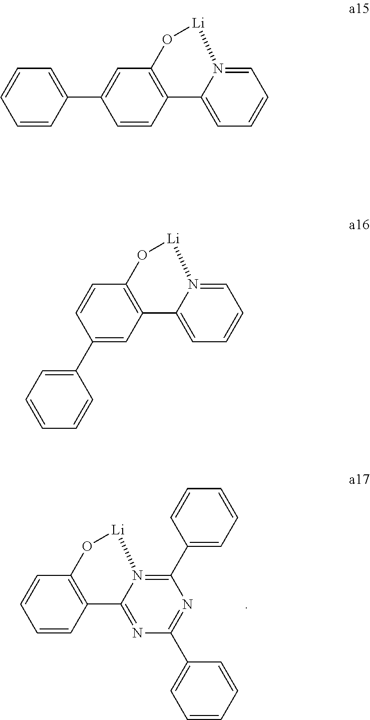

8. The light emitting element of claim 1, wherein a refractive index of the first capping layer with respect to visible light is higher than a refractive index of the second capping layer with respect to visible light.

9. The light emitting element of claim 1, wherein a thickness of the first capping layer is greater than a thickness of the second capping layer.

10. The light emitting element of claim 1, wherein a sum of a thickness of the first capping layer and a thickness of the second capping layer is in a range of about 100 nm to about 300 nm.

11. The light emitting element of claim 1, wherein
the first capping layer has a thickness in a range of about 50 nm to about 80 nm, and
the second capping layer has a thickness in a range of about 30 nm to 60 nm.

12. The light emitting element of claim 1, wherein
the first emission layer comprises:
a first red emission layer that emits red light;
a first green emission layer that emits green light; and
a first blue emission layer that emits blue light, and
the first red emission layer, the first green emission layer, and the first blue emission layer are spaced apart from each other in a plan view.

13. The light emitting element of claim 12, wherein the second emission layer comprises:
a second red emission layer that corresponds to the first red emission layer and emits red light;
a second green emission layer that corresponds to the first green emission layer and emits green light; and
a second blue emission layer that corresponds to the first blue emission layer and emits blue light.

14. The light emitting element of claim 1, wherein
the first light emitting unit further comprises:
a first hole transport region disposed on a lower portion of the first emission layer; and
a first electron transport region disposed on an upper portion of the first emission layer, and
the second light emitting unit further comprises a second electron transport region disposed on an upper portion of the second emission layer.

15. A display device comprising:
a base layer;
a circuit layer disposed on the base layer; and
a display element layer disposed on the circuit layer and comprising a light emitting element, wherein
the light emitting element comprises:
a first electrode;
a first light emitting unit disposed on the first electrode and comprising a first emission layer;
a charge generation unit disposed on the first light emitting unit;
a second light emitting unit disposed on the charge generation unit and comprising a second emission layer;
a second electrode disposed on the second light emitting unit;
a first capping layer disposed on the second electrode; and
a second capping layer disposed on the first capping layer,
the first capping layer comprises a first compound represented by Formula 1, and
the second capping layer comprises a second compound represented by Formula 2-1 or Formula 2-2: 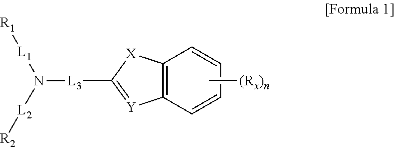
wherein in Formula 1,
L₁ to L₃ are each independently a direct linkage, a substituted or unsubstituted arylene group having 6 to 12 ring-forming carbon atoms, or a substituted or unsubstituted heteroarylene group having 5 to 11 ring-forming carbon atoms,
X is O or S,
Y is N or C(R_{y}),
R₁, R₂, Rₓ, and R_{y} are each independently a hydrogen atom, a deuterium atom, a halogen atom, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and
n is an integer from 0 to 4; 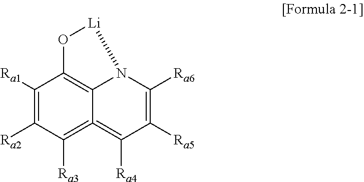
wherein in Formula 2-1,
Rₐ₁ to Rₐ₆ are each independently a hydrogen atom, a deuterium atom, a halogen atom, a cyano group, a substituted or unsubstituted amine group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring; and 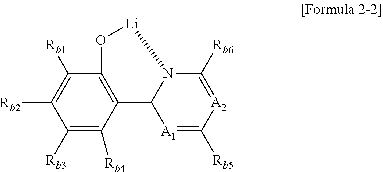
wherein in Formula 2-2,
A₁ and A₂ are each independently N or C(R_{z}), and
R_{z} and R_{b1} to R_{b6} are each independently a hydrogen atom, a deuterium atom, a halogen atom, a cyano group, a substituted or unsubstituted amine group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

16. The display device of claim 15, wherein
the base layer comprises:
a first light emitting region, a second light emitting region, and a third light emitting region, which are spaced apart from each other in a plan view; and
a non-light emitting region defined between the first light emitting region, the second light emitting region, and the third light emitting region, the display element layer comprises:
a pixel defining film that overlaps the non-light emitting region; and
openings that overlap each of the first light emitting region, the second light emitting region, and the third light emitting region, and
the first emission layer is disposed in each of the openings.

17. The display device of claim 16, wherein
the first emission layer comprises:
a first red emission layer that corresponds to the first light emitting region;
a first green emission layer that corresponds to the second light emitting region; and
a first blue emission layer that corresponds to the third light emitting region, and
the second emission layer comprises:
a second red emission layer that corresponds to the first light emitting region;
a second green emission layer that corresponds to the second light emitting region; and
a second blue emission layer that corresponds to the third light emitting region.

18. The display device of claim 17, wherein
the first light emitting unit further comprises:
a first hole transport region disposed on a lower portion of the first emission layer; and
a first electron transport region disposed on an upper portion of the first emission layer, and
the first hole transport region and the first electron transport region are each provided as a common layer with respect to the first light emitting region, the second light emitting region, and the third light emitting region.

19. The display device of claim 17, wherein
the second light emitting unit further comprises a second electron transport region disposed on an upper portion of the second emission layer, and
the second electron transport region is provided as a common layer with respect to the first light emitting region, the second light emitting region, and the third light emitting region.

20. The display device of claim 17, wherein the first electrode, the charge generation unit, the second electrode, the first capping layer, and the second capping layer are each provided as a common layer with respect to the first light emitting region, the second light emitting region, and the third light emitting region.
